(19) United States
(12) Patent Application Publication
(10) Pub. No.: US 2026/0043875 A1
(43) Pub. Date: Feb. 12, 2026

(54) SYSTEM, APPARATUS AND/OR PROCESS

(71) Applicant: Orica International Pte Ltd, Singapore (SG)

(72) Inventors: Kresten Lukas Coffey NIELSEN, Hamilton (AU); Kieren Peter RASMUSSEN, Kurri Kurri (AU); Johann ZANK, Valentine (AU)

(21) Appl. No.: 19/102,578

(22) PCT Filed: Aug. 10, 2023
(86) PCT No.: PCT/SG2023/050551

§ 371 Date: Feb. 10, 2025

(30) Foreign Application Priority Data
Aug. 10, 2022 (SG) 10202250696E

(51) Int. Cl. G01R 33/02; G01V 3/10

(52) U.S. Cl. CPC G01R 33/0206; G01V 3/10

(57) ABSTRACT

A process for remote localization of an object including (i) receiving/determining two or more magnetic field measurements using at least one magnetometer of a magnetic field generated by a magnetic field source (MFS) in a marker apparatus remote from the magnetometer and in/on an opaque medium such that the magnetic field extends through the opaque medium and/or through a navigable medium between the MFS and the magnetometer; (ii) receiving/determining two or more respective measurement locations of the magnetic field measurements in 3D by determining locations of the magnetometer when the magnetic field measurements are/were determined; and (iii) numerically estimating a location of the MFS in 3D using the magnetic field measurements, the measurement locations, and a mathematical model representing the system as a magnetic dipole (the MFS) in the navigable and opaque media and the resulting magnetic fields. The measurements can be made while the magnetometer is moving.

### RELATED APPLICATIONS

The present application is related to Singaporean patent application number 10202250696E, entitled “System, Apparatus and/or Process”, filed in the name of Orica International Pte Ltd on 10 Aug. 2022, the original specification of which is hereby incorporated by reference in its entirety herein.

### TECHNICAL FIELD

The present disclosure relates to localization of objects, e.g., buried/submerged/obscured markers, including determining their locations in three orthogonal dimensions, thus determining “3D locations”.

### BACKGROUND

It is often desirable to monitor movement of portions of an opaque/non-transparent medium, including substantially solid materials (e.g., in commercial blasting/mining/quarrying operations), or to localize buried/submerged/obscured objects (e.g., in commercial blasting/mining/quarrying/exploration operations and/or in safety/rescue/monitoring operations).

In an example, identification of ore/waste boundaries is a common, and, usually necessary, part of recovering valuable minerals as part of the mining process that serves two primary purposes: firstly, it ensures that ore loss is minimised at the excavation stage: secondly, it ensures that the treatment of waste is minimised in the post-mining recovery stage. To this end, physical targets have been used to track the boundaries after blasting. These targets include visual markers such as plastic pipes installed in extra boreholes within and along the boundaries, or coloured sandbags; magnetic metal targets such as metal balls, chains and the like that are picked up using simple metal detectors. In some mines a spotter is required to assist the operator to make that decision—a further, albeit small, cost impost on the operation. In other examples, geotechnical monitoring may be desirable to monitor movements in dam walls and/or coal stockpiles, and borehole monitoring may be desirable to monitor/detect locations of boreholes (including at different depths in the boreholes) in mining/quarrying operations. Some previous movement markers may have been designed to generate and emit a magnetic field that penetrates the medium around the markers (e.g., ore/rock/earth), and that is detectable at an adjacent surface of the medium (e.g., at the surface of a muckpile after blasting), and a handheld magnetic-field detector may have been used to detect a point on the surface of maximum strength of the magnetic field, and thus to estimate that the buried marker was located directly below/adjacent that point. When used for commercial blasting operations, these markers may be referred to as “blast movement markers”. However, some previous markers used for localization may be too complicated/expensive for some applications, and previous processes for determining their locations may be too slow/inaccurate. Some previous markers may require detection of a magnetic field maximum in the horizontal x-y plane relative to gravity (of the surface in which the marker is buried) by moving a detector (e.g., a sensor loop) back and forth in the horizontal place, and such previous markers require a self-righting antenna inside to provide a vertical magnetic dipole (VMD) relative to gravity that produces a symmetrical magnetic field, such that the magnetic field maximum will be directly above it. Previous markers may require separate determination of marker depth (in the vertical z direction), e.g., by angling the sensor loop to measure the angle of the field lines (null-finding), which may require manual operation of the detector to: (i) move it horizontally back-and-forth over the maximum, and (ii) then angle it relative to the horizontal to find the field line angles: after which the depth can be estimated/determined from the field line angles. Alternatively, previous markers may need to be placed at the same elevation/depth when multiple markers are used, which may be difficult to arrange and/or inaccurate. The previous markers with the internal self-righting mechanisms may be prone to failure or poor operation in some environments, thus introducing localization errors.

In another example, in commercial blasting operations for mining/quarrying, including underground mining, it may be desirable to confirm the locations of buried explosive initiators/primers, particularly initiators/primers configured for wireless through-the-earth (TTE) operation, such as Orica's WEBGEN devices. International Patent Application Publication No. WO2015/143500A1 (Appleby et al.) describes a method for remote localization of a marker TTE; however, this method may require an undesirably complicated/expensive marker to be integrated/attached to an explosive initiator/primer, and/or an undesirably large/powerful magnetic field source, at least for some operations.

In another example, it may be desirable to mark where buried objects are located to mitigate undesirable/dangerous activities, e.g., excavation, including to mark buried pipelines/powerlines or to mark buried explosive initiators/primers/material. Previous markers for marking buried pipeline locations may require a person using a handheld metal detector to locate the markers (e.g., and thus the pipeline) using an iterative search, which might be too slow/inconvenient for some applications.

In another example, in seismic exploration, it may be desirable to localize the blasting initiators/primers (also referred to as “sources”) and/or the geophone/hydrophones (also referred to as “receivers”). Previous markers for seismic sources/receivers may include global positioning system (GPS) receivers for localization; however, these may be insufficiently accurate/useful in GPS-denied environments, e.g., in water/earth or under foliage.

In another example, in agricultural operations, it may be desirable to monitor soil conditions using localized sensing devices. Previous methods for soil monitoring may have required soil samples to be taken from selected/surveyed locations, and the locations recorded manually to match laboratory testing results on the soil samples.

In another example, in emergency operations, it may be desirable to locate and/or track a person or a piece of equipment buried in an avalanche, a landslide, or a collapsed structure.

In another example, in civil engineering and construction operations, it may be desirable to locate and/or track a person or a piece of equipment inside a structure; and in geological, seismological or construction monitoring, it may be desirable to monitor rock, earth, foundations or structures to determine movement over time.

It is desired to address or ameliorate one or more disadvantages or limitations associated with the prior art, or to at least provide a useful alternative.

### SUMMARY

Disclosed herein is a process (300) for remote localization of an object, the process (300) including:
receiving/determining two or more measurements (“magnetic field measurements”) of a magnetic field using at least one magnetometer (106) when the magnetic field is generated by a magnetic field source (MFS) in a marker apparatus (102), when the marker apparatus (102) is remote from the or each magnetometer (106) and in/on an opaque medium (104) such that the magnetic field penetrates through the medium (104) and/or through a navigable medium (112) (e.g., space, air or water) between the MFS and the at least one magnetometer (106) (the opaque medium (104) may have a surface, e.g., including earth/rock/ice/water, and the marker apparatus (102) may be buried or submerged in the medium (104) or seated/placed on the opaque medium (104) such that the marker apparatus (102) is stationary relative to the opaque medium (104) so that the marker apparatus (102) moves with the medium (104) if the medium (104) moves);
receiving/determining (e.g., measuring) two or more respective locations (“measurement locations”, also referred to as “stations”) of the magnetic field measurements in three orthogonal dimensions (3D) by determining locations of the magnetometer (106) when the magnetic field measurements are/were determined (wherein the measurement locations may be in the opaque medium (104), or outside the opaque medium (104) and in the navigable medium (112)); and
numerically estimating (e.g., using an iterative process, and using at least one data processing unit/processor, such as at least one microprocessor) a location (“source location”) of the magnetic field source (MFS) in three orthogonal dimensions (3D) using:
   the two or more magnetic field measurements;
   the two or more measurement locations; and
   a mathematical model representing a magnetic dipole of the magnetic field source (MFS).

The receiving/determining of the two or more magnetic field measurements may include receiving/determining magnetic field measurements from at least one of the or each magnetometer (106)—a “mobile magnetometer”—attached to at least one mobile platform (which can include a plurality of configurations, including one or more mobile magnetometers attached to the or each mobile platform (108), and/or two or more mobile magnetometers attached to two or more mobile platforms (108), including one mobile magnetometer attached to each mobile platform (108)), including using magnetic field measurements made while a speed of the or each mobile magnetometer is substantially non-zero (in a reference frame of the marker apparatuses (102) and the opaque medium (104)). The mobile platform (108) is configured to move relative to the marker apparatus (102) and the opaque medium (104). The mobile platform (108) is configured to move in the opaque medium (104) and/or outside the medium (104), which may include on the surface of the medium (104) (e.g., for earth/rock/ice or water) and/or flying/floating substantially off the surface—e.g., above a mine bench or along a mine tunnel. The magnetic field measurements are made while the mobile magnetometer is while travelling along a path including the measurement locations. The substantially non-zero speed can include from slightly above zero meters per second (m/s) to substantially 30 m/s, including from above zero to 25 m/s, including from above zero to substantially 3 to 4 m/s (e.g., for a multi-rotor drone, e.g., for mining or quarrying operations), and substantially 8 m/s to substantially 25 m/s (e.g., for a fixed wing drone, e.g., for linear operations, e.g., along a ditch or pipeline). Using the one or more mobile platforms (108), e.g., in the form of one or more remotely controlled and/or autonomous vehicles (referred to as “drones”), including an individual drone or a plurality of such vehicles (referred to as a “drone swarm”), allows rapid/convenient coverage of multiple of the measurement locations (also referred to as “stations”) as the mobile platforms (108) move.

The receiving/determining of the two or more magnetic field measurements may include using at least one of the at least one magnetometer (106) attached to a fixed point, or stationary at a fixed point, which is a non-mobile point in a reference frame of a site that includes the at least one opaque medium (104) and the marker apparatus (102), which may be a mine frame of reference, or a site frame of reference, or an environment frame of reference. Using the fixed point may mitigate the need to measure the location of the at least one magnetometer (106) while the magnetic field measurements are being made, e.g., because the location of the fixed point can be selected/measured before/after the magnetic field measurements are being made.

As the magnetic field source (MFS) is in the marker apparatus (102), the (estimated) source location is also an (estimated) marker location, or at least the MFS location is in the marker location.

The process (300) allows the magnetic field source (MFS) to have any orientation in the medium (104) (i.e., an arbitrary orientation, e.g., caused by movement of the medium (104)) while still being accurately localizable, thus addressing problems of expensive/unreliable internal self-righting mechanisms in buried markers. The marker apparatus (102) remains stationery during the two or more measurements (e.g., by being buried), with a fixed location and orientation, with respect to the duration of the two or more measurements. Using the magnetometer (106) attached to the mobile platform (108) may be more flexible/efficient that using an array of magnetometers/sensors fixed in space, e.g., at fixed stations relative to a mining site.

Use of the mathematical model allows localization of the marker apparatus (102), and a plurality of marker apparatuses (102) with respective MFSes measured at the same time, without requiring detection of a signal maximum from the marker apparatus (102) on the surface or in space, thus without requiring the mobile platform (108) to pass through a region of space containing the signal maximum. This may allow for efficient/flexible routing of the mobile platform (108) around a site with one or more of the marker apparatuses (102). The mathematical model includes relationships between the 3D marker location and the magnetic field measurements and locations, thus allowing a “one-step solution” of the 3D marker location, rather than estimation of an XY location from a maximum signal and a separate estimation of a Z (depth) location from knowledge of ground permeability. As the process (300) uses the mathematical model for determining the source location, the process (300) may be referred to as providing “model-based localization”. As the process (300) determines the source location in 3D without requiring knowledge of previous locations of the MFS, the process (300) can use the magnetic field measurements taken after a blasting operation, including wherein the marker apparatus (102) is in a post-blast muckpile.

Use of the mathematical model allows localization of the marker apparatus (102) in three orthogonal dimensions (3D location) without necessarily requiring knowledge of a magnetic strength of the magnetic field source (MFS), or an orientation of the magnetic field source (MFS), and may avoid a factory calibration of marker moment magnitude or alignment antenna coil(s) to a shell (714) of the marker apparatus (102). The combination of the magnetic strength and the orientation of the magnetic field source (MFS) define its magnetic moment.

The process (300) may include numerically estimating (e.g., using the iterative process) an orientation of the magnetic field source, including in three orthogonal dimensions (3D orientation), and estimating an orientation of the marker apparatus (in/on the medium) from the numerically estimated orientation of the magnetic field source.

The process (300) may optionally include using a selected strength or moment or a calibration of the marker apparatus to improve precision. The magnetic field source may be configured to generate the magnetic field with a selected strength or moment, which may include a selected value and/or a selected range of values (which may be referred to as a “calibrated range”), and the process (300) may use the selected strength or moment with the mathematical model when numerically estimating the location of the magnetic field source.

The marker apparatus (102) may be configured to measure/control the orientation of the magnetic field source (MFS), and the process (300) may use the measured/controlled orientation of the magnetic field source (MFS) with the mathematical model when numerically estimating the location of the magnetic field source (MFS), which may improve the efficiency/precision of the process (300).

The mathematical model associates the magnetic field measurements, the determined locations in 3D, and the 3D location of the magnetic dipole. The mathematical model may optionally assume that the medium (104) is homogeneous, and/or that the medium (104) has a skin depth substantially approaching infinity for frequencies at which the magnetic field (b) is modulated.

The process (300) may include:
a) receiving/determining (e.g., measuring) two or more orientations of the magnetometer (106) at the two or more measurement locations in three orthogonal dimensions (3D orientation) (thus determining the orientations of the magnetometer (106) when the magnetic field measurements are/were determined); and
b) numerically estimating (e.g., using an iterative process) the location of the magnetic field source (MFS) in the three orthogonal dimensions (3D) using a combination of:
   i) the two or more magnetic field measurements;
   ii) the two or more measurement locations;
   iii) the mathematical model representing the dipole of the magnetic field source; and
   iv) the two or more magnetometer orientations.

The determining of the two or more orientations of the magnetometer may include:
a) determining (e.g., measuring) one or more orientations of the mobile platform (108);
b) determining (e.g., measuring) one or more relative orientations of the magnetometer (106) to the mobile platform (108); and
c) estimating the two or more orientations of the magnetometer (106) based on numerical addition/subtraction of the orientations of the mobile platform (108) and the relative orientations.

The determining of the two or more measurement locations may include:
receiving/determining respective magnetic-field-measurement times when the magnetic field measurements are/were measured; and determining the respective locations of the magnetometer at the magnetic-field-measurement times from location tracking data representing the location of the magnetometer over time. Determining the measurement locations based on the times may be more accurate/efficient if the magnetic-field-measurement times can be recorded accurately and stored efficiently, e.g., on a drone, and if the location tracking data representing the location of the magnetometer over time can be recorded accurately and efficiently, e.g., using the navigation module (118) on the drone, and/or using a remote location tracking system that tracks the path of the drone with respect to time.

The magnetometer may be in the form of a “total field magnetometer” and may be configured to measure a total scalar value of the magnetic field (b) (which may be referred to as a “total field”) at the measurement location, regardless of its direction.

The magnetometer may be in the form of a “vector magnetometer” and may be configured to measure a scalar value of the magnetic field (b) in one to three of the three orthogonal dimensions (3D), and the two or more magnetic field measurements may therefore be non-coherent vector magnetic field measurements.

The magnetometer may be in the form of a “coherent vector magnetometer” and may be configured to measure a phasor value of the magnetic field (b) in three orthogonal dimensions (3D), and the two or more magnetic field measurements may therefore be phasor magnetic field measurements. The measuring of the phasor value of the magnetic field may be referred to as “coherent detection” of the magnetic field (b).

The measurements of the magnetic field may include scalar magnetic field strength values (total field), vector magnetic field strength values (1D, 2D or 3D absolute values), and/or phasor magnetic field strength values (1D, 2D or 3D coherent values).

The determining of the two or more measurement locations may include:
a) determining (e.g., measuring) locations of the mobile platform (108);
b) determining (e.g., measuring) a relative location of the magnetometer (106) to the mobile platform (108); and
c) estimating the two or more measurement locations based on numerical addition/subtraction of the locations of the mobile platform (108) and the relative location.

The determining of the measurements of the magnetic field (b) may include the magnetometer (106) detecting magnetic-induction (MI) signals/through-the-earth (TTE) signals from the magnetic field source (MFS).

The 3D locations may include three Cartesian values or three spherical values.

The mathematical model may include:
a) a closed-form mathematical model with a system of closed-form equations (mathematical relationships): or
b) a numerical integration model (e.g., a finite element analysis (FEA) model).

The closed-form equations represent solutions to Maxwell's equations for an (infinitesimal) magnetic dipole in a conducting/permeable medium with a simple structure. The numerical integration model represents integration of Maxwell's equations for an magnetic dipole in a conducting/permeable medium with any structure. The model may use magnetic dipole modelled as an infinitesimal magnetic dipole (where the distance to the magnetometer (106) is far larger than the size of the MFS: alternatively, the MFS could be modelled as a loop/coil of finite extent, in which case the the ‘strength’ of the marker would be described by the current, turn shape and area and number of turns rather than by the “dipole moment”. In some applications, the closed-form mathematical model may be preferable for being faster. In other applications, the FEA model may be preferable for being more accurate. For embodiments using the FEA model, the cost function includes: {modelled value} minus {measured value}, where each {value} can be total field, coherent vector or magnitude vector.

The localization process includes the data processing unit(s)/microprocessor(s) (110) (hereafter microprocessor (110) for purpose of brevity and simplicity) receiving the one or more orientations of the magnetic field source (MFS) from marker apparatus (102). The localization process includes the microprocessor (110) receiving the selected strength of the moment (m) of the magnetic field source (MFS) from the calibration process. The localization process includes the microprocessor (110) receiving the two or more magnetic field measurements from the magnetometer (106). The localization process includes the microprocessor (110) receiving the two or more measurement locations from a tracking module (e.g., a navigation module (118) attached to the mobile platform (108), and/or a remote location tracking system). The localization process includes the microprocessor (110) receiving the two or more orientations of the magnetometer (106) from a relative pose measurement system and/or the tracking module). The process (300) thus includes at least one microprocessor: receiving the one or more orientations of the magnetic field source (MFS) in the marker apparatus: the microprocessor receiving the selected strength of the moment (m) of the magnetic field source (MFS) from the calibration process: the microprocessor receiving the two or more magnetic field measurements from the magnetometer: the microprocessor receiving the two or more measurement locations from a navigation module; and/or the microprocessor receiving the two or more orientations of the magnetometer from a relative pose measurement system and/or a navigation module. In particular, the process (300) includes: at least one microprocessor receiving the two or more magnetic field measurements; and the microprocessor receiving the two or more measurement locations from a navigation module.

The process (300) may include making the plurality of magnetic field measurements with respective SNRs (which include mutually different SNR values), and only selecting ones of the magnetic field measurements (also referred to as selecting the “stations”) having SNRs or magnetic fields over a selected threshold for the numerically estimating of the source location.

The process (300) may include localizing at least a portion of a drill bit or drill string by localizing a corresponding marker apparatus (102) during drilling with the drill bit or drill string, or after detachment of the portion from the drill bit or drill string.

The process (300) may include localizing a blast initiation device or a blast primer device for initiating blasts in commercial blasting operations based on the localization of at least one marker apparatus (102) that is attached to or includes or forms the blast initiation device or the blast primer device.

The process (300) may include localizing an explosive material in the opaque medium (104) by localizing at least one marker apparatus (102) buried in a selected location in the opaque medium (104) relative to and/or adjacent to and/or above the explosive material, optionally while digging/excavating a portion of the opaque medium (104) or after the digging/excavating.

The process (300) may include localizing seismic receivers (902) and/or seismic sources (904) by localizing the marker apparatuses (102) respectively incorporated in or attached to the seismic receivers (902) and/or the seismic sources (904).

The process (300) may include monitoring movement of broken rock (e.g., in a heap) by repeatedly localizing the marker apparatus (102) placed on or buried in the broken rock.

The process (300) may include tracking an ore body during blasting, excavation and/or processing by the localization of the corresponding marker apparatuses (102), optionally including measuring draw of a stockpile by repeated localization of the corresponding marker apparatuses (102) over a selected time period.

The process (300) may include a mobile magnetometer and/or a wireless receiver on the mobile platform (108) gathering wireless encoded/modulated data signals from devices in/on the opaque medium (104) incorporating the marker apparatuses (102), and/or capturing optical/thermal images, while on a path measuring the magnetic fields.

The process (300) may include localizing a linear utility (e.g., a pipeline/powerline) in the opaque medium (104) by localizing at least one marker apparatus (102) buried in a selected location in the opaque medium (104) relative to and/or adjacent to and/or above the linear utility, optionally while digging/excavating a portion of the opaque medium (104) above the linear utility.

The process (300) may include localizing measured physical parameters of the opaque medium (104) (e.g., pressure, moisture, and/or temperature) by localizing at least one marker apparatus (102) buried in the opaque medium (104) with respective environmental sensors to measure the physical parameter values, optionally while ploughing the opaque medium (104) adjacent/around the buried marker apparatus (102).

The process (300) may include localizing a person or a piece of equipment buried in the opaque medium (104), e.g., an avalanche, a landslide, or a (collapsed) structure, by localizing at least one marker apparatus (102) attached to the person or the piece of equipment in the opaque medium (104).

The process (300) may include placing/burying the at least one marker apparatus (102) on/in the opaque medium (104) (rock, earth, foundations or structures), and the process (300) may include localizing the marker apparatus (102) repeatedly over a selected time period to monitor movement of the opaque medium (104).

Disclosed herein is a system (100) for remote localization of an object, the system (100) including:
at least one magnetometer (106) (optionally attached to a mobile platform (108)) configured for determining (e.g., measuring) two or more measurements (“magnetic field measurements”) of a magnetic field (b) when the magnetic field (b) is generated by a magnetic field source (MFS) in a marker apparatus (102), when the marker apparatus (102) is remote from the or each magnetometer (106) and in/on an opaque medium (104) such that the magnetic field extends through the opaque medium (104) and/or through a navigable medium between the MFS and the or each magnetometer (106);
a tracking module (e.g., a navigation module (118) attached to the mobile platform (108), and/or a remote location tracking system) configured for determining (e.g., measuring) two or more respective locations (“measurement locations”) of the magnetic field measurements in three orthogonal dimensions (3D) by determining locations of the or each magnetometer (106) when the magnetic field measurements are/were determined (wherein the measurement locations may be in the opaque medium (104) or outside the opaque medium (104)); and
at least one microprocessor (110) configured for numerically estimating a location (“source location”) of the magnetic field source (MFS) in three orthogonal dimensions (3D) using:
   the two or more magnetic field measurements;
   the two or more measurement locations; and
   a mathematical model representing a magnetic dipole of the magnetic field source.

The or each magnetometer (106) may include at least one mobile magnetometer attached to at least one mobile platform (108), optionally wherein the or each magnetometer (106) includes a plurality of magnetometers (106) attached to the or each mobile platform (108), optionally wherein the or each magnetometer (106) includes two or more magnetometers (106) attached two or more mobile platforms (108), optionally including one magnetometer (106) attached to each mobile platform (108).

The tracking module may include a navigation module (118) attached to the mobile platform (108) and configured for measuring the 3D measurement locations of the magnetic field measurements.

The tracking module may include a remote location tracking system configured for recording the 3D measurement locations in a path of the mobile platform (108) during the measuring of the magnetic field measurements, and time stamping the 3D measurement locations.

The or each magnetometer (106) may include at least one magnetometer (106) attached to a fixed point, or stationary at a fixed point, in a reference frame of a site that includes the opaque medium (104) and the marker apparatus (102).

The microprocessor (110) may be configured for numerically estimating an orientation of the magnetic field source (MFS), including in three orthogonal dimensions (3D orientation), and estimating an orientation of the marker apparatus (102) (on/in the medium (104)) from the numerically estimated orientation of the magnetic field source (MFS).

The magnetic field source (MFS) may be configured to generate the magnetic field (b) with a selected strength or moment, which may include a selected value and/or a selected range of values (which may be referred to as a “calibrated range”), and the microprocessor (110) may be configured for using the selected strength or moment with the mathematical model when numerically estimating the location of the magnetic field source (MFS).

The marker apparatus (102) may be configured to measure/control the orientation of the magnetic field source (MFS), and the microprocessor (110) may be configured for using the measured/controlled orientation of the magnetic field source (MFS) with the mathematical model when numerically estimating the location of the magnetic field source (MFS).

The system (100) may include a relative pose measurement system and/or a navigation module configured for determining (e.g., measuring) two or more orientations of the magnetometer (106) at the two or more measurement locations in three orthogonal dimensions (3D orientation); and the microprocessor (110) may be configured for numerically estimating the location of the magnetic field source in the three orthogonal dimensions (3D) using a combination of:
a) the two or more magnetic field measurements;
b) the two or more measurement locations;
c) the mathematical model representing the dipole of the magnetic field source; and
d) the two or more magnetometer orientations.

The magnetometer (106) may include a total magnetometer configured to measure a total scalar value of the magnetic field (b) at the measurement location, regardless of its direction.

The magnetometer (106) may include vector magnetometer configured to measure a scalar value of the magnetic field in one to three of the three orthogonal dimensions (3D), and the two or more magnetic field measurements may be non-coherent vector magnetic field measurements.

The magnetometer (106) may include a coherent vector magnetometer configured to measure a phasor value of the magnetic field in three orthogonal dimensions (3D), and the two or more magnetic field measurements may therefore be phasor magnetic field measurements, including a recorded relative phase between the orthogonal components.

The system (100) may include at least one marker apparatus (102) substantially adjacent to, coupled to or incorporated into a drill bit or a drill string.

The system (100) may include at least one marker apparatus (102) that includes or forms a blast initiation device or blast primer device for initiating blasts in commercial blasting operations.

The system (100) may include at least one marker apparatus (102) buried in a selected location in the opaque medium (104) relative to and/or adjacent to and/or above explosive material.

The system (100) may include at least one marker apparatus (102) incorporated respectively into the seismic receivers (902) (hydrophones/geophones) and/or the seismic sources (904) (blasting devices).

The system (100) may include at least one marker apparatus (102) buried in broken rock (e.g., in a heap).

The system (100) may include at least one marker apparatuses (102) buried adjacent to or in an ore body (e.g., down a borehole).

The mobile platform (108) may include the mobile magnetometer and/or a wireless receiver configured for receiving wireless encoded/modulated data signals from devices in/on the opaque medium (104). The mobile platform (108) may include at least one optical/thermal camera configured to capture images from the mobile platform (108) while the mobile platform (108) travels along a path and makes the magnetic field measurements.

The system (100) may include at least one marker apparatus (102) buried in a selected location in the opaque medium (104) relative to and/or adjacent to and/or above a linear utility (e.g., a pipeline/powerline) in the opaque medium (104).

The marker apparatus (102) can include one or more environmental sensors configured to detect, monitor, estimate, or measure physical parameters of the surrounding portion of the opaque medium (104), and the environmental sensors may include temperature sensors and/or moisture sensor (e.g., for soil monitoring).

The system (100) may include at least one marker apparatus (102) incorporated into a marker beacon for mountain workers or engineering workers, e.g., attached or incorporated in clothing, modified ski passes/access tags, and/or smartphone cases/power banks.

The system (100) may include an uplink channel between the marker apparatus (102) and the magnetometer (106) for transferring the one or more orientations of the magnetic field source (MFS) from the marker apparatus (102).

In one or more implementations, the marker apparatus (102) may include an accelerometer (818) and/or a magnetometer (820) configured to measure an orientation of the magnetic field source (MFS) when stationery relative to Earth's gravity and/or the Earth's magnetic field (or “geomagnetic field”).

Accordingly, disclosed herein is a marker apparatus (102) for localizing buried objects, the marker apparatus (102) including:
a) an accelerometer (818) and/or a magnetometer (820) configured to measure an orientation of a magnetic field source (MFS) of the marker apparatus (102) when stationery relative to Earth's gravity and/or the Earth's magnetic field (or “geomagnetic field”); and
b) the magnetic field source (MFS) (e.g., including a through-the-earth (TTE) or magnetic induction (MI) transmitter with a transmit antenna) in the marker apparatus (102) configured to transmit a signal representing the measured orientation to a receiver (with a receive antenna) through a medium (104) (in which the marker apparatus (102) is stationery, which may have a surface, e.g., including earth/rock/ice/water, including to a vehicle-borne magnetometer, which may be in or outside the medium (104)) such that the measured orientation can be used to estimate (including by calculation) a location of the marker apparatus (102) in three orthogonal dimensions (3D).

Thus the marker apparatus (102) can communicate the orientation of the magnetic field source (MFS) (which may be fixed to the orientation of the marker apparatus (102)) via modulation of the magnetic field (b) and/or by the uplink signals (which may be in a different channel) such that the magnetic field shape is not changed in ‘orientation’, merely the receiver, and therefore mathematical model, is informed of the orientation in space reducing unconstrained variables when using the mathematical model. The data link may be formed by modulation of the magnetic field (b) used for localization, and/or at a different frequency/channel.

In addition, disclosed herein is a marker apparatus (102) for localizing buried objects, the marker apparatus (102) including:
a) an accelerometer (818) and/or a magnetometer (820) configured to measure an orientation of a magnetic field source (MFS) of the marker apparatus (102) when stationery relative to Earth's gravity and/or the Earth's magnetic field; and b) a microcontroller (806) configured to control the magnetic field source (MFS) in the marker apparatus (102) based on the measured orientation of the magnetic field source (MFS) such that the magnetic field source (MFS) generates a magnetic field
(b) with a selected orientation (e.g., such that the generated magnetic field (b) is equivalent to that of an overall/resultant magnetic dipole that may be vertical) (without a mechanical self-righting mechanism in the marker apparatus (102)).

### BRIEF DESCRIPTION OF THE DRAWINGS

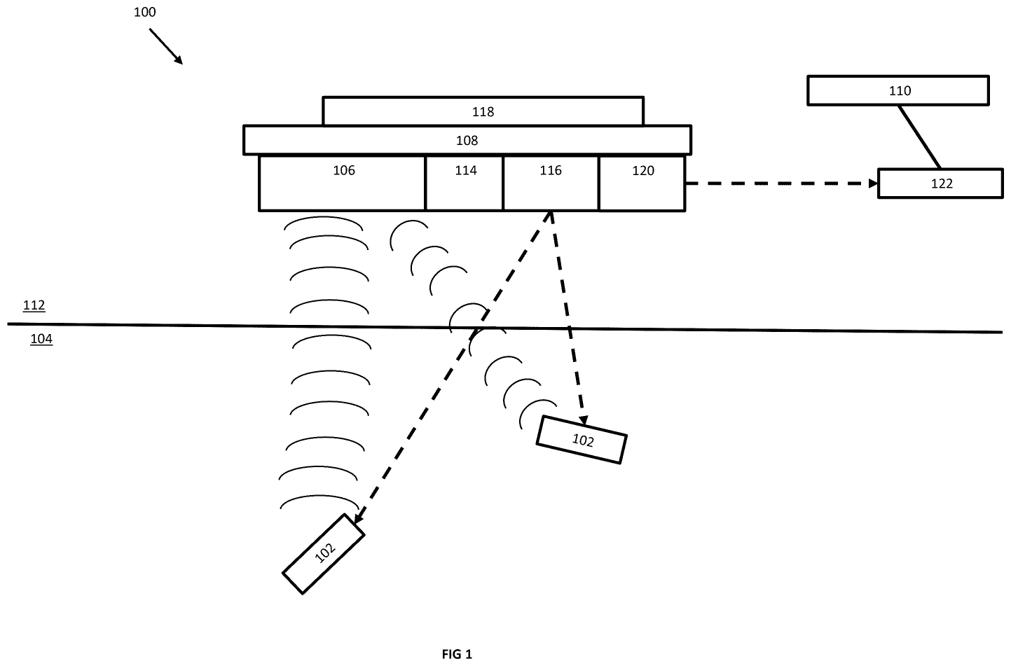

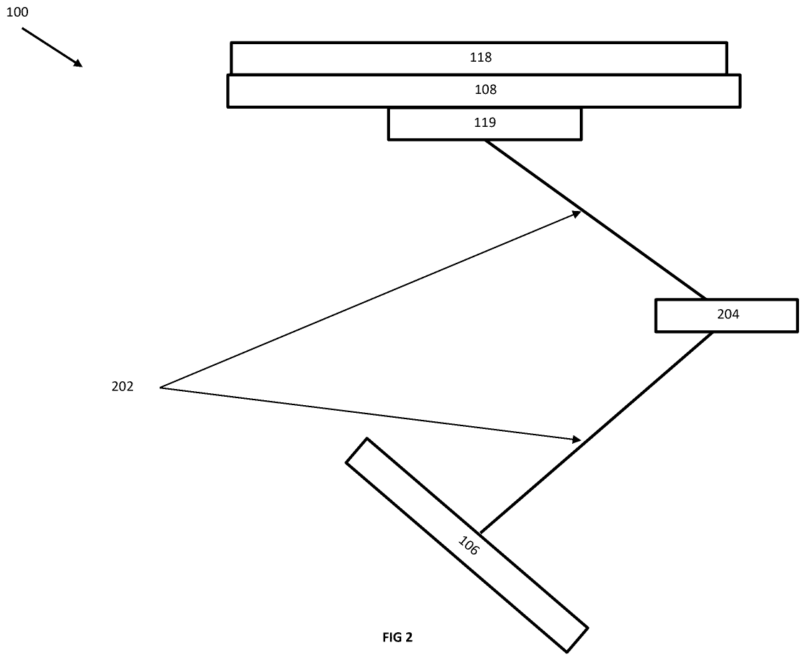

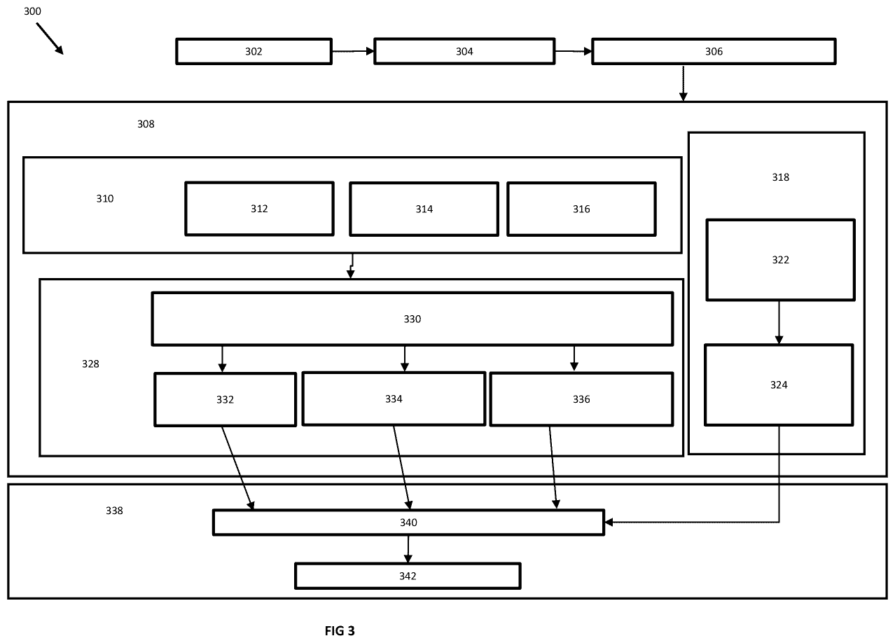

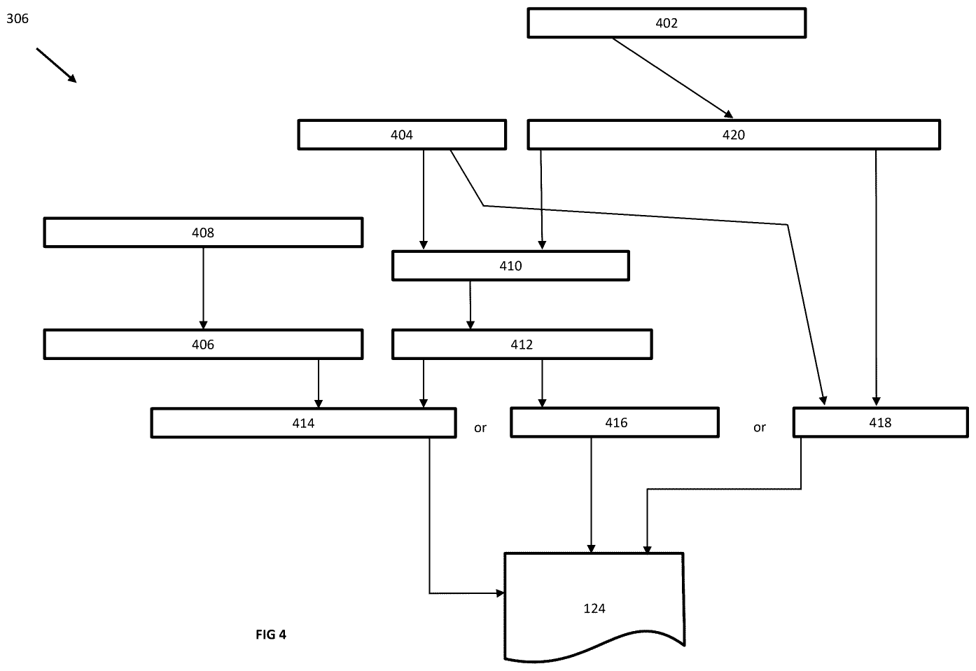

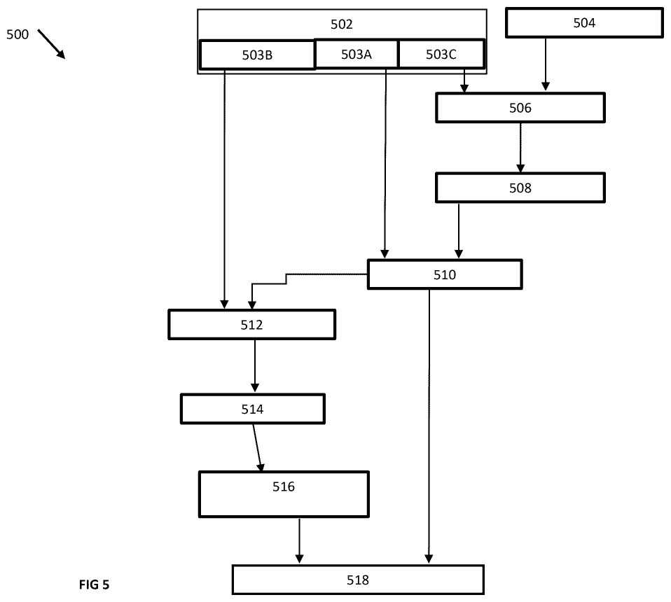

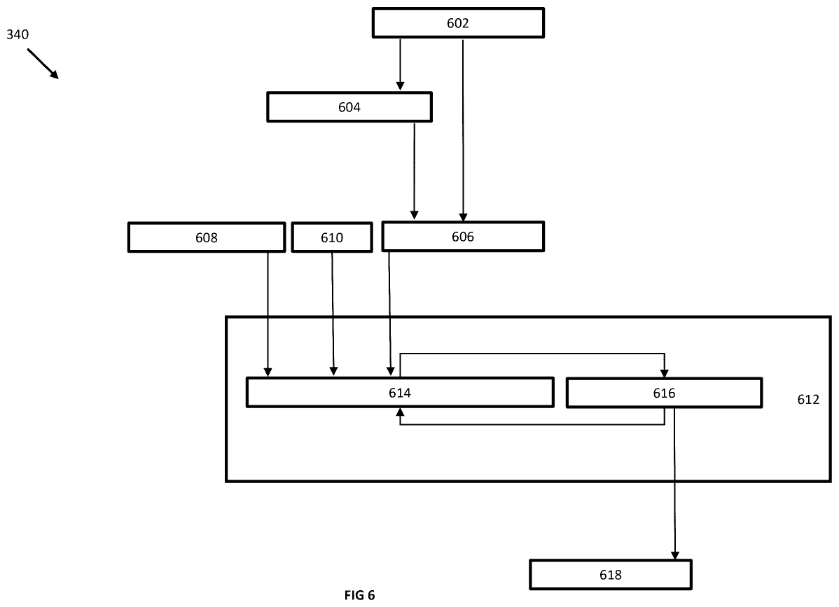

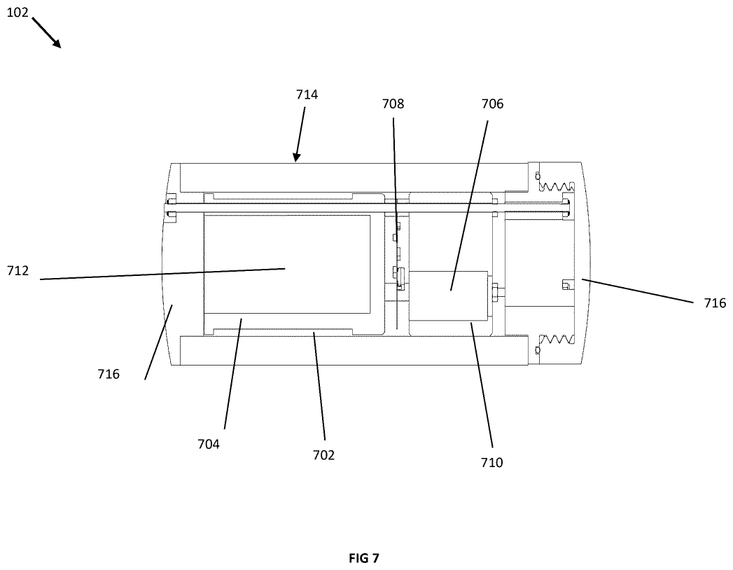

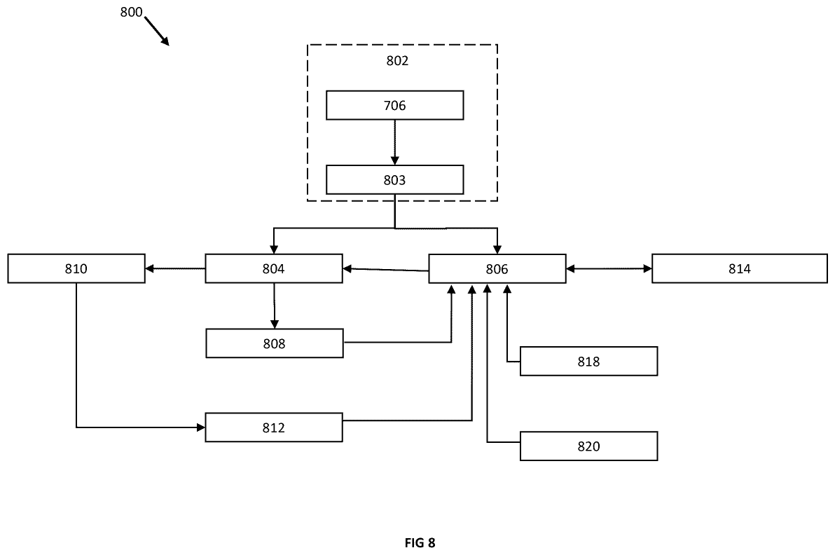

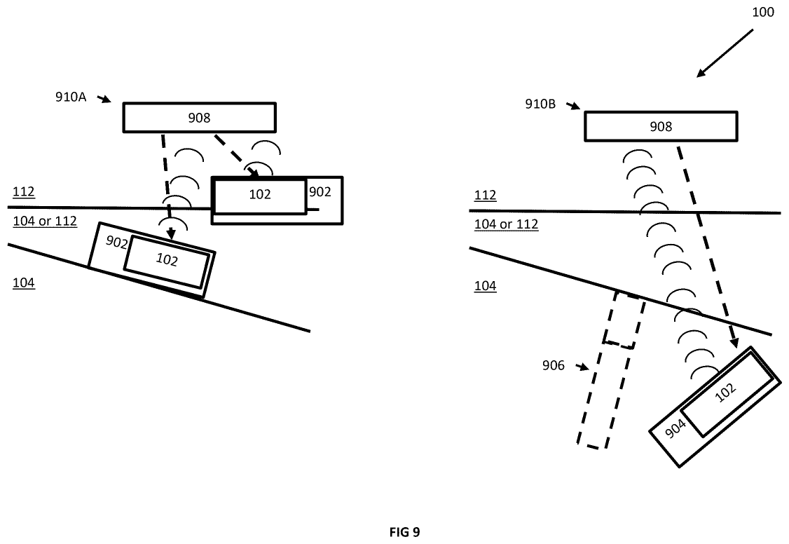

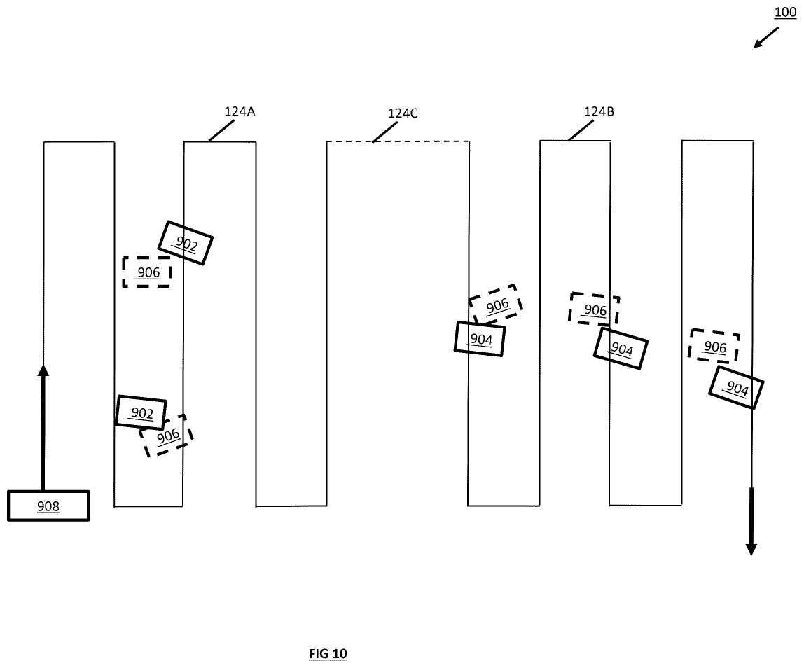

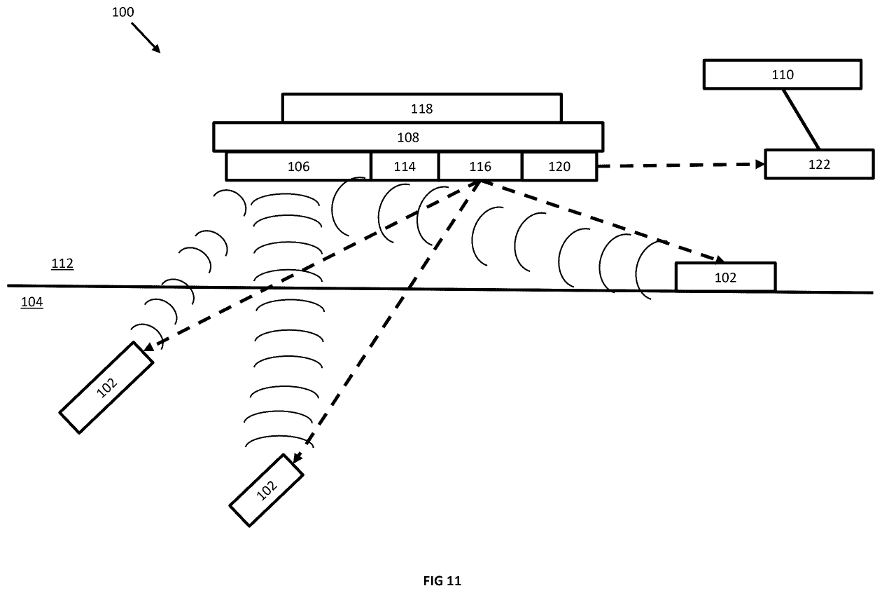

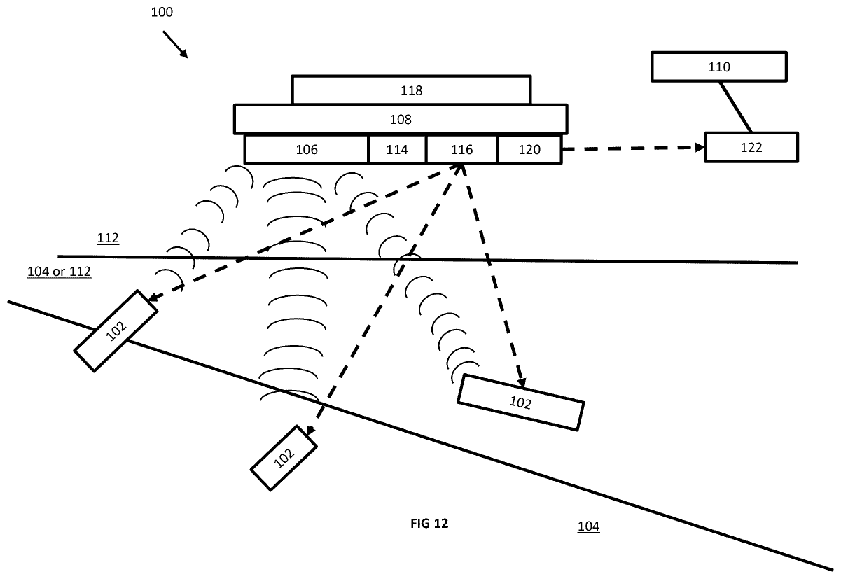

Some embodiments of the present invention are hereinafter described with reference to the accompanying drawings in which:
a) FIG. 1 is a side-view schematic diagram of a system for localizing buried objects in which dashed lines represent wireless signals and lines of curves represent detectable magnetic fields;
b) FIG. 2 is a side-view schematic diagram of a mobile platform of the system including a knee;
c) FIG. 3 is a flow chart of an overall process performed by the system;
d) FIG. 4 is a flow chart of a path generation process of the overall process;
e) FIG. 5 is a flow chart of a data reduction process of the overall process;
f) FIG. 6 is a flow chart of an inversion process of the overall process;
g) FIG. 7 is a sketch of a marker apparatus of the system;
h) FIG. 8 is a block diagram of electronic components of the marker apparatus;
i) FIG. 9 is a side-view schematic diagram of the system configured for a partially underwater (or “transition zone”) seismic blasting application;
j) FIG. 10 is a plan-view schematic diagram of a path of magnetometer over a medium with a plurality of marker apparatuses;
k) FIG. 11 is a side-view schematic diagram of the system configured for an on-land seismic blasting application; and
l) FIG. 12 is a side-view schematic diagram of the system configured for an underwater (or “transition zone”) seismic blasting application.

### DETAILED DESCRIPTION

Described herein are a system (100) and a process (300) for localizing objects, including for locating marker apparatuses (102) that are stationery (which includes being buried/submerged) in, and/or seated/placed on, an opaque (non-transparent) medium (104) that can include a mixture of materials. This locating of the marker apparatuses (102) includes determining their locations in three orthogonal dimensions, thus determining “3D locations”. This locating of the marker apparatuses (102) may be referred to as “remote localization”, “remote marker localization” or “wireless marker localization” because the locations are measured/detected remotely, using generated magnetic fields (b) and magnetic induction (MI) signals (referred to herein as “MI signalling” or “uplink signals” or equivalently “MI uplink signals”) that penetrate through the medium (104), without needing to physically/electrically contact/touch the marker apparatuses (102); similarly, the marker apparatuses (102) may be referred to as “wireless markers” and/or “remote markers”. The generated magnetic field is a vector field denoted by the symbol “b” herein for consistency with the pseudocode in the Appendices; however, the generated magnetic field could analogously be denoted by the symbol “B” or the symbol “H” herein, including in bold type, since a skilled addressee in the field of electromagnetics would understand that the magnetic field strength field (H), measured in ampere per meter, and the magnetic flux density field (B), measured in tesla, are closely related vector fields, equal in direction and proportional in magnitude. The system (100) and the process (300) may be referred to as providing “magnetic tracking/localization”, “dipole tracking/localization” and/or “radiolocation” because the localization is based on using the generated magnetic fields (b) and the uplink signals. The generated magnetic field (b), at least when it is detectable, may referred to as a “localization signal”. The system (100) and the process (300) may be referred to as providing “position tracking” or “position and orientation (P&O) tracking”, e.g., if a portion of the medium (104) containing the marker apparatus (102) moves, thereby carrying the marker apparatus (102). The system (100) and process (300) use the generated magnetic fields (b) and the uplink signals, which include or are quasi-static magnetic fields substantially in the near-field region or zone (or substantially in a transition region or zone between the near-field and the far-field) of the stationery marker apparatuses (102) defined by wavelengths of the generated magnetic fields (b) and the uplink signals, and by skin depths of the medium (104) as described hereinafter. In mining/quarrying operations, the marker apparatuses (102) may be referred to as “ore markers” because they may be buried adjacent to or in an ore body, and the marker apparatuses (102) may be used for tracking ore during blasting, excavation and/or processing. In heap leaching operations, the marker apparatuses (102) may be referred to as “movement markers”, “monitoring sensors”, and “primers”. In operations marking buried objects, including pipelines/powerlines or explosive initiators/primers, the marker apparatuses (102) may be referred to as “markers” or “leakage sensors” for pipelines: or, if the marker apparatuses (102) include the explosive initiators/primers as attachments or in a shared housing/shell/unit, the marker apparatuses (102) may be referred to as “marker components” or “radio modules”. In operations tracking drills and drill-bit portions, the marker apparatuses (102) may be referred to as “drill trackers” or “attachments” or “components” of the drill bits or drill strings. In seismic exploration operations, the marker apparatuses (102) may be referred to as “attachments” or “components” of the seismic sources and/or seismic receivers. In soil monitoring operations, the marker apparatuses (102) may be referred to as “attachments” or “components” of the soil sensing devices. In emergency operations, the marker apparatuses (102) may be referred to as “trackers” or “beacons” worn by or attached to a person or piece of equipment. In civil engineering and construction operations, the marker apparatuses (102) may be referred to as “markers”, “trackers” or “beacons” worn by or attached to a person or piece of equipment, or attached to or embedded in the structure. In geological, seismological or construction monitoring, the marker apparatuses (102) may be referred to as “markers”, “trackers” or “detectors” or “monitors” that are seated/placed on, attached to, or embedded in the rock, earth, foundations or structures to determine movement over time.

### System (100)

As shown in FIG. 1, the system (100) described herein includes:
a) the at least one marker apparatus (102) configured to be buried/submerged and remain stationary in or on a portion of the opaque medium (104) (which can be an opaque or a non-transparent medium, including a mixture of materials) at the marker location, the marker apparatus (102) including a magnetic field source (MFS) configured to generate the magnetic field (b) and to generate the uplink signals (which may include by modulating the magnetic field (b));
b) at least one magnetometer (106) (also referred to as a “magnetic field/flux sensor”), which include a “mobile magnetometer” and/or a “fixed magnetometer”, configured to detect the magnetic field (b) and the uplink signals, and to measure the magnetic field (b) (transmitted through the opaque medium (104) and/or a navigable medium (112)) at each of the two or more measurement locations (which may also be referred to herein as “stations” or “measurement stations”, which are mutually and substantially different measurement locations relative to the marker location), thus generating at least one magnetic field value at each of the two or more measurement locations;
c) at least one mobile platform (108), e.g., a vehicle, configured to move/carry the at between the measurement locations, including moving/carrying the at least one magnetometer (106) while it measures the magnetic field (b), i.e., in order to make the magnetic field measurements while continuously moving (including keeping a speed of the at least one magnetometer (106) substantially above zero meters per second) along a path; and
d) at least one data processing unit or digital microprocessor (110) configured to estimate the marker location in three orthogonal dimensions (3D) based on: the measurements of the magnetic field (b) from the marker apparatus (102): the measurement locations; and at least one predefined mathematical model representing a magnetic dipole of the magnetic field source (the mathematical model including modelled magnetic field strengths from the model magnetic dipole at modelled measurement locations in 3 mutually orthogonal directions).

The system (100) and process (300) measure the magnetic field (b) produced by the marker apparatus (102), and then infer the position of the marker apparatus (102) from the shape and strength of that magnetic field (b). The system (100) is configured to determine the 3D position of each magnetic field measurement (based on the 3D position of the magnetometer (106) making the measurement of the magnetic field (b)) in a frame of reference, e.g., in a global frame of reference. Thus the system (100) is configured to identify 3 orthogonal spatial values in the 3 mutually orthogonal directions (e.g., in Cartesian coordinates or in spherical coordinates) for each magnetic field value.

The magnetometer (106) may include a scalar magnetometer that measures a total/absolute magnetic field value of the magnetic field (b) at each measurement location. The magnetometer (106) may include a non-coherent vector magnetometer or a coherent vector magnetometer (or “phasor magnetometer”) that measures a directional/vector magnetic field value (in 3D) at each measurement location. With a vector magnetometer, the system (100) is configured to determine the 3D orientation of each magnetic field measurement (based on the 3D position and orientation of the magnetometer (106)), in the frame of reference, in addition to determining the 3D position of each magnetic field measurement: thus, in this configuration, the system (100) may identify a minimum of 6 values, including in the 3 mutually orthogonal directions and in 3 mutually orthogonal orientations (pitch, roll, yaw), for each measurement location. When configured to measure the value of the magnetic field in the three orthogonal dimensions (3D), the vector magnetometer may be referred to as including a “triaxial” sensor since it senses the magnetic field along three orthogonal axes. The coherent vector magnetometer (“phasor magnetometer”) is a vector magnetometer that also measures/records phase differences between the two or more orthogonal components of the measured generated magnetic field (b) (but not necessarily relative to the magnetic field source (MFS)), and these phase differences (also known as “phase reference information”) are recorded (by a data acquisition (DAQ) component (114) described hereinafter) between the different orthogonal axes at each measurement location: the phasor component is thus a reconstruction from a series of instantaneous samples of the magnetic field (b), recorded by the DAQ component (114), e.g., reconstructed via a frequency transformation process (e.g., based on a fast Fourier transform, or a Hilbert transform) or via complex sampling (using a mixer), into a phasor form—this reconstruction is based on the time base of the recorded measurements of the magnetic field (b) at each measurement location, not necessarily the time base of the magnetic field source (MFS), which may be unknown/undetected by the DAQ component (114)/magnetometer (106) unless sent as source phase information in the uplink channel described hereinafter.

The process (300) includes a localization process (338) that solves/applies the mathematical model to effectively determine/estimate three or more unknown values relating to the marker apparatus (102). Since the 3D location of the marker apparatus (102) is unknown, the mathematical model has at least three unknown values in the form of the 3D location. The orientation of the marker apparatus (102) may also be unknown or may be partially unknown (depending on use of an accelerometer (818) and/or a “compass” magnetometer (820) in the marker apparatus (102) described hereinafter), so the mathematical model may also have one or two further unknown values in the form of the magnetic dipole orientation (the magnetic dipole is rotationally symmetric, so at least one orientation direction need not be determined). The magnitude of the magnetic moment (m) of the magnetic field source (MFS), and thus the strength of the magnetic field source (MFS), may also be unknown or known only to within a calibrated range (depending on use of a calibration process (302) described hereinafter), so the mathematical model may also have an additional unknown in the form of the magnetic dipole magnitude/strength. As the process (300) uses the mathematical model for determining the source location (also referred to as “localization” of the source location), the process (300) may be referred to as providing “model-based localization”. As the process (300) determines the source location in 3D without requiring knowledge of previous locations of the MFS, the process (300) can use the magnetic field measurements taken after a blasting operation, including wherein the marker apparatus (102) is in a post-blast muckpile.

The system (100) and the process (300) require a minimum number of measurement locations and corresponding magnetic field values, and this minimum depends on: the type of the magnetometer (106)—which can be scalar or vector or phasor, and whether other measurements/controls can reduce the number of the unknown values relating to the marker apparatus (102), e.g., by controlling or measuring the orientation of the marker apparatus (102) and/or by calibrating the strength of the magnetic field source (MFS). Using the mathematical model to estimate the 3D marker location when there are only 3 unknown values may be referred to as solving for 3 degrees of freedom (DoF): similarly, if there are 5 or 6 of the unknown values, it may be referred to as solving for 5 DoF or 6 DoF. In practice, the system (100) and the process (300) use substantially more measurements than the minimum number, including substantially 10, 100 or 1000 times more than the minimum number, including because the field/locations measurements may have low signal-to-noise ratios (SNRs), and using the substantially more measurements can increase the accuracy of the marker location estimates. In an example, a 10 m by 10 m flight pattern may use substantially 100 field measurements (e.g., approximately 30 3D vector measurements, or 100 scalar measurements); in another example, a wider flight pattern over more space may use substantially 1000 field measurements.

The magnetic field (b) may be modulated, e.g., with at least one carrier frequency (fc) and wavelength, such that it is not merely a DC field but a quasi-static field. The magnetic field source (MFS) in the marker apparatus (102)—and the magnetic dipole in the mathematical model—include alternating current (AC) dipoles that provide a time varying signal or at least one time varying component (e.g., sinusoidal), varying in time according to the carrier frequency (fc), that is detectable by the magnetometer (106) at the carrier frequency (fc). The modulation of the magnetic field (b) may therefore be referred to as including “AC modulation”. The carrier frequency (fc) is selected during construction of the marker apparatus (102), or in an encoding process (304) or in a CHANNEL SELECT process (312) as described hereinafter. The carrier frequency (fc) may include one or two selected carrier frequencies (fc), or set of carrier frequencies within a defined range, e.g., within an available range for a channel as described hereinafter. The use of the carrier frequency (fc) by the marker apparatus (102) allows the magnetometer (106) to detect/measure the magnetic field (b), including its strength and optionally direction and phase (depending on the type of magnetometer), using a demodulation process based on the carrier frequency (fc), and this demodulation process can provide a significant mitigation of magnetic noise in the recorded magnetic field measurements.

In a path generation process (306) described hereinafter, the measurement locations may be selected to be substantially within a near field and/or within one wavelength of the marker location at the TTE frequencies along the path. In some applications, the system (100) is configured such that the magnetometer (106) detects the generated magnetic field (b) within 3 meters (m), or within 8 meters (e.g., for mines with shallow flitches), or within 13 meters (e.g., for a higher bench/muckpile), or within 50 meters, or within 100 meters. The system (100) may be configured such that the magnetometer (106) can measure the magnetic field (b) within substantially 1 m of the boundary/surface of the medium (104), or more than 1 m distance from the boundary/surface, or within 1 m to 10 m of the boundary/surface, or between 10 m and 100 m of the boundary/surface, e.g., for the magnetometer (106) on the mobile platform (108) to reliably clear a muckpile in a blasting application. Different distances between the marker apparatus (102) and the magnetometer (106) may have different preferred inversion processes (described hereinafter) when numerically estimating the source location using the mathematical model: e.g., when using the coherent vector magnetometer, at shorter distances there may be good recovery of the phase information, so a coherent vector inversion process may provide the most accurate fix, and at greater distances the signal level may be too low for accurate phase reconstruction, so a total field inversion process may be more accurate

In the path generation process (306), the measurement locations forming the path are selected to be mutually spaced such that the magnetic field (b) can be substantially mapped, and at least a plurality of the measurement locations may be preferably not collinear or coplanar. In the path generation process (306), the measurement locations may be selected to be sufficiently close to the likely marker location such that they detect sufficient field strength (b) to be within the magnetic field detection range of the magnetometer (106), while still being substantially mutually separated, e.g., circumferentially around a likely location of the marker apparatus (102). The magnetic field detection range of the magnetometer (106) may be defined by a minimum signal-to-noise ratio (SNR) of the (modulated) magnetic field (b) detected by the magnetometer (106). The path may be have a square-function shape, e.g., as shown in FIG. 10, to cover all marker apparatuses (102) in the area under/above the path, or the path may have an irregular shape, e.g., selected by a remote pilot controlling the mobile platform (108), such that the regions of interest are reasonably well covered. The path may be selected, either in advance or by the pilot/controller while moving, such that the region of space where the signal is detectable (i.e., the SNR is above the minimum threshold described hereinafter) is sampled out to its X, Y and Z extents, and throughout.

The system (100) and process (300) can work without line-of-sight because the magnetic field (b) can pass through the non-transparent/opaque medium (104) that substantially attenuates/blocks electric fields and electromagnetic waves that could be practically generated by the marker apparatus (102) due to the dimensions/size of the marker apparatus (102), and the modulation wavelength of the magnetic field (b) is substantially greater, including orders of magnitude greater, than the dimensions/size of the marker apparatus (102).

As shown in FIG. 1, the at least one marker apparatus (102) can include a plurality of marker apparatuses (102).

In use, the at least one marker apparatus (102) is arranged, placed, dropped, or embedded to be substantially stationery (e.g., on/buried/submerged) with respect of the non-transparent medium (“opaque medium (104)”). The non-transparent medium (104) generally includes materials that substantially inhibit/block visible and radio-frequency radiation, including ore, rock, broken rock, stone, rubble, debris, gravel, cement, stemming material, soil, dirt, sand, clay, mud, sediment, snow; ice, hydrocarbon fuel reservoirs, civil infrastructure, building materials, construction materials, earth, coal, stockpiles of ore/waste, tailings, landfill, concrete (including in civil engineering structures, e.g., in dam walls), foliage and/or tree cover. The non-transparent medium (104) may include substantially fluid/liquid materials including water, e.g., for undersea applications.

As described hereinafter, the navigation module (118) can include a global navigation satellite system (GNSS) receiver and INS navigation system, and/or a Light Detection and Ranging Simultaneous Localization and Mapping (LiDAR SLAM) system. The LiDAR SLAM system may be used by the mobile platform (108) to measure the position of its surroundings, navigate through them, and avoid collisions, thus generating position and orientation as described hereinafter, and may assist with flight underground and near bench/muck surface an high walls (where a pilot would not have good visual line of site), and the LiDAR SLAM can be georeferenced to GNSS when above ground. The remote location tracking system, which tracks the path of the marker apparatus (108) (and thus the magnetometer (106) with respect to time), may include two or more optical cameras, reflective laser targets or radar targets, or sonar systems for underwater vehicles.

### Marker Apparatus (102)

As described hereinbefore, the magnetic field source (MFS) can be configured and controlled to generate the magnetic field (b) with the magnetic-field modulation, for detection by the magnetometer (106) and for corresponding demodulation and recording by the magnetometer (106)/DAQ component (114). The magnetic-field modulation can include the AC modulation at the at least one carrier frequency (fc), and the corresponding demodulation—e.g., by the magnetometer (106)/DAQ component (114) can include demodulating based on the at least one carrier frequency (fc). The AC modulation may include frequency-shift keying (FSK) using previously available FSK methods. The magnetic-field modulation can allow for more sensitive detection of the magnetic field (b), e.g., by allowing rejection/filtering of noise sources based on the demodulation, e.g., rejection of low-frequency (DC) noise and/or high-frequency noise.

In addition, the magnetic field source (MFS) can be configured and controlled to transmit the uplink signals by at least one signal modulation of the magnetic field (b) in addition to the magnetic-field modulation used by the magnetometer (106) for detection/measurement/recording of the strength and direction of the magnetic field (b). The at least one signal modulation can include frequency modulation, phase modulation and/or amplitude modulation, and the corresponding demodulation and recording by the magnetometer (106)/DAQ component (114) can thus include respective frequency demodulation, phase demodulation and/or amplitude demodulation using selected modulation and demodulation processes configured into the marker apparatus (102) and the magnetometer (106)/DAQ component (114).

The signal modulation provides an uplink channel that is defined during the construction of the marker apparatus (102), or in the encoding process (304) or in the CHANNEL SELECT process (312) as described hereinafter. By way of the signal modulation, the uplink signals can transmit information (referred to as “uplink information” generally represented by digital data) from the marker apparatus (102) to the magnetometer (106) that is additional to, and transmitted in parallel with, the magnetic field (b). This uplink information may include:
a) source phase information to allow for improved coherent detection/recordal by the coherent vector magnetometer/DAQ component (114);
b) a unique ID of the marker apparatus (106);
c) measured orientation of the magnetic field source (MFS) from a control/measure MFS orientation process (322) described hereinafter; and/or
d) measurements from one or more environmental sensors (described hereinafter) that detect, monitor, estimate, or measure physical parameters associated with the medium portion which the marker apparatus (102) is deployed; and/or
e) measurements/parameters pertaining to the state of the marker apparatus (106).

The measurements from the environmental sensors, the measurements/parameters pertaining to the state of the marker apparatus (106), and/or the source phase information may be referred to as “arbitrary data” because the values are not known in advance by the magnetometer (106)/DAQ component (114)/microprocessor (110). In contrast, the unique ID of the marker apparatus (106) could be known to the magnetometer (106)/DAQ component (114)/microprocessor (110) because it can be one of a selected set of ID stored/accessed, e.g., in the microprocessor (110). The uplink information can therefore be referred to as including “arbitrary data”, which is data that is not known to the receiver (including the magnetometer (106)/DAQ component (114)/microprocessor (110)), so the arbitrary data must be decoded/demodulated rather than just correlated for: the system (100) cannot rely just on correlation for the arbitrary data, but uses decoding/demodulation, which may require a relatively higher level of SNR.

As the magnetic dipole of the marker antenna is rotationally symmetrical about its magnetic axis, it has only 2 orientational DoF.

The magnetic field source (MFS) can be modelled by a magnetic dipole with a single axis.

The magnetic field source (MFS) may include a marker antenna that may be used for:
a) the generation of the (modulated) magnetic field (b);
b) the transmission of the uplink signals; and/or
c) receiving of downlink signals from a MI Tx component (116).

The marker antenna may comprise a single-axis coil antenna (e.g., for a simple/disposable marker) or a multi-axis coil antenna (e.g., for controlling the magnetic field source (MFS) orientation, e.g., synthesising a vertical magnetic dipole, in the control/measure MFS orientation process (322)). With a single-axis antenna, the marker apparatus (102), may be described as a “single axis marker”. Requiring only one magnetic dipole, and thus only one single-axis coil antenna, instead of two or three, decreases complexity of the physical layout in the marker apparatus (102) (e.g., coils fitting inside each other), may avoid the need to multiplex signals from multiple different axes, may avoid the cost of three coils compared to one, may require less power than two or three coils, and may avoid the need for a moving magnetic component in the magnetic field source (MFS), e.g., a spinning magnet, that would be prone to damage (as a moving part).

As shown in FIG. 7, the marker antenna may include a magnetic induction (MI) antenna that includes a coil (702). The coil (702) including many turns of an electrically conductive material (through which an electric current (“electric driving current”) representing the modulated magnetic field (b) and the uplink signals is driven by a coil driver circuit (804), e.g., copper or aluminium wire), with an electrically insulating coating (e.g., a plastic material or enamel material). The coil (702) is configured for transmission by: having a coil diameter that substantially equal to the diameter of the marker apparatus (102), e.g., as large as practically possible inside a shell (714) of the marker apparatus (102); and by drawing a maximum current from a power source (e.g., battery) of the marker apparatus (102) to provide the electric current in the coil (702).

Although, as mentioned hereinbefore, the marker antenna may be used for both transmission (of the uplink signals) and reception (of the downlink signals), the marker antenna may still be configured primarily for transmission rather than reception because the downlink signals are generally easier to detect than the uplink signals and the magnetic field (b) (used for the localization), e.g., since more power and coil diameter may be available for the MI Tx (116) than for the marker antenna in the marker apparatus (102), and since there may be lower noise at the marker location in the opaque medium, e.g., underground, where the marker antenna is located during the communication.

As shown in FIG. 7, the marker antenna may include a bobbin (704) onto which the coil (702) is mounted for mechanical stability. The bobbin (704) includes a low/non-conductive, low/non-permeable material, e.g., a plastic material. The construction of the coil (702) and bobbin (704) may include winding the turns of the insulated conductive material around the bobbin (704).

The marker apparatus (102) includes at least one printed circuit board assembly (PCBA) (708) with electronic components (800) of the marker apparatus (102).

The power source is configured to power the marker antenna by way of the electric driving current. The power source may include a battery (706), e.g., as shown in FIG. 7. For some applications, the battery (706) may include a replaceable battery that fits removably into a battery holder (710) of the marker apparatus (102), e.g., if the marker apparatus (102) is configured to be re-used.

As shown in FIG. 8, the electronic components (800) in the marker apparatus (102) may include:
a) the power source (802), including the battery (706) and a voltage regulator circuit (803) that regulates the voltage from the battery (706);
b) a coil driver circuit (804) powered by the power source (802);
c) at least one microcontroller (806), powered by the power source (802), connected or connectable to a programming input (814) that allows the microcontroller (806) to be configured to control the marker apparatus (102) to operate as described herein;
d) a magnetic field feedback circuit configured to maintain stability of the magnetic field during substantially 100% of the measurement time by the magnetometer: the magnetic field feedback circuit may be in the form of a current sense circuit (808) configured to sense a current from the coil driver (804) and to generate a signal representing the current from the coil driver (804), wherein the current sense circuit (808) is electrically connected to the coil driver (804) and to the microcontroller (806) to transmit the value of the current to the microcontroller (806)—alternatively, the magnetic field feedback circuit may include a magnetic sensor that measures the generated magnetic field strength from the antenna (in the form of the coil 702) and transmits a signal representing fluctuations in the generated magnetic field strength to the microcontroller (806) to stabilise the current to the marker antenna in the form of a negative feedback loop;
e) a transmit/receive component (810), driven by the coil driver (804) when the marker apparatus (102) is transmitting, and connected to the marker antenna, and configured to control the marker antenna to be in either a transmit mode (to transmit the uplink signals) or a receive mode (to receive the downlink signals); and
f) a downlink MI receiver (Rx) (812) configured to receive the downlink signals from the marker antenna via the Tx/Rx component (810) when in the receive mode.

The power source (802) provides sufficient voltage and current to power the other electronic components (800), e.g., substantially 3 to 21 volts (V), or at least substantially 0.5 V and/or no more than substantially 100 V. The programming input (814) may include an electrical connector (e.g., a plug) or a wireless interface (e.g., an infrared or near-field communication (NFC) interface that is configured to provide communication between the microcontroller (806) and the blast encoder.

The coil (702) may have an average diameter of between 0.01 m and 0.3 m, which can corresponding to a diameter of a borehole. The marker antenna can be driven at substantially or approximately 3 watts (W).

In some implementations, the marker apparatus (102) may include a mechanical self-righting mechanism in the form of a weighted gimbal that naturally aligns the marker antenna to a preselected orientation (e.g., vertically) due to the force of gravity while the marker apparatus (102) remains stationary. In these implementations, the marker apparatus (102) includes an inner shell (with a weight at one end) that is free to rotate in at least 2 orthogonal directions in an outer shell such that the magnetic dipole settles into preselected orientation (due to placement of the weight), e.g., a vertical orientation, by the force of gravity. However, as described hereinbefore, such mechanical self-righting marker apparatuses may be undesirable in some applications, e.g., for being complicated to manufacture and/or prone to damage.

As shown in FIG. 8, the marker apparatus (102) may include the accelerometer (818), and optionally the “compass” magnetometer (820), and these are configured to measure the orientation of the marker apparatus (102), which is stationery, relative to Earth's gravity and/or the Earth's magnetic field (or “geomagnetic field”). By measuring the gravity vector, the marker apparatus (102) detects the component of the moment in the direction of gravity, and the associated magnetometer (820) in the marker apparatus (102) (which may be referred to as a “compass”) generates complimentary information by detecting the direction of the Earth's magnetic field. By detecting both gravity and the Earth's magnetic field together, the accelerometer/magnetometer (818,820) provide complete orientation information (as long as they are not in the same direction, which would be unusual).

The accelerometer/magnetometer (818,820) are connected to the microcontroller (806) to provide the orientation measurements of the magnetic field source (MFS) to the microcontroller (806). The microcontroller (806) is configured to use these marker orientation measurements:
a) in the control/measure MFS orientation process (322), to control the magnetic source in the marker apparatus (102), and if the magnetic field source (MFS) includes three orthogonal single-axis antennas, to generate the magnetic field (b) with a selected axis, e.g., a vertical axis, which reduces the number of unknown values in the mathematical model (the marker apparatus (102) may in this case be referred to as a “non-mechanical self-righting marker” or “an electronically self-righting marker”); and/or
b) in a transmit MFS orientation process (324), transmit the marker orientation measurements to the microprocessor (110), via the uplink information, to allow the use of the marker orientation measurements in the numerically estimating of the source location using the mathematical model, which reduces the number of unknown values in the mathematical model.

In the control/measure MFS orientation process (322), controlling the magnetic field source (MFS) to generate the magnetic field (b) with a selected axis includes: (i) the microcontroller (806) receiving the marker orientation measurements, so the microcontroller (806) can determine a direction in the global frame of reference that the microprocessor (110) will be prepared for; and (ii) the microcontroller (806) performing a control process predefined in the microcontroller (806) to control the relative phases and amplitudes of the three driving currents for the three orthogonal single-axis antennas.

In the control/measure MFS orientation process (322), the controlling of the magnetic field source (MFS) to select the direction of the generated magnetic field (b) need not require the “compass” measurements if the moment vector is selected to be in the same direction as the gravity vector (since the heading would not matter); however, the “compass” magnetometer (820) allows synthesis of the magnetic moment in any direction, which may be preferred, e.g.:
a) signal strength from a horizontal dipole is greater than a vertical dipole under some conditions (when the ground has some skin-depth attenuation);
b) noise may be different in different directions; and
c) some of the inversion processes, described hereinafter, might converge better for one orientation compared with others.

In the transmit MFS orientation process (324), just sending the orientation from the accelerometer (818) without using the “compass” magnetometer (820) reduces the unknowns in the mathematical model, so can improve the processing efficiency/accuracy, but the processing efficiency/accuracy can be further improved by also sending the orientation from the “compass” magnetometer (820). Using just the accelerometer orientation eliminates one degree of freedom (“elevation” angle known), which may be beneficial, and using both the accelerometer and “compass” orientation eliminates two degrees of freedom (“heading” and “elevation” angles known), which may be more beneficial. If the magnetic axis of the magnetic field source (MFS) is controlled to be vertical (thus forming a VMD), using just the accelerometer orientation eliminates two degrees of freedom, so the compass orientation measurement may not be needed; however, if the magnetic axis is other than vertical, the accelerometer orientation eliminates only one degree of freedom, and the “compass” orientation is required to eliminate to degrees of freedom.

The localization process (338) includes receiving the one or more orientations of the magnetic field source (MFS) from the transmit MFS orientation process (324). The localization process (338) also includes receiving a strength of the moment (m) of the magnetic field source (MFS) if available, e.g., in calibration data from the calibrate MFS process (302).

The accelerometer 818 and the “compass” magnetometer (820) could be mounted in the marker assembly (102) by the addition of at least one MEMS integrated circuit to the PCBA (708), e.g., near the microcontroller (806) and connected thereto, and to the electronic components (800). One integrated circuit may include the accelerometer 818 and the “compass” magnetometer (820), or there may be an integrated circuit for each.

Each marker apparatus (102) may be configured or configurable to store/include its unique ID (which is at least a quasi-unique ID), e.g., in the memory of the marker apparatus (102), e.g., in the microcontroller (806). The ID can be stored/written/hardcoded/configured into the marker on manufacture, and/or stored/written/soft-coded by the blast encoder during the encode markers process (304), and/or in the downlink commands described hereinafter in the downlink processes (310). The marker apparatus (102) may be configured to transmit its stored ID in the modulated magnetic field (b) and the uplink signals by the modulation thereof, including in the uplink information. The magnetometer (106) and/or the DAQ (114) may be configured to demodulate/decode the modulated magnetic field (b) and the uplink signals—or at least received electronic signals representing the modulated magnetic field (b) and the uplink signals—to determine the ID of each localization signal, and to store the ID in association with the magnetic field measurements and measurement locations from that marker apparatus (102). The microprocessor (110) may include or access a database or list of the IDs of the marker apparatuses (102) in the system (100) that the microprocessor (110) then associates with the estimated markers locations after the estimating the marker locations. By having these IDs for the marker apparatuses (102) in the system (100), the microprocessor (110) can indicate which marker apparatuses (102) in the system (100) have been localized, and can thus determine and indicate if any marker apparatuses (102) in the system (100) have not yet been localized/detected (these are “missing markers”), which may allow the platform (108) to be directed to move along another pattern, e.g., close to expected locations for the missing markers, in an attempt to detect and localize additional IDs.

The marker apparatus (102) can be configured for deployment in a confined space proximate to or in the portion of the physical media. The marker apparatus (102) can have a geometry (including shape and size) configured for deployment in the confined space. The confined space can be a borehole, and the geometry can include: a perpendicular width (e.g., diameter for a circular cross section) that is less that a borehole diameter (open diameter of the borehole); and a (longitudinal) length that can be limited by (i) loading manner and optionally (ii) other borehole contents. The coil (702) is configured based on the size of the marker apparatus (102). The marker apparatus (102) has an electrical power storage capacity associated with the size: for example, the marker apparatus (102) can be sized to fit into conventional boreholes, e.g., having an average diameter of substantially 4 to 6 cm (for a smaller embodiment) or substantially 10 to 20 cm (for a larger embodiment), and the battery (706) can be substantially equivalent to two or four commercially available “AA” size batteries (each of which can have substantially 1000 to 4000 milliampere hours capacity, e.g., substantially 3500 mAh for a lithium AA battery).

In some implementations, the marker apparatus (102) may include components that provide functionality apart from the localization, or can be attached to or incorporated in devices that provide functionality apart from the localization. The marker apparatus (102) may include or form a blast initiator (which can be referred to as a blast initiation device), and/or a blast primer device, for initiating blasts in commercial blasting operations. The blast initiator/primer gives rise to an explosion or detonation. The marker apparatus (102) forming the blast initiator can be positioned in boreholes or blastholes. The downlink commands may include initiation-specific MI signals, and representing enabling/disabling, encoding, querying, (re) programming, (re) synchronizing, and/or controlling operation and/or firing of selected ones of the blast initiators (as part of enabling/disabling, encoding, querying, (re) programming, (re) synchronizing, and/or controlling the operation and/or firing of blast initiators in association with a commercial blasting operation). The marker apparatus (102) can be integrated into an initiation device such that the marker and the initiation device are both within the shell (714). Alternatively, two or more of the marker apparatuses (102) may be configured to reside in two or more blastholes with initiation devices for commercial blasting operations, and/or in auxiliary boreholes located proximate to and separate from the blasthole in which the initiation devices reside. The marker apparatuses (102) can be coupled or attached to the initiation devices. The marker apparatuses (102) and the initiation device, when coupled or attached or integrated, can be configured, during manufacture, to utilize mutually different MI communication channels (including different signal frequency bands or frequencies or multiplexing channel) to mitigate the risk of the modulated magnetic field (b), or the uplink signals or the downlinks signals, causing initiation of the associated initiation device. The marker apparatus (102) can include the one or more sensors (referred to herein as “environmental sensors”) that detect, monitor, estimate, or measure physical parameters associated with the medium portion which they are deployed. The sensors can include a set of sensors configured for sensing selected environmental conditions or parameters, including temperature, moisture, pressure, and/or shock (e.g., for soil monitoring). The marker apparatus (102) can be fixed/attached to a drill bit or drill string configured to underground/rock drilling, e.g., to drill boreholes. The marker apparatus (102) can include or be fixed/attached to seismic initiators/primers and/or hydrophones/geophones (or seismic sources and/or seismic receivers).

### At Least One Magnetometer (106)

The at least one magnetometer (106) may include a plurality of magnetometers, each configured and operating as the magnetometer (106) described herein.

As shown in FIG. 1, the at least one magnetometer (106) (which may also be referred to as including at least one magnetic “sensor”) may include at least one mobile magnetometer that operates in a navigable medium (112) that is separated from the opaque medium (104) by a boundary (which may include a surface of the opaque medium (104)). The plurality of magnetometers may include a plurality of the mobile magnetometers attached to at least one mobile platform (108), which may include a plurality of the mobile magnetometers attached to a plurality of the mobile platform (108), forming a “swarm” of mobile magnetometers operating mutually simultaneously to record the magnetic field measurements. The navigable medium (112) may be space, air or water: e.g., a portion of the Earth's atmosphere, air above an open mine, air in an underground mine, air above a body of water, water adjacent a glacier, or water adjacent a sea bed. The navigable medium (112) may be the same medium/fluid as the opaque medium (104), e.g., water. The generated magnetic fields (b) and magnetic induction (MI) signals (also referred to as the “uplink signals”) penetrate through the navigable medium (112) to reach the magnetometer (106), e.g., as shown in FIG. 1.

The or each magnetometer (106) is configured to measure the strength of the magnetic field in which it lies. By measuring the strengths (and optionally directions and phases, depending on the type of the magnetometer (106)) at the measurement locations, the shape of the magnetic field (b) is determined by the system (100).

The or each magnetometer (106) may include at least one sensor configured to measure the magnetic field at the measurement location, and the process of measurement may include measuring the following, depending on the type of the magnetometer (106):
a) a scalar value of the field (which represents the amplitude (A) of the magnetic field signal, including at a selected modulation frequency);
b) a vector value of the field (which represents the amplitude (A) in 1D, 2D or 3D); and/or
c) a phasor value of the field (which represents the amplitude (A) and the phase (θ) in 1D, 2D or 3D), wherein the phasor is a complex number representing a sinusoidal function whose amplitude (A), angular frequency (ω), and initial phase (θ) are time-invariant.

As mentioned hereinbefore, the or each magnetometer (106)—in combination with the DAQ component (114)—may include:
a) the scalar magnetometer (which may be referred to as a “total field magnetometer”) configured to measure the magnetic field strength without measuring orthogonal components of the magnetic field severally (see the Total Field Inversion Process hereinafter);
b) a ID vector magnetometer (or a “single-axis sensor”) configured to measure the magnetic field strength along a single axis that is optionally fixed relative to the orientation of the magnetometer, e.g., fixed vertically such that it naturally aligns with gravity to have a constant or “fixed” Z/vertical orientation (see the Absolute Value Inversion Process hereinafter);
c) a 2D vector magnetometer;
d) a 3D vector magnetometer—a vector magnetometer with a three-axis sensor configured to measure the magnetic field strength along three mutually orthogonal axes at each measurement location (thus measuring three orthogonal components of the magnetic field) in a global frame of reference;
e) a 1D coherent vector magnetometer (see the Coherent Vector Inversion Process hereinafter);
f) a 2D coherent vector magnetometer; and/or
g) a 3D coherent vector magnetometer.

The scalar magnetic field strength sensor may include a total field magnetometer, e.g., a proton magnetometer or a caesium magnetometer.

The 1D, 2D, or 3D vector magnetic field strength sensors may include a flux gate or an induction coil (or “pick-up coil”) for each axis.

The magnetometer (106) can be 3-axis vector magnetometer configured for detecting magnetic flux in 3 mutually orthogonal axes. Alternatively, the magnetometer (106) can be a single axis magnetometer configured for detecting magnetic flux in 1 axis. The magnetometer (106) can include a coil or loop antenna (referred to as a “receive loop”) with an average diameter of between 0.01 m and 2 m; and the smaller loops may be coils on a ferrite core.

The 3D vector magnetic field strength sensor may include three mutually orthogonal pick-up coils arranged to measure the three orthogonal components of the magnetic field separately. The 3D vector magnetic field strength sensor may include a magnetometer as described in Stoll J, Kordes T, Nollenburg R (2020) “Semi-Airborne Electromagnetics Using a Multicopter”, FastTIMES 25:106-107. The 1D, 2D, or 3D phasor magnetic field strength sensors are configured to measure a magnitude and a phase of each orthogonal component of the alternating magnetic field/flux density of the modulated magnetic field (b), thus measuring a magnitude and a direction (thus a vector in 1D, 2D or 3D) of the alternating magnetic field/flux density of the modulated magnetic field (b) in the global frame of reference. The coherent vector magnetometer may be configured to measure the phase of each component by taking many measurements of the time-varying signal, from which the phase is determined/reconstructed. The coherent vector magnetometer is configured, by construction and calibration, such that any discrepancies in the phase delay on each axis are accounted for.

For the 3D magnetometers, the system (100) can measure all three components (x, y, z) of the magnetic field (b) in a global (absolute) coordinate system, even if the magnetometer (106) wobbles in space.

As shown in FIG. 3, for the vector magnetometers and coherent vector magnetometers, the system (100) controls and/or measures the orientation of the magnetometer (106) at each measurement location so the measurement locations are recorded (in a record mobile magnetometer position process (334)) at the same time as the orientation of each dimension of the magnetometer sensor(s) are recorded (in a record mobile magnetometer orientation process (336)) and at the same time as a record measured magnetic field (b) process (332).

Determining the orientation of the or each magnetometer (106) at each measurement location in the record mobile magnetometer orientation process (336) can allow for:
a) more measurements to improve the accuracy/speed of the use of the mathematical model (including inversion of a forward model as described hereinafter, including allowing for more sophisticated inversion algorithms by enabling algebraic manipulation of the forward model); and/or
b) correction of orientation changes of the magnetometer (106), e.g., due to movement/wobble/orientation change of the magnetometer (106) during operation.

Although the system (100) and process (300) described herein may be used if the marker (102) includes a self-righting mechanism, which potentially reduces the DoF of the magnetic dipole in the mathematical model as described hereinafter, since the system (100) and process (300) do not require finding a signal maximum from the magnetic field source (MFS), nor a specific relative orientation between the magnetic field source (MFS) and the magnetometer (106), the marker apparatus (102) need not include a self-righting mechanism to keep its magnetic dipole in a predetermined orientation relative to gravity, and this allows each marker apparatus (102) to have a random/arbitrary orientation relative to the magnetometer (106), which may be preferable in applications where the orientation of the marker apparatus (102) naturally changes (including partially randomly) due to movement of the medium (104), e.g., during dam wall movement or rock blasting. This allows for simpler marker construction, e.g., not requiring a mechanical self-righting mechanism (e.g., an internal gimbal mechanism as in previous markers) that may be susceptible to damage/misalignment, and/or may attenuate any magnetic field/flux generated by the MFS in the marker apparatus (102). Not requiring a self-righting mechanism may allow the marker apparatus (102) to be constructed simply and inexpensively, which may be desirable for single-use markers, e.g., in blasting applications.

The system (100) and process (300) described herein may also allow for a simpler pattern of the measurement locations compared to previous systems using markers, e.g., a flight path for the mobile platform (108), because the measurement locations do not need to be directly above the marker apparatuses (102) as in previous systems—and the simpler pattern may allow for faster location of multiple markers (102) at the same time, e.g., in experimental examples, up to 15 examples of the markers (102) have been located in a short flight. The simpler pattern may allow for a simpler (and less accurate) control system for the mobile platform (108): e.g., the mobile platform (108) may be manually controlled in an imprecise pattern that does not need to follow a predefined pattern, so long as the magnetometer (106) reaches within its magnetic field detection range of the plurality of markers (102) instead of requiring to travel over the tops of the markers, and instead of requiring to travel through the signal maxima as with previous systems, e.g., mentioned in the background. The system (100) and process (300) described herein also allow for at least one fixed magnetometer to provide measurements from its fixed location that are used in the 3D localization of the marker apparatus (102) because measurements from the plurality of locations can be automatically integrated by the localization process and the fixed magnetometer need not be directly above the marker apparatuses (102) as in previous systems. The system (100) and process (300) described herein allow for the or each mobile magnetometer to be continuously moving while making the magnetic field measurements: the mobile magnetometer can be continuously moving, thus having a non-zero speed a reference frame of a site that includes the at least one magnetometer (106) and the marker apparatus (102)—e.g., a mine frame of reference, or a site frame of reference, or an environment frame of reference. The or each mobile magnetometer is configured to make the magnetic field measurements while its speed relative to the marker apparatuses (102) (on the ground, through the air, or through the water) is substantially non-zero (meters per second) while travelling along its path, including by having a sufficiently short accumulation time (or “integration time”) for making the magnetic field measurements at each “station”/measurement location and a shorter accumulation time is selected for higher travel speeds. The accumulation time is controlled in the DAQ component (114) or in post processing in a separate (e.g., remote) computing system (described hereinafter), e.g., the accumulation time can be substantially 0.5 seconds for a travel speed of up to substantially 3 or 4 m/s.

As mentioned hereinbefore, the at least one magnetometer (106) may include the fixed magnetometer, which has a fixed point as its position. The fixed point is a non-mobile point in a reference frame of the site that includes the at least one magnetometer (106) and the marker apparatus (102), which may be a mine frame of reference, or a site frame of reference, or an environment frame of reference. Being “non-mobile” means a speed of the fixed point is zero in the reference frame. The fixed point may be a preselected 3D position, e.g., from being surveyed in, or a location determined after the magnetic field measurements have been made, e.g., from a schedule of fixed point identifiers and corresponding 3D locations. The fixed magnetometer may be provided by a mobile magnetometer that has been parked or located or attached to, or stationary at, the fixed point. In contrast to the mobile magnetometer, the fixed magnetometer does not need to measure its 3D orientation and 3D location for the system (100) to determine the 3D orientation/location of each magnetic field measurement. For a fixed magnetometer, the measurement locations can be recorded separately and associated with the magnetic field measurements instead of using the record mobile magnetometer position process (334) and the record mobile magnetometer orientation process (336). The system (100) may include the fixed magnetometers to enhance the results from the mobile magnetometers. The fixed magnetometers need not be precisely located relative to the marker apparatuses (102) in advance because the system (100) and process (300) described herein do not require the magnetometer (106) to be at a signal maximum or other predefined location relative to the markers, unlike previous systems, e.g., mentioned in the background. The process of receiving/determining of the two or more magnetic field measurements may thus include using the or each fixed magnetometer, which may mitigate the need to measure the location of the at least one magnetometer (106) while the magnetic field measurements are being made, e.g., because the location of the fixed point can be selected (e.g., surveyed in) or measured before/after the magnetic field measurements are being made.

The system (100) and process (300) allow for the three-dimensional (3D) localization of the marker apparatus (102), thus combined horizontal and vertical localization at the same time and from the same set of measurements.

### Data Acquisition Component (114) and Data Transmission Component (120)

As shown in FIG. 1, the system (100) includes the data acquisition (DAQ) component (114) that is configured to: record the magnetic field measurements from the magnetometer (106) at each measurement location, e.g., continuously/repeatedly over time for the duration of the measurement, in the record measured magnetic field (b) process (332); and record the measurement locations (and respective orientations if required by the mathematical model) corresponding to the magnetic field measurements in the record mobile magnetometer position process (334) and optionally the record mobile magnetometer orientation process (336). These location and orientation measurements at each location may be referred to collectively as “pose measurements”. Thus the DAQ component (114) records: the magnetic field measurements; and the measurement locations and optionally the respective measurement orientations.

As shown in FIG. 1, the system (100) includes a data transmission (Tx) component (120) configured for data communication with a data reception (Rx) component (122) that together form a data link to transfer the recorded data from the DAQ component (114) (which include the magnetic field measurements and the location (and optionally orientation) measurements) to the at least one microprocessor (110) for the numerically estimating of the source location, and the estimating of the marker location. The data Tx component (120) is configured for communication with the DAQ (114) and is attached to the mobile platform (108). Depending on implementation, the data Tx component (120) may include transferrable media (e.g., an USB stick) or a cable (e.g., a USB cable or an optical cable), thus the acquired data may be stored locally in the DAQ component (114) and downloaded later—after the movement and measurement processes—via the data Tx component (120). Alternatively, the data Tx component (120) may include communications link between the data Tx component (120) and the data Rx component (122) that is configured to transfer the recorded data while the movement and measurement process 328 is taking place, thus simultaneously/contemporaneously, and the communications link may include a cable connection, e.g., a fibre optic tether (e.g., for an underwater rover), and/or a wireless connection, e.g., a WiFi link. In alternative implementations, the at least one microprocessor (110) may be included on/in the mobile platform (108) such that the localization processes (338) can be executed locally on the mobile platform (108); and the data Tx component (120) and the data Rx component (122) may be configured to transmit the estimated source location and/or marker location, e.g., in real time, to identify the marker locations while the movement and measurement process (328) is taking place.

### Downlink Signals

As shown in FIG. 1, the system may include the MI Tx (116) mounted/attached to the mobile platform (108). The MI Tx (116) may also be referred to as a “downlink transmitter” because it provides “downlink information” to the marker (102) from the rest of the system (100)—and in particular from the mobile platform (108). The MI Tx (116) is configured to transmit the downlink signals (which include wireless downlink signals as described hereinbefore) to the marker apparatuses (102). The downlink signals can travel in any direction from the mobile platform to the marker apparatus (102), not just down: this direction may be upward if the markers are buried in rock/earth above an undergrown mine tunnel in which the mobile platform is moving.

The MI Tx (116) may include at least one loop antenna (referred to as the “downlink transmit antenna”) substantially in a plane perpendicular to an axis that is substantially directed between the mobile platform (108) and the marker apparatuses (106) in/on the opaque medium (104), e.g., when the navigable medium (112) is above the opaque medium (104), the axis may be a substantially vertical axis but not precisely due to wind/movement that forms a vertical magnetic dipole (VMD). The downlink transmit antenna may have substantially vertical axis for some applications, e.g., where the marker apparatuses (106) are substantially below the navigable medium (112), e.g., in a muckpile: in other applications, the downlink transmit antenna may have a substantially horizontal axis, thus forming a horizontal magnetic dipole (HMD), e.g., where some/all markers are substantially horizontal to the navigable medium (e.g., in a bench/quarry face). In other applications, the downlink transmit antenna may include two or more loop antennas oriented at respective mutually different orientations (with respective orthogonal axes), including orthogonally, including at two mutually orthogonal orientations or at three mutually orthogonal orientations, e.g., when the markers are substantially surrounding the navigable medium, e.g., around a shaft/tunnel in an underground mine. The downlink transmit antenna can include a set of electrically conductive coil or loop antennas.

The set of electrically conductive coil or loop antennas can includes an average diameter of between 0.5 m and 5 m, e.g., substantially 1 m.

The downlink transmit antenna can be driven at substantially or approximately 50 watts (W).

The downlink signals include MI downlink signals that can travel a downlink distance (or “downlink range”, which includes TTE) using the one or more downlink MI signal frequencies. The downlink MI signal frequencies can include at least one frequency in the low frequency (LF) ITU frequency band, and/or frequencies between 100 Hz to 1 MHz, between 1 kHz and 10 kHz, between 1 kHz and 1 MHz, between 10 kHz and 300 kHz, or between 20 kHz and 200 kHz, or between 35 kHz and 130 kHz, or between 50 kHz and 100 kHz, e.g., substantially 70 KHz.

The downlink distance provided by the MI Tx (116) and the coil (702) can be at least 10 meters: greater than 100 meters: greater than multiple or many hundreds of meters: up to substantially 500 meters: between 200 and 900 meters; up to substantially a kilometre: greater than a kilometre; and/or or greater than multiple kilometres.

The MI Tx (116) is configured to generate the downlink signals in at least one downlink channel (which is modulation channel defined by a FDM carrier frequency or CDM code or TDM timeslot) that is different from the uplink channel defined by the FDM frequency and/or CDM code and/or TDM timeslot of the uplink signals from the marker apparatus (102), thus allowing simultaneous operation of the downlink channel with the uplink channel. The downlink signals may include at least one downlink frequency that is higher than the frequencies of the uplink signals. The downlink signals include a data component, so higher bit rate may be desirable (higher frequency). In addition, more power may be available on the mobile platform (108) than in the marker apparatus (102), so signal loss due to attenuation of higher frequencies in the medium (104) can be overcome. Higher frequencies may increase signal pickup in the coil antenna (702). In other words, the localization signal (which is in the uplink channel) may work better with a lower frequency signal having correspondingly lower distortion: in some cases, the lower the frequency, the less distortion there is due to the ground (and there may be less variation from simplified models that account only for a homogenous geology); however, lower frequencies mean less bandwidth for data, lower voltages induced in induction loop antennas, and more capacitance required for resonant systems, so to duplex two signals (in the downlink and uplink channels), it can be preferable to have the downlink (which provides no localization, and is data heavy) as the higher frequency and the uplink (which provides localization, and is data light) as the lower frequency. In examples, this difference may be substantially 20 Hz, or it might be substantially 200 Hz or substantially 2 kHz, or substantially 20 KHz.

When the system (100) includes the MI Tx (116), the at least one marker apparatus (102) includes the MI Rx (812) that is configured to receive the wireless downlink signals. The MI Rx (812) is configured to demodulate the downlink signals, and send corresponding downlink commands represented by the downlink signals to the at least one microcontroller (806). The MI Rx (812) and microcontroller (806) are configured to detect a downlink command which may include a preamble with a selected number of cycles of the downlink carrier frequency that the MI Rx (812) is configured to lock to. The microcontroller (806) may be configured to recognise the downlink command based on the quasi-unique code ID stored in the microcontroller (806) (memory of the microcontroller (806)) matching a marker ID sent with the downlink command. The downlink command may include data representing (i) what uplink channel to use; and (ii) how long the marker should remain awake (defining a transmit duration), and/or defining a condition for the marker to return to its low-power state: e.g., transmit localization signal on frequency 7 kHz for 2 minutes.

The downlink commands recognised by the microcontroller (806) may include:
a) a WAKE UP command;
b) a CHANNEL SELECT command; and/or
c) a TRANSMIT TIME command.

In response to the WAKE UP, the microcontroller (806) transitions the marker apparatus (102) from a low-power state to a high-power state, and commences generation of the (modulated) magnetic field (b), optionally after waiting for a selected field generation delay time (which may be defined in the WAKE UP command or in the TRANSMIT TIME command received by the microcontroller (806)) and optionally for a selected field generation duration defined in the TRANSMIT TIME command received by the microcontroller (806). The selected field generation duration may be provided by the microcontroller (806) counting for the selected duration after commencing generation of the magnetic field (b), and then transitioning from the high-power state to the lower-power state, and stopping generating/modulating the magnetic field (b).

The marker apparatus (102) may be configured to be awoken multiple times by two or more WAKE UP commands, including at mutually different locations, e.g., pre-blast and post-blast, or pre-excavation and post-excavation (including detecting the marker apparatus (102) again in a stockpile and again on a conveyor). In block caving, at least one marker apparatus (102) may be buried in an upper portion of the ore body and the movement of the portion can be repeatedly monitored during excavation by repeatedly localizing the marker apparatuses (102).

The demodulation process based on the carrier frequency (fc) that the magnetometer (106) uses to detect the modulated magnetic field (b) can also allow for simultaneous and parallel measurement of two or more magnetic fields (b) from two or more respective marker apparatuses (102) if the carrier frequency (fc) from each marker apparatus (102) is mutually different, or if the respective marker apparatuses (102) are otherwise transmitting on non-overlapping multiplexing channels, e.g., using frequency-division multiplexing (FDM), time-domain multiplexing (TDM) and/or code-division multiplexing (CDM).

To use the multiplexing channels, the magnetometer (106) is configured to detect the modulated magnetic field (b) and the uplink signals from two or more marker apparatuses (102) simultaneously (thus in “parallel”), and the marker apparatuses (102) are configured to use the mutually different (and substantially different) multiplexing channels (e.g., defined by the carrier frequencies (fc) for their modulated magnetic fields (b)).

The selected multiplexing process may include frequency-division multiplexing (FDM), time-domain multiplexing (TDM) and/or code-division multiplexing (CDM), with each marker (102) being configured to use a selected multiplexing channel at manufacture (e.g., by hard coding a multiplexing channel into the marker apparatus (102), e.g., a selected carrier frequency and/or modulation code) and/or during deployment (e.g., by an encoding process described hereinafter), and/or during operation of the process described herein (e.g., by downlink signals in MI transmissions from an MI transmitter (116) of the system (100) described hereinafter).

When configured for FDM, the respective marker apparatuses (102) have respective frequency channels and are configured/configurable to generate their magnetic fields (b) and uplink signals using respective substantially separated carrier frequencies (fc). Each marker apparatus (102) may be configured/configurable to generate the magnetic fields (b) and uplink signals with at least one carrier frequency (fc) such that adjacent markers use mutually different carrier frequencies. The carrier frequency (fc) for each marker apparatus (102) may be selected during manufacture (“hard coded”), including by configuration of the magnetic field source (MFS), e.g., size, inductance, and drive frequency. Alternatively, an available range of carrier frequencies may be set during manufacture, including by the configuration of the magnetic field source (MFS), and the carrier frequency (fc) (within the available range) may be selected during an encode markers process (304) at the site by a person/user/operator or by a robotic deployment apparatus, using an encoder device (e.g., a standard mine-site encoder, also referred to herein as a “blast encoder”) that is configured to transmit a command signal (which may be in the form of a data string) representing the selected carrier frequency (fc) within the available range: the encode markers process (304) occurs prior to or during deployment of the marker apparatus (102) in the medium (104), while the marker apparatus (102) is in electrical communication with the encoder device, or in line-of-sight communication with the encoder device, and before the marker apparatus (102) is attached/seated/placed/buried/submerged on/in the opaque medium (104) and before the marker apparatus (102) enters the low-power state (thus power use is reduced in the marker apparatus (102)). Alternatively, the carrier frequency (fc) for each marker apparatus (102) may be selected during the execute mission process (308) by the MI transmitter (116) sending the CHANNEL SELECT command to the marker apparatus (102) in the downlink signals. The CHANNEL SELECT command instructs the marker apparatus (102) to select a carrier frequency (fc) from the available range, e.g., based on a selected carrier frequency (fc) in the CHANNEL SELECT command and/or a random number generator in the marker apparatus (102) and/or a list of the carrier frequencies (fc) in the available range stored in the memory of the marker apparatus (102). The CHANNEL SELECT command may be transmitted with the WAKE UP command.

The downlink signals may be in any spatial direction, but are always from the mobile platform (108) to the marker (102), and the downlink signals are always wireless signals, travelling by way of the MI transmissions that are wirelessly emitted from the MI Tx (116) attached to the mobile platform (108) and wirelessly received by the marker apparatus (102). The downlink signals provide through the earth (TTE) communications because the MI Tx (116) is configured to generate the MI transmissions with appropriate frequency components to travel substantially into the opaque medium (104).

In some implementations, the system (100) may select the carrier frequencies with reference to the spatial separation of the marker apparatuses (102). In such implementations, a memory of a controller of the system (100)—which may be a microcontroller or a microprocessor on the platform (108) or otherwise in communication with the MI transmitter (116) to control the CHANNEL SELECT command—may include a list of the available channels (based on the available range of carrier frequencies) for the deployed marker apparatuses (102), and the controller of the system (100) may be configured to control adjacent ones of the marker apparatuses (102) in a selected area/volume of the medium (104) to have mutually different channels in the CHANNEL SELECT command such that ones of the marker apparatuses (102) that generate magnetic fields that overlap where the magnetometer (106) is moving can be distinguished by the magnetometer (106), using the demodulation process, because they have mutually different channels.

As a result of the encode markers process (304) or the CHANNEL SELECT command (depending on whether the channels are hard coded or soft coded), the marker apparatus (102) is programmed with channel, e.g., the carrier frequency (fc), to transmit the magnetic field (b) and the uplink signals. The channel may thus be unique to each marker apparatus (102) and may be used to identify which measurements from the magnetometer (106) belong to which marker apparatus (102). The WAKE UP command may include the CHANNEL SELECT command, so the marker apparatuses (102) may wake up in response to the WAKE UP command, and the carrier frequency m may be allocated at this point. The CHANNEL SELECT command may be sent with the TRANSMIT TIME command.

The TRANSMIT TIME command represents the selected field generation duration (also known as the “transmission time”), which may be a duration from the receipt of the TRANSMIT TIME command, to begin transmitting its magnetic field (b), and representing the selected field generation delay time. The field generation duration and the field generation delay time may be selected according to a localization plan for the site. The field generation delay time may be effectively zero, to control the marker apparatus (102) to commence transmitting its localization signal immediately, or the field generation delay time may be at least 1 minute, 1 hour, 1 day or 1 week, e.g., such that the marker apparatus (102) commences transmission of its magnetic field (b) before or after an expected event, e.g., a blast defined by a blasting plan.

The FDM may be sufficient for low-density marker deployments, but higher density deployments may require TDM/CDM if spectrum in the frequency domain within a specific spatial region is exhausted.

When configured for CDM, the marker apparatuses (102) are configured with memory to store and/or receive a channel code representing a plurality of carrier frequencies (using a spread spectrum process), and to modulate the magnetic field (b) and/or the uplink signals according to the channel code, and the CHANNEL SELECT command instructs the marker apparatus (102) to select a channel code instead of just one carrier frequency (fc), and the controller of the system (100) may be configured to select the mutually different ones of the available channels to send in the CHANNEL SELECT commands based on a list of the available channel codes for the deployed marker apparatuses (102).

The modulated magnetic field (b) and the uplink signals may each include the code or identifier (ID) that identifies each marker apparatus (102). When configured for CDM, the respective marker apparatuses (102) transmit the codes or identifiers (ID) to allow the recorded magnetic field measurements to be allocated to the correct marker apparatus (102), including when performing the inversion process (340).

When configured for TDM, the respective markers have respective multiplexing channels by generating their magnetic field (b) and/or uplink signals in respective different time slots selected in the same processes for selecting/setting the carrier frequencies (fc).

In some applications, FDM/CDM may be more desirable than TDM because it may be difficult to maintain a global time (used in TDM) between the plurality of the markers, e.g., when there are many markers buried without communicating for days/weeks/months, e.g., without a downlink providing synchronisation, e.g., in the WAKE UP command or CHANNEL SELECT command. FDM may be more desirable when there is high attenuation of the magnetic field (b) and/or the uplink signals from the markers apparatuses (102) (which can be common in rock/soil/earth and air, e.g., when the magnetometer (106) is operating in the near field region or zone of the marker apparatuses (102)), thus reducing the magnetic field detection range of the magnetometer (106) required for frequency reuse.

The multiplexing process may include FDM, TDM and/or CDM in combination, e.g., a layered stack of a base FDM with slowly modulated (as in several carrier cycles) data/code on top. At a base level, the channels may be split in frequency, but each channel may be shared by mutually different marker apparatuses (102) using respective different codes. The channels may further be spread spatially: as the magnetic field (b) and/or the uplink signals are highly attenuated, pairs of marker apparatuses (102) with matching carrier frequencies (fc) may be separated by distance that is sufficient that the magnetometer (106) does not measure the localization signals from both marker apparatuses (102) in the pair at the same time (or such that the localization signal from one of the pair is below a selected SNR), thus allowing reuse of the spectrum.

In some implementations, the magnetometer (106) may be configured to detect the magnetic field (b) and/or the uplink signals with carrier frequencies (fc) up to substantially 300 kHz, such that the carrier frequencies can span from substantially 1 kHz to substantially 300 kHz, or from at least substantially 0.001 kHz, 0.01 kHz, 0.1 kHz or 1 kHz, or up to substantially 300 kHz, or between 1 kHz and 10 kHz. In some implementations, the magnetometer (106) and the DAQ component (114) have a frequency resolution of at least substantially 1 Hz or at least substantially 10 Hz or 20 Hz, for example by digitising the uplink signals at up to substantially 10 MS/s or up to substantially 100 MS/s. Thus the carrier frequency separation when configured for FDM between adjacent ones of the marker apparatuses (102), or marker apparatuses (102) within the magnetic field detection range of the magnetometer (106), can be substantially 1 Hz, 10 Hz or 20 Hz or greater. In examples with relatively few marker apparatuses (102), the carrier frequency separation can be thousands of Hertz, from 2 kHz to 10 kHz.

### Microprocessor (110)

The at least one digital microprocessor (110) may include one or more processing units that are remote from the measurement locations and that access machine-readable memory with code that controls the processing units to determine/calculate the marker location by executing the localization process (338). The at least one digital microprocessor (11) may include an application specific integrated circuit or a field programmable gate array configured to perform one or more steps of the localization process (338).

The at least one digital microprocessor (110) receives the measurement locations and the magnetic field (b) measurements (and optionally field vectors and phases for the vector and coherent vector magnetometers) that have been recorded/logged by the DAQ component (114).

In some implementations, the at least one digital microprocessor (110) may include at least one processing unit in the DAQ component (114), e.g., for performing one or more of steps of the localization process (338), and/or may include at least one processing unit that is remote from the DAQ component (114) but connected using digital communications (e.g., a wireless data link or a wired data link that is connected after the execute mission process (308)). The remote microprocessor may include a GPU/CPU on a laptop or personal computer, or a server computer, or at least one cloud processor in a computing cloud, e.g., provided by Microsoft Azure or Amazon Web Services.

The digital microprocessor (110) is at least one physically discrete device that may include a microcontroller in the DAQ component (114) that handles the control of the analog to digital converter that accepts the analog information from the magnetometer coils, then logs digitised flux measurement to non-volatile memory, and records the measurements from encoders (119) in the gimbal (if present). The digital microprocessor in the DAQ component (114) may log the stream of data from the navigation module (118), or the navigation module (118) may include its own digital microprocessor with non-volatile memory for logging this stream of data. The data from the DAQ component (114) and the navigation module (118) or the remote location tracking system may be transmitted to the separate computing system for performing the inversion process (340) in “post processing” by another physically discrete set of data processing units/processors configurable or configured to execute stored program instructions and operate upon data in accordance therewith, such as a digital microprocessor, e.g., at least one general processor unit and/or graphics processing unit (GPU). Thus in embodiments there may be at least two physical digital microprocessors. The data reduction process (500) and the inversion processes (340) may be performed after the mission process (308), e.g., using a set of remote data processing units/processors, which may allow for improved GNSS correction, either by using INS data or getting better ephemeris for PPK, compared to relying on real-time correction. Using the at least one remote processor may allow for unconstrained computational power.

### Marker Survivability

The marker apparatus (102) includes the shell (714) that surrounds the magnetic field source (MFS), including the marker antenna, and the electronic components (800), including the power source, e.g., as shown in FIG. 7.

The shell (714) is a housing, case, frame and/or support structure that mechanically houses, carries, protects and/or supports at least pressure and water-sensitive elements of the blasting-related device. The pressure and water-sensitive elements include the device-based electronic elements, including the electronic components (800), e.g., the device power source, the device control unit, and the device-based MI coil driver.

The shell (714) may include a hard shell or housing. The hard shell provides impact protection and/or force dispersion (of any externally applied force to the marker) in order to protect the electronic components (800) and the coil (702) inside.

The shell (714) may also provide chemical resistance and abrasion resistance.

The shell (714) may be substantially formed of a low/non-conductive material and/or low/non-permeable material, e.g., plastic or fibreglass reinforced plastic, e.g., Nylons, POM (Delrin), Fibreglass composites, Polyethylene, and/or Polycarbonate. The shell (714) be extruded or injection molded, and may be machined from an extruded/cast base.

The overall size of the shell (714) is substantially less than the wavelengths in the modulated magnetic field (b), e.g., the maximum length of the shell (714) along any of its axes may be substantially less than the wavelengths, e.g., at least 10, 100, or 1000 times less. Thus the practical size of the marker antenna is much less than the length of the wavelength the magnetic field generated, and the marker antenna can be approximated to be emitting from a point source in the processes described herein. Accordingly, the magnetic dipole model of the marker axis antenna may be substantially accurate.

The shell (714), and thus the marker apparatus (102), may have a substantially cylindrical shape: the shell (714) may include a length of pipe forming a curved wall around the marker apparatus (102); and the ends of the shell (714) may include removably attachable caps (716), e.g., substantially circular caps, e.g., caps with threads for screwing into the pipe, e.g., as shown in FIG. 7. One cap (716) may be manually removable during deployment by a person/operator in order to plug in the blast encoder to communicate with the microcontroller (806) as described hereinbefore. Alternatively, if the marker apparatus (102) is encoded wirelessly, or not during deployment, the caps (716) may be both sealed, and shell (714) may be completely encapsulated with no removable cap.

The shell (714) may have a substantially cylindrical shape, e.g., with a substantially 90-mm outer diameter and a substantially 100 to 200-mm length.

Having a substantially cylindrical shape may be easier to make and receive the marker antenna, the PCBA (708) and the battery (706), e.g., as shown in FIG. 7.

The length ratio (aspect ratio) of the coil (702) may affects its performance as a magnetic field source, thus there may be a trade-off between a longer shape for better core performance vs a shorter shape for better survivability.

Long skinny devices may perform poorly in survivability in some applications, e.g., by being more likely to snap in half, so the cylindrical shape may be selected to be a squat cylinder or substantially spherical. The shell (714) may have a substantially spherical shape to provide a minimal volume:surface ratio.

### Mobile Platform (108)

The mobile platform (108) (e.g., the vehicle) is configured to move/carry the mobile magnetometer (106) between the plurality of measurement locations (which may also be referred to herein as “stations”), including while making the magnetic field measurements, i.e., making the magnetic field measurements (e.g., multiple magnetic field measurements, or a multiplicity of magnetic field measurements) while moving at the non-zero speed. In operation, the mobile platform (108) moves through the navigable medium (112) (e.g., space, air or water) to make the measurements at the multiple locations relative to the obscured marker apparatuses (102) and the or each mobile magnetometer makes the magnetic field measurements while the mobile platform (108) is moving, i.e., while a speed of the or each mobile magnetometer is non-zero in the reference frame of the marker apparatuses (102) and the opaque medium (104).

The mobile platform (108) includes frame or body that carries a power or energy source, and locomotion elements. The mobile platform (108) includes a prime mover, motor or engine. The mobile platform (108) is configured for locomotion (i.e., the ability to move from one place to another) such that it can be selectively/selectably deployed, positioned, directed, guided, manoeuvred, piloted, and/or driven to multiple physical locations during at least the move mobile magnetometer process (330).

The mobile platform (108) may be an airborne platform configured for air travel, a land-based mobile platform configured for land travel, or a waterborne platform configured for on-water or submersible travel, e.g., an aircraft drone, a boat, an underwater drone, and/or a land vehicle (with wheels).

The mobile platform (108) may include a crewed vehicle or an uncrewed vehicle. The mobile platform (108) can include manual controls for a human occupant. The mobile platform (108) can include a remote-control unit for remote control of the mobile platform (108). The mobile platform (108) can include an autonomous control unit for autonomous control of the mobile platform (108).

The vehicle may be an air vehicle (e.g., a helicopter, a drone or Remotely Piloted Aircraft (RPA)), a land vehicle, or a water vehicle. The RPA may include an uncrewed airborne drone or UAV, being fixed-wing or multirotor or other configuration. The mobile platform (108) may include one or more types of control systems, including: an on-board pilot control system, a remote-piloted control system, an autonomous control system, and/or an adaptive/learning control system. The vehicle may include a plurality of rotors, e.g., four or more. The vehicle may have a significant payload capacity, e.g., substantially 0.5 kg, between 0.5 and 1.5 kg, between 0.6 and 1.1 kg (e.g., substantially 0.9 kg), between 1 and 5 kg (e.g., substantially 3.2 kg), between 5 and 10 kg.

The vehicle may be a land based automated and/or autonomous vehicle (e.g., a remotely piloted terrestrial rover (RPTR) and/or autonomous land based drone).

As shown in FIG. 2, the system (100) may include a tow member with one or more mechanical linkages (202) between the mobile platform (108) and the magnetometer (106) to provide a substantial spatial distance between the magnetometer (106) (which includes sensitive magnetic-field sensors and associated electronic circuits) and the mobile platform (108) (which can be a source of magnetic-field noise, electromagnetic interference (EMI) and/or vibration). Including the tow member in the system (100) allows for the magnetometer (106) to make the measurements further away from the mobile platform (108), which may be a source of the electromagnetic/magnetic noise. The tow member may also allow the magnetometer (106) to be clear of any landing skids and/or obstacle avoidance landing cameras of the mobile platform (108). The tow member may be referred to as providing a “tow” mechanism because the magnetometer (106) is towed by the mobile platform (108), although the magnetometer (106) need not be behind the mobile platform in a travel direction. The tow member may include a rigid structure forming a fixed relation to hold the magnetometer (106) in a fixed spatial relation to the mobile platform (108) during operation (the measuring and the movements between the measurement locations). Alternatively, instead of the rigid structure, the tow member may include a flexible structure forming a flexible relation to hold the magnetometer (106) at the substantial spatial distance from the mobile platform (108) while allowing relative spatial movement of the mobile platform (108) and the magnetometer (106): in this alternative, the system (100) includes a relative pose measurement system to measure the pose between the mobile platform (108) and the magnetometer (106) during the operation (at least during the measuring at the measurement locations) since the relative spatial relationship is not fixed during the operation. The flexible tow structure may include a rope/chain/line that sets a maximum spatial separation equal to the substantial spatial distance but that can be coiled/folded for landing/storage: the rope/chain/line has a predefined length in tension but can be shortened by compression. The flexible tow structure may include a pole (of the mechanical linkages (202) connected beneath the mobile platform (108) by a gimbal that allows rotation and swing of the pole relative to the mobile platform (108) while the pole has a predefined length in tension and in compression.

Having the tow member allows the navigation module (118), which may include the GNSS receiver and/or the LiDAR SLAM system, to be above the mobile platform (108), while allowing the magnetometer (106) to be substantially below the mobile platform (108), thus mitigating the mobile platform (108) blocking navigational signals to the navigation module (118), which may include satellite signals, from one direction (e.g., form above) and mitigating the mobile platform (108) blocking the uplink signals from the other opposite direction (e.g., from below). Having the rigid structure (of the tow member) or the relative pose measurement system allows determination (respectively by static control or dynamic measurement) of the location, and optionally orientation (for vector and phasor measurements), of the magnetometer (106) from the location, and optionally orientation, of the navigation module (118) and the relative pose of the magnetometer (106) attached to the mobile platform (108) by the tow member. In an example, by using a rigid pole between the platform (108) and the magnetometer (106), the pose measurement may be simplified to measuring the orientation of the magnetometer (106) relative to the navigation module (118), which may provide a global position and orientation (P&O). In another example, a tow rope/chain may allow more movement of the magnetometer (106) relative to the mobile platform (108) (including orientation and a direction affected by travel speed), in which case the relative pose measurement system may measure relative P&O in 6 dimensions (including 3 positional and 3 orientational).

For a land-based platform, the tow member may include a rigid or jointed boom extending horizontally from the platform, e.g., fixed rigidly to a frame of the vehicle, such as the vehicle's body/chassis, by mechanical fasteners/welds. The rigid/jointed boom may be attached and configured to hold the magnetometer (106) at the substantial spatial distance away from the mobile platform (108) and close to but not touching the boundary/surface, e.g., the ground, e.g., substantially 0.1 m to 10 m, e.g., substantially 1 m from the ground.

As shown in FIG. 2, the tow member may include a mechanically flexible mechanism that allow the tow member to change shape (including its linear length) under control of the system (100) when the mobile platform (108) is parked/stored. When the system (100) includes the pole, the pole may include a flexible joint (or “knee”) 204 between ends of the otherwise rigid pole, thus forming two of the linkages (202) joined at the knee (204). The knee (204) is configured to be locked such that the pole is rigid, e.g., straight, while the mobile platform (108) is moving between the measurement locations (e.g., when the mobile platform (108) is an air vehicle) so that the magnetometer (106) orientation can be measured accurately. The knee (204) is configured to unlocked after making the measurements, e.g., when the air vehicle lands, thus allowing the pole to fold at the knee (204), allowing the mobile platform (108) and magnetometer (106) to land and be stored/transported in a compact manner. The knee (204) may include a cable that is pulled tight to lock the knee (204) by an actuator, e.g., including a servo-type motor controlled by the control system of the mobile platform (108): alternatively, the knee (204) may include a hinge in the form of a mechanical bearing, e.g., releasably locked by a pin that engages with a lever actuated by a servo-type motor controlled by the control system of the mobile platform (108).

The system (100) may include a protective shoe mounted to/on the magnetometer (106) to protect the magnetometer (106) from impact when the mobile platform (108) approaches a solid object/surface, e.g., when landing/parking or moving close to a wall/muckpile. The shoe may include a base portion mounted/attached to the base/underside of the magnetometer (106). The shoe is configured to protect the magnetometer (106) from impact when landing, so is on the face facing substantially towards the ground during the measurements (e.g., on the bottom of the magnetometer (106)). The shoe may be configured to tip the magnetometer (106) onto its side when the shoe touches the solid object/surface, when landing and being stored/transported, thus guiding the magnetometer (106) away from the solid object/surface to protect the magnetometer.

The system (100) may include both the knee (204) and the shoe, or just one of the knee (204) and the shoe, in different embodiments/applications.

In one or more applications, the folding knee (204) (and optionally the shoe) may improve safety through a simpler take-off and landing because the folding payload makes landing easier. For example, an example air vehicle may descend substantially vertically to land, in contrast to having a pole without a knee (a rigid pole) which would require descend at a substantial angle to lay out the pole. Allowing a vertical landing may be preferable if the air vehicle is configured to have a simple vertical landing in its predefined return to home (RTH) failsafe, initiated when the air vehicle loses its control system connection/link—with a rigid pole, an air vehicle may encounter upwards resistance as the sensor touches down, which may be interpreted as the airframe touching down, causing a crash. In one or more applications, it may be advantageous to not have to reprogram/reconfigure the mobile platform (108) in order to operate with the magnetometer (106): the pole with the knee (204) may thus allow the system to be “drone-agnostic”.

The tow member may include a telescopic strut between the magnetometer (106) and the mobile vehicle (108). The telescopic strut may include a gas with sufficiently high pressure to extend the telescopic strut to a maximum length (thus providing the substantial spatial distance) during the measurements (e.g., during flight), but sufficiently low pressure to allow the telescopic strut to be compressed to a minimum length for landing and storage, e.g., by exerting a lower extension force on the strut that a downward force applied by the mobile platform (108) when landing and pressing the magnetometer onto the ground/landing platform. When the mobile platform (108) is the airborne platform, instead of the knee and the shoe (which provide for re-orientation of the magnetometer (106) on landing and for storage), the telescopic strut may include a passive gas strut collapsed by the weight of the airborne platform (including all components carried by the mobile platform). Alternatively, including for an airborne, land-based and/or water-borne platform, the telescopic strut may have powered extension and retraction by the system (100) including a pressure pump/controller to switch between the low pressure and the high pressure in the strut, e.g., controlled by the control system of the mobile platform (108).

### Overall Process (300)

As shown in FIG. 3, the system (100) is configured to perform an overall process (300) that includes the following processes:
a) the calibrate magnetic field source (MFS) process (302);
b) the encode markers process (304);
c) the path generation process (306);
d) the execute mission process (308), which includes:
   i) the downlink processes (310),
   ii) the marker processes (318), and
   iii) the move and measurement process (328); and
e) the localization process (338), which includes:
   i) the inversion process or processes (340), and
   ii) the estimate markers' P&O process (342).

The calibrate magnetic field source (MFS) process (302) includes the strength or moment (m) of the magnetic field source (MFS) being measured/set, e.g., during manufacture, prior to the execute mission process (308). Since the inversion process (340) may optionally use one or more calibration values of the magnetic field source (MFS) to improve precision, the magnetic field source (MFS) may be configured to generate the magnetic field (b) with a selected strength or moment (m), defined by the one or more calibration values, in the calibration process (302). The one or more calibration values include a selected value and/or a selected range of values (which may be referred to as a “calibrated range”), and the inversion process (340) may use the selected strength or moment (m) with the mathematical model when numerically estimating the location of the magnetic field source (MFS).

The path generation process (306) includes generating an intended path (124) for the mobile platform (108) (e.g., vehicle) using a planning system, e.g., a drone controller.

The intended path (124) may include two or more passes past the expected marker locations, including:
a) a first pass to transmit the CHANNEL SELECT commands to the marker apparatuses (102) which may include approaching the expected marker locations within the downlink distance but not necessarily within the magnetic field detection range of the magnetometer (106);
b) a second pass (or two passes) to transmit the WAKE UP and TRANSMIT TIME commands, possibly within the downlink distance but not necessarily within the magnetic field detection range of the magnetometer (106);
c) a third pass to measure the magnetic field (b) and receive any uplink signals, this time within the magnetic field detection range of the magnetometer (106); and
d) a fourth pass to re-measure magnetic field (b) and receive any uplink signals from any marker apparatuses (102) for which the localization process (338) did not generate a sufficiently clear/precise location, e.g., by moving even closer to expected marker locations in a blasting plan.

The move and measurement process (328) includes the mobile platform (108) executing the mission by following the intended path (124) and the or each mobile magnetometer making the magnetic field measurements while the speed of the or each mobile magnetometer (and thus the or each corresponding mobile platform (108)) is substantially non-zero or non-zero, e.g., the substantially non-zero speed can include from slightly above zero meters per second (m/s) to substantially 30 m/s, including from above zero to 25 m/s, including from above zero to substantially 3 to 4 m/s (e.g., for a multi-rotor drone, e.g., for mining or quarrying operations), and substantially 8 m/s to substantially 25 m/s (e.g., for a fixed wing drone, e.g., for linear operations, e.g., along a ditch or pipeline).

The downlink processes (310) include the MI Tx (116) downlink transmitter generating the wireless downlink signals, including:
a) sending the CHANNEL SELECT command in the CHANNEL SELECT process (312);
b) sending the WAKE UP command in the WAKE UP process (314); and
c) sending the TRANSMIT TIME command in the TRANSMIT TIME process (316).

In the downlink processes (310), the mobile platform (108) follows the intended path (124) such that the at least one marker apparatus (102) is within the downlink distance of the MI Tx (116) downlink transmitter. The downlink distance for the downlink signals may be selected to exceed the magnetic field detection range of the magnetometer (106) (which defines the range of detectable magnetic field (b) and the uplink signals) since the magnetic field detection range is limiting: this may be arranged by first selecting/measuring the magnetic field detection range of the magnetometer (106), the configured the MI Tx (116) to provide the downlink distance that is substantially greater than the determined magnetic field detection range. Accordingly, the intended path portion during the downlink processes (310) may differ from the intended path portion during the move and measurement process (328): e.g., the intended path portion during the move and measurement process (328) may carry the mobile platform (108) substantially closer to the expected marker locations, e.g., closer to the surface, then during the downlink processes (310).

The move and measurement process (328) include the following, repeated iteratively for each mobile magnetometer:
a) the move mobile magnetometer process (330), moving along the intended path (124), followed by
b) the measurement processes at each measurement location (without necessarily stopping), including:
   i) the record measured magnetic field (b) process (332) for recording the magnetic field (b),
   ii) the record mobile magnetometer position process (334), including the navigation module (118) or the remote location tracking system recording the magnetometer location at the same time as a recording the magnetic field (b); and
   iii) the record mobile magnetometer orientation process (336) for recording the magnetometer orientation at the same time as a recording the magnetic field (b).

Alternatively or additionally, if the system (100) includes a fixed magnetometer, the receiving/determining of the two or more magnetic field measurements may include using at least one of the at least one magnetometer (106) attached to the fixed point.

The at least one magnetometer (106) measures the magnetic fields at the plurality of measurement locations, and the corresponding tracking module measures these measurement locations, thus making the magnetic and location measurements simultaneously, and recording/receiving/storing/logging the simultaneous magnetic and location measurements in the DAQ component (114). Alternatively or additionally, the determining of the two or more measurement locations may include: receiving/determining respective magnetic-field-measurement times when the magnetic field measurements are/were measured (e.g., using time stamps recorded with the magnetic measurements, e.g., in a magnetic-field v. time file); and determining the respective locations of the magnetometer at the magnetic-field-measurement times from location tracking data representing the location of the magnetometer over time using the remote location tracking system (e.g., a satellite or visual or infrared tracking system) with sufficient resolution for recording the flight path of the mobile platform (108) (drone) with time stamps recorded with the 3D locations, e.g., in a 3D location v. time file).

The receiving/determining of the two or more magnetic field measurements may include using at least one of the at least one magnetometer (106) attached to the at least one mobile platform (108), including: optionally using the one or more magnetometers (106) attached the or each mobile platform (108); and/or optionally using two or more magnetometers (106) attached two or more mobile platforms (108), including using one magnetometer (106) attached to each mobile platform (108).

The inversion process (340) includes:
a) the at least one digital microprocessor (110) receiving the magnetic measurements and matching location measurements and optionally orientations from the DAQ component (114);
b) the at least one digital microprocessor (110) optionally correcting the location measurements and optionally orientations using the data reduction process (500); and
c) the at least one digital microprocessor (110) applying the mathematical model to generate the 3D location (and optionally the orientation) of the at least one marker apparatus (102).

The data reduction process (500) includes using corrections data (e.g., GNSS) received from a corrections service or a GNSS base station or the INS (which includes the kinematics processing), and/or the at least one digital processor optionally correcting the P&O measurements using the relative P&O of the magnetometer and GNSS from the relative pose measurement system—GNSS typically uses the terms RTK or PPK as the data-processing processes that take a source of corrections, and INS can be used to supplement/aid the RTK or PPK (e.g., reject satellite measurements that say the vehicle moved drastically when the accelerometers said the vehicle was static) using a data processing component that outputs either a stream or file of positions and orientations of the magnetometer (106) for the inversion process (340).

The record measured magnetic field (b) process (332) includes: determining two or more measurements (“magnetic field measurements”) of the magnetic field (b) using the magnetometer (106) attached to the mobile platform (108), wherein the magnetic field (b) is generated by the magnetic field source (MFS) in the marker apparatus (102), wherein the marker apparatus (102) is stationary with respect to the opaque medium (104), which may have the surface, e.g., including earth/rock/ice/water, which may include being buried or submerged in the medium (104), wherein the marker apparatus (102) is stationary relative to its surrounding portion of the medium (104) so that the marker apparatus (102) moves with the medium portion if the medium portion moves.

The localization process (338) includes receiving the two or more magnetic field measurements from the record measured magnetic field (b) process (332).

The record mobile magnetometer position process (334) includes determining (e.g., measuring) the two or more locations (“measurement locations”) of the magnetic field measurements in three orthogonal dimensions (3D), thus determining the locations of the magnetometer (106) when the magnetic field measurements are/were determined, wherein the locations may be in the medium (104) or outside the medium (104) (in which the marker is buried)—wherein the mobile platform (108) is configured to move relative to the marker apparatus (102) in the medium (104) and/or outside the medium (104), which may include on the surface of the medium (104) (e.g., for earth/rock/ice or water) and/or flying/floating substantially off the surface—e.g., above a mine bench or along a mine tunnel.

The localization process (338) includes receiving the two or more measurement locations from the record mobile magnetometer position process (334).

The determining of the two or more measurement locations may include:
a) determining (e.g., measuring) locations of the mobile platform (108);
b) determining (e.g., measuring) a relative location of the magnetometer (106) to the mobile platform (108); and
c) estimating the two or more measurement locations on numerical addition/subtraction of the locations of the mobile platform (108) and the relative location.

The inversion process (340) includes numerically estimating (e.g., using an iterative process, and using the at least one microprocessor (110)) the location (“source location”) of the magnetic field source (MFS) in three orthogonal dimensions (3D) using:
a) the two or more magnetic field measurements;
b) the two or more measurement locations; and
c) a mathematical model representing a magnetic dipole of the magnetic field source (MFS).

As the magnetic field source (MFS) is in the marker apparatus (102), the estimated source location is also an estimated marker location.

The marker processes (318) include:
a) the control/measure MFS orientation process (322) for controlling (synthesising) or measuring the orientation of the magnetic field source (MFS) in a global frame of reference; and
b) the transmit MFS orientation process (324) for transmitting the measured orientation of the magnetic field source (MFS) for use in the inversion process (340).

The control/measure MFS orientation process (322) includes measuring the orientation of the marker apparatus (102) when stationery relative to Earth's gravity and/or the Earth's magnetic field (or “geomagnetic field”), and thus measuring the orientation of the magnetic field source (MFS) because the MFS is fixed relative to the accelerometer/magnetometer (818,820).

The transmit MFS orientation process (324) includes the TTE MI transmitter of the marker apparatus (102) transmitting the uplink signals representing the measured marker orientation to the at least one magnetometer (106), which act as an MI receiver. The uplink signals are transmitted through the medium (104) such that the measured orientation can be used to estimate (by calculation) the location of the marker apparatus (102). The marker apparatus (102) communicates the orientation of the marker apparatus (102) via modulation of the magnetic field (b) and/or by the uplink signals (which may be in a different channel) such that the field shape is not changed in “orientation”, merely the receiver, and therefore mathematical model is informed of the orientation in space, thus reducing unconstrained variables when using the mathematical model in the inversion process (340).

The control/measure MFS orientation process (322) includes the marker microcontroller (806) controlling the magnetic field source (MFS) in the marker apparatus (102) based on the measured orientation of the marker apparatus (102) such that the magnetic field source (MFS) generates the magnetic field (b) with a selected orientation (e.g., such that the generated magnetic field is equivalent to that of an overall/resultant magnetic dipole that may be vertical) (without a mechanical self-righting mechanism).

The localization process (338) includes numerically estimating (e.g., using the iterative process) the orientation of the magnetic field source (MFS), including in three orthogonal dimensions (3D orientation), and estimating an orientation of the marker apparatus (102) from the numerically estimated orientation of the magnetic field source (MFS).

The inversion process (340) includes using the measured/controlled orientation of the magnetic field source (MFS) with the mathematical model when numerically estimating the location of the magnetic field source (MFS), which may improve the efficiency/precision of the inversion process (340).

The mathematical model associates the magnetic field measurements, the determined locations in 3D, and the 3D location of the magnetic dipole. The mathematical model may optionally assume that the medium (104) is homogeneous, and/or that the medium (104) has a skin depth substantially approaching infinity for frequencies at which the magnetic field (b) is modulated.

The record mobile magnetometer orientation process (336) includes determining (e.g., measuring) two or more orientations of the magnetometer (106) at the two or more measurement locations in three orthogonal dimensions (3D orientation) (thus determining the orientations of the magnetometer (106) when the magnetic field measurements are/were determined. The localization process (338) may take into account the orientations of the magnetometer (106) when estimating the location of the magnetic field source (MFS) by way of a measurement rotation process described hereinafter.

In the record mobile magnetometer orientation process (336), determining of the two or more orientations of the magnetometer (106) may include:
a) determining (e.g., measuring) orientation of the mobile platform (108);
b) determining (e.g., measuring) relative orientation of the magnetometer (106) to the mobile platform (108); and
c) estimating the two or more orientations of the magnetometer (106) based on a numerical addition/subtraction of the orientation of the mobile platform (108) and the relative orientation.

The localization process (338) includes receiving the two or more orientations of the magnetometer (106) from the record mobile magnetometer orientation process (336). The magnetometer (106) may include a plurality of types of magnetometer, including:
a) a “total magnetometer” configured to measure a total scalar value of the magnetic field (b) (which may be referred to as a “total field”) at the measurement location, regardless of its direction;
b) a “vector magnetometer” configured to measure a scalar value of the magnetic field (b) in one to three of the three orthogonal dimensions (3D), and the two or more magnetic field measurements may therefore be non-coherent vector magnetic field measurements; and
c) a “coherent vector magnetometer” configured to measure a phasor value of the magnetic field (b) in three orthogonal dimensions (3D), and the two or more magnetic field measurements may therefore be phasor magnetic field measurements (the measuring of the phasor value of the magnetic field may be referred to as “coherent detection” of the magnetic field).

The measurements of the magnetic field (b) may include scalar magnetic field strength values (total field), vector magnetic field strength values (1D, 2D or 3D absolute values), and/or phasor magnetic field strength values (1D, 2D or 3D coherent values).

The determining of the measurements of a magnetic field (b) may include the magnetometer detecting the modulated magnetic field (b) and detecting magnetic-induction (MI) signals from the magnetic field source (MFS).

The 3D locations may include three Cartesian values or three spherical values.

The mathematical model may include:
a) a closed-form mathematical model with a system of closed-form equations (mathematical relationships): or
b) a numerical integration model (e.g., a finite element analysis (FEA) model).

The closed-form equations represent solutions to Maxwell's equations for an magnetic dipole in a conducting/permeable medium with a simple structure. The numerical integration model represents integration of Maxwell's equations for the magnetic dipole (e.g., an infinitesimal magnetic dipole) in a conducting/permeable medium with any structure. In some applications, the closed-form mathematical model may be preferable for being faster. In other applications, the FEA model may be preferable for being more accurate. For embodiments using the FEA model, the cost function includes: {modelled value} minus {measured value}, where each {value} can be total field, coherent vector or magnitude vector.

The process 100 allows the magnetic field source (MFS) to have any orientation (i.e., an arbitrary orientation, e.g., caused by movement of the medium portion) while still being accurately localizable, thus addressing problems of expensive/unreliable internal self-righting mechanisms in previous buried markers. The marker apparatus (102) remains stationery during the two or more measurements (e.g., by being buried), with a fixed location and orientation, with respect to the duration of the two or more measurements. Using the magnetometer (106) attached to the mobile platform (108) may be more flexible/efficient that using an array of magnetometers/sensors fixed in space, e.g., at fixed stations relative to a mining site.

Use of the mathematical model allows localization of the marker apparatus (102) without requiring detection of a signal maximum from the marker apparatus (102) on the surface or in space, thus without requiring the mobile platform (108) to pass through a region of space containing the signal maximum, in contrast to previous markers. This may allow for efficient/flexible routing of the mobile platform (108) around a site with one or more of the marker apparatuses (102). The mathematical model includes relationships between the 3D marker location and the magnetic field measurements and locations, thus allowing a “one-step solution” of the 3D marker location, rather than estimation of an XY location from a maximum signal and a separate estimation of a Z (depth) location from knowledge of ground permeability, e.g., as required with previous markers.

Use of the mathematical model allows localization of the marker apparatus (102) in three orthogonal dimensions (3D location) without necessarily requiring knowledge of a magnetic strength or moment (m) of the magnetic field source (MFS), or an orientation of the magnetic field source (MFS), and may avoid the need for factory calibration of the magnetic strength or moment (m) (in the calibration process (302)) and/or alignment of the marker antenna with respect to a shell (714) of the marker apparatus (102). The combination of the magnetic strength and the orientation of the magnetic field source (MFS) define its magnetic moment (m).

### Measurement Rotation Process

The at least one microprocessor (110) may be configured to take into account the orientation of the magnetometer (106) (also referred to as the “sensor orientation”) in order to estimate the magnetic field (thus magnetic flux density) in the global frame by transforming a measurement from the sensor frame in the measurement rotation process. Transforming from the sensor frame to the global reference frame includes determining, for each measurement location (which corresponds to a “sample” in a set or series of the plurality of measurements):

$${b}_{s} = {K}^{- 1} v$$

$${b}_{g} = {A}_{s}^{T} {b}_{s}$$

where the bold symbols are vectors, b is the magnetic flux density vector, subscript s is the sensor frame, which may be different to (rotated relative to) the global frame, subscript g,

$${A}_{s}^{}$$

is the rotation matrix that takes a vector from the global reference frame into the sensor reference frame (aka the “sensor orientation”), the opposite rotation matrix

$${A}_{s}^{T}$$

(matrix transpose) goes in the other direction, K is the calibration matrix for the magnetometer (106), and the measurement values are represented by v, which is the voltage measured on the magnetometer (106) (a vector vₓ v_{y} v_{z}).

The mathematical model may be based on the infinitesimal dipole model because the distance between the marker apparatus (102) and the magnetometer (106) is generally substantially larger than the radius of the magnetic source in the marker apparatus (102).

The navigation module (118) and/or the remote location tracking system may be configured to measure a P&O history of the magnetometer (106), and thus to measure the magnetometer's position and orientation (P&O) at each measurement location.

As described hereinafter, the navigation module (118) may include:
a) the global navigation satellite system (GNSS) receiver for above-ground/water applications;
b) an inertial navigation system (INS);
c) a simultaneous localization and mapping (SLAM) system, e.g., when GNSS is denied, e.g., the LiDAR SLAM system; and/or
d) a receiver in an underwater acoustic positioning system.

The GNSS receiver is preferably mounted on top of, or not below, the mobile platform to mitigate the mobile platform shadowing the satellites.

The INS may be configured to operate with the GNSS receiver to measure the magnetometer's position and orientation (P&O) at each measurement location. Alternatively, the INS may be configured to operate independently of, or without, the GNSS to measure the magnetometer's P&O at each measurement location. The GNSS-INS system includes a GNSS (GPS and other satellite services, potentially using multiple GNSS constellations at the same time) measurement system onboard, may include corrections data from a reference station, and may include measurements from an onboard IMU (accelerations and compass). The GNSS-INS system includes sensor fusion algorithms to calculate the P&O over time, either in real time (e.g., using a Realtime Kinematics, RTK, system) or after the measurements have been made (e.g., using a Post-Processed Kinematics, PPK, system).

The tracking module may be configured to measure the P&O of the mobile platform (108), and the system (100) is then configured to determine the magnetometer's P&O from the mobile platform's P&O. The navigation module (118) may include a commercially available dual-antenna heading GNSS-INS sensor unit, and/or PPK software: additionally/alternatively, the P&O system may include/incorporate a pose estimation system of a movement/flight controller of the mobile platform (108) (e.g., drone)—for example, the mobile platform (108) may include a flight controller configured to generate the P&O measurements, and the flight controller may be coupled/connected to the system to receive the P&O measurements from the mobile platform (108).

The system (100) may determine the magnetometer's orientation (which may be referred to as the “payload orientation”) from the mobile platform's orientation (which may be the drone's airframe orientation) by measuring a relative orientation between the magnetometer (106) and the mobile platform (108) by way of the relative pose measurement system described hereinbefore.

Using the relative pose measurement system in addition to the navigation module (118) may be desirable since attaching the navigation module (118) directly to the magnetometer (106) may be undesirable because: the navigation module (118) might be preferably installed on top of the mobile platform (108) as described hereinbefore so GNSS signals are not blocked by the mobile platform itself, and the magnetometer (106) might be preferably installed underneath the mobile platform so the uplink signals (and corresponding magnetic field/flux) are not blocked/distorted by the mobile platform (108) as mentioned hereinbefore. During operation, the magnetometer (106) may be positioned closer to the marker apparatus (102) during the operation (movement of the magnetometer between the measurement locations) by gravity.

As described further hereinafter, the magnetometer (106) may be connected beneath the mobile platform (108) by a gimbal. The relative pose measurement system may include two or more rotary encoders (119) configured to measure two gimbal angles continuously/repeatedly or at least at each measurement location: e.g., two encoders (119) for two gimbal angles (if the gimbal is constructed to not allow movement in one orientation, e.g., yaw), or three encoders (119) for three gimbal angles. The at least one digital processor may be configured to combine the position, and optionally orientation, of the mobile platform (108) with the two gimbal angles to calculate the P&O of the magnetometer (106) over time (continuously/repeatedly, including for each measurement location). When the system (100) includes the one or more mechanical linkages (202), and these are substantially rigid (e.g., the pole), the system (100) is configured to estimate/measure/determine the magnetometer position and orientation using a vector sum of the P&O of the mobile platform (108), the selected distance between the magnetometer (106) and the navigation module (118) (due to the mechanical linkages (202) and the mobile platform's frame), and the measured angle from the encoders (119).

The relative pose measurement system may include an on-board wireless localization system configured to provide measurements in up to six degrees of freedom (DoF) using axial rotation measurements of the magnetometer (106) relative to the mobile platform (108), for example including: at least one 3D transducer/target on one of the mobile platform (108) and the magnetometer (106), and at least one 3D wireless sensor on the other of the mobile platform (108) and the magnetometer (106), wherein the 3D wireless sensor generates the relative orientation for each measurement location. The on-board wireless localization system may include a 6 DoF magnetic induction system, Alternatively/additionally, the on-board wireless localization system may include a camera/image sensor as the wireless sensor and a visible target on the magnetometer (106), e.g., based on a fiducial marker on top of the magnetometer (106) (visible to camera/image sensor) and visual tracking of the fiducial marker from the camera/image sensor on the mobile platform (108).

### Path Generation Process (306)

As shown in FIG. 4, generating the intended path (124) includes the planning system:
a) generating coordinates of a search area (which are generally horizontal coordinates) selected to bring the magnetometer (106) within its magnetic field detection range of the one or more marker apparatuses (102) (the search area may be defined by a bench or a muckpile using latitude/longitude values and/or local coordinates in process (420));
b) optionally generating the coordinates based on data exported from blast design software (402) (e.g., SHOTPlus);
c) optionally generating the coordinates based on a region of interest manually selected by mine geologists (404);
d) for an airborne platform, in process (406), optionally calculating an altitude for the mobile platform (108) (thus vertical coordinates), which may include automatically selecting vertical coordinates that are a selected distance above the boundary between the media (which may be generated from topographic information of the search area), and/or receiving user input (e.g., of a pilot's judgement and choice of take-off location) in process (408)—alternatively/additionally, using a pre-defined height above the boundary (e.g., selected to be equal to or less than the magnetic field detection range) and an active terrain-following mechanism of the mobile platform (e.g., wheels, or a altimeter) in process (416);
e) automatically generating a boundary polygon for movement of the mobile platform in the search area using geometrical operations on the horizontal and vertical coordinates in process (410); and
f) automatically generating the intended path (124) for the mobile platform within the boundary polygon in process (412), which may include using at least one predefined patterns, e.g., a zigzag or square-wave pattern in processes (414,416)—or alternatively receiving user input during the movement to control the intended path (e.g., from the pilot) in process (418).

The intended path (124) need not be followed accurately because the measurement locations are measured simultaneously/contemporaneously with the magnetic field measurements, and the measured locations are used in the inversion (not the intended path coordinates). Any path in 3D space may be used, as long as it is measured accurately, and as long as it spans/covers the area of interest with coverage sufficient to reliably wake and detect all of the markers to be used, e.g., selected by a user/operator of the system (100) depending on the application (e.g., where the muckpile will be). The system (100) may include a user interface that displays the flight boundary and the detected marker locations (to the user) so the user can see if any located markers are close to or outside the selected boundary, and the user interface may be configured to prompt the user to re-fly the mission with an adjusted boundary (such that it is within the magnetic field detection range), to get better results.

The system (100) determines global position, global orientation and magnetic field amplitude (and optionally phase) for each measurement location (or ‘station’) used in the inversion. The global position and global orientation of the magnetometer (106) may be comprised of global P&O of the mobile platform (108) plus the relative P&O of the magnetometer (106) relative to the mobile platform (108). The global position and global orientation values may be measured directly or estimated. For example, if the magnetometer (106) has a consistent orientation without significant wobble, the global orientation values may be substantially consistent for a plurality of the measurement locations/stations, so the global orientation values (pitch, yaw, roll) may be estimated for the plurality of the measurement locations/stations, e.g., based on orientation values estimated/selected during design of the system (100) (e.g., by setting the global orientation of the magnetometer relative to the ground by affixing it to the mobile platform (108) at a fixed orientation and driving/flying/moving the mobile platform (108) only in substantially straight lines): this may reduce the measurement time required at each measurement location.

### Data Reduction Process (500)

As shown in FIG. 5, correcting the P&O measurements and initiating the inversion includes:
a) in step (502), receiving the data from the DAQ component (114), including from:
   i) in substep (503A), measuring the relative P&O (e.g., relative to airframe) of the magnetometer (106) and the mobile platform (108) using the relative P&O system (e.g., including the encoders (119)),
   ii) in substep (503B), the magnetic field measurements, and
   iii) in substep (503C), navigation data from the tracking module:
b) in step (504) receiving the corrections data, e.g., for the GNSS;
c) in step (506), performing the kinematics processing using the corrections data and the navigation data;
d) in step (508), determining the actual P&O of the mobile platform (108);
e) in step (510), determining the actual P&O of the magnetometer (106) from the actual P&O of the mobile platform (108) and the relative P&O using the vector addition;
f) in step (512), using the magnetometer P&O to correct for orientation of the magnetometer (106) using the measurement rotation process;
g) in step (514), separating the different marker signals using the selected multiplexing process(es) described hereinbefore;
h) in step (516), extracting the magnetic flux density for each location and each marker apparatus (102); and
i) in step (518), providing the corrected data to the inversion process (340).

### Inversion Process (340)

As shown in FIG. 6, performing the inversion process (340) includes:
a) in step (602), receiving approximate marker locations to initiate the estimation processes;
b) in step (604), performing a direct solution process (described hereinafter);
c) in step (606), providing an approximate P&O from steps (602,604) for use as a starting guess for the solver;
d) in step (608), receiving a position history of the magnetometer (106), during this mission;
e) in step (610), receiving a signal history of the magnetometer (106), during this mission;
f) in step (612), looping or iterating on the P&O of the marker to minimise the cost function, including:
   i) in step (614), calculating the cost function, and
   ii) in step (616), generating new guesses for the marker's P&O; and
g) in step (618), providing the solution for the marker's P&O, and thus the location of the magnetic field source (MFS).

Performing the inversion process (340) may include providing additional starting guesses, looping or iterating to provide an iterative solution for each, and selecting the iterative solution that has the lowest ‘cost’ for determining the marker location.

The at least one predefined mathematical model (between the model magnetic dipole and the modelled magnetic field strengths/directions at the plurality of modelled measurement locations) may itself be referred to as the “forward model”, and it may include or represent the following relationship for each marker apparatus (102) (each “single coil marker”):

$${K}^{- 1} v = {b}_{s} = \frac{{μ}_{0} m}{4 π {r}^{3}} {A}_{s} {P}^{T} {CPA}_{m}^{T} \hat{m}$$

where \hat{m} is the unit vector in the direction of the magnetic moment (marker frame), Aₘ described hereinbefore, P the tracking matrix (a rotation matrix), as described in Kuipers J B, others (1999) “Quaternions and rotation sequences: a primer with applications to orbits, aerospace, and virtual reality”. Princeton University Press, Princeton—this describes the direction between the station and the marker), C the coupling matrix (the ‘shape’ of the magnetic dipole field), m the magnetic moment (magnitude), μ₀ the vacuum permeability, r the distance between station and marker, and the rest as described hereinbefore.

As the plurality of the measurements of the magnetic field (b) from the marker apparatus (102) are made at the corresponding plurality of measurement locations, the at least one digital processor estimates the marker location by performing an inversion of the forward model to fit the plurality of measurements. Thus the determination/calculation of the marker location is based on: the plurality of measurements of the magnetic field (b) from the marker apparatus (102): the plurality of measurement locations; and the at least one predefined mathematical relationship. This estimation of the source location may be referred to as “inversion for the forward model”, “solving the inverse problem”, and/or as “fitting” the forward model to the measurements.

The inversion process (340) may include an iterative process to minimise a cost function (also referred to as an “objective function”), and various appropriate cost functions are described hereinafter, and in the Appendices, applicable in different situations/applications, e.g., depending on available SNR, the required accuracy of the marker locations, and/or the processing power of the at least one digital processor. Alternative cost functions and minimization processes may be used as a person of ordinary skill in the relevant art would comprehend.

If the orientation of the magnetic field source (MFS) and its moment (m) in the reference frame is known, e.g., if the marker apparatus (102) is a self-righting marker such that its magnetic dipole is always vertical, the marker apparatus (102) effectively has 3 degrees of freedom (DoF), e.g., X, Y and Z directions, in the reference frame.

If the orientation of the magnetic field source (MFS) in the reference frame is not known, e.g., if the marker apparatus (102) is not configured to be self-righting and the orientation of the magnetic dipole is not known, the marker effectively has 5 degrees of freedom (DoF), e.g., X, Y and Z directions, and pitch and roll orientations in the reference frame. Using the definitions of Kuipers J B, the two orientation degrees of freedom for the single-axis marker may be referred to as: (i) heading (wherein yaw is a change in heading), and (ii) elevation (wherein pitch is a change in elevation); and the symmetry axis (which is the missing degree of freedom for a single-axis marker) may be referred to as bank (wherein roll is a change in bank).

The numerically estimating of the source location in the three orthogonal dimensions (3D) using the mathematical model requires a different minimum number of the two or more magnetic field measurements (and the two or more measurement locations) depending on the DoF of the magnetic field source (MFS), in other words the number of unknown magnetic dipole values of the magnetic field source (MFS), which can include dipole strength and orientation (of the magnetic moment) and dipole location in 3D, thus up to 6 unknowns (the dipole is symmetrical about its axis, so there are not 7 unknowns). The minimum number of the two or more magnetic field measurements also depends on the type of the magnetometer (106) and thus whether the magnetic field measurements are scalar, vector or phasor, and how many dimensions each measurement has (from 1 to 3 orthogonal dimensions). For example:
a) for the total scalar magnetometer, the minimum number of the two or more magnetic field measurements (at substantially non-overlapping locations) can be equal to the number of unknowns in the Total Field Inversion Process, e.g., 6, 5 (if dipole strength is known), 4 (if dipole orientation is known), or 3 (if dipole strength and dipole orientation are known.
b) for the vector magnetometer (without phase information), and for the coherent vector magnetometer, which can make 1, 2 or 3 independent measurements at each location, the minimum number of measurements can be equal to the number of unknowns, but the number of locations can be fewer by a factor of the number of independent measurements at each location.

The magnetic field (b) is a vector quantity, meaning that it has a direction in space. This can be described using three vector components in x, y, z directions. Since the modulated magnetic field (b) is an alternating field, it also has a phase. The three vector components may have a phase shift relative to each other, and also relative to the source magnetic dipole. In embodiments, the magnetometer (106) may be configured to sense the three vector components, and optionally their phase (the “coherent vector magnetometer”), or it may be sensitive only to the magnitude of the field (the “length” of the total field vector, or the “total field”, thus a “scalar magnetometer”). A vector magnetometer measures the magnetic flux density in the sensor frame, bₛ.

### Total Scalar Magnetometer—Total Field Inversion Process

A total field magnetometer measures ∥bₛ∥. The total field can be calculated from the vector field where ∥·∥ indicates the Euclidean norm or 2-norm.

The total root-mean-square (RMS) flux density squared for a single-coil marker is given by:

$${‖ {b}_{s} ‖}^{2} = {b}_{s}^{*} {b}_{s} = {( \frac{{μ}_{0} m}{4 π} )}^{2} \frac{1}{{r}^{6}} {\hat{m}}^{T} {A}_{m} {P}^{T} {‖ C ‖}^{2} {PA}_{m}^{T} \hat{m}$$

using the forward model, wherein the coupling matrix C can be a constant for the free-space model, and the asterisk in b* indicates the complex conjugate transpose.

In the inversion process (340), a cost function for the inversion is determined as a difference between the measured total field and the predicted field (at each location), and the Total Field Inversion Process includes a non-linear optimisation process (performed by the microprocessor (110)) to find a solution for marker P&O and optionally for the mean moment as m the magnitude (length) of the magnetic moment vector m (thus 5 or 6 DoF):

$${‖ {b}_{s} ‖}^{2} - {( \frac{{μ}_{0} m}{4 π} )}^{2} \frac{1}{{r}^{6}} {\hat{m}}^{T} {A}_{m} {P}^{T} {‖ C ‖}^{2} {PA}_{m}^{T} \hat{m} = 0$$

where \hat{m} is in the marker frame. This assumes that the magnetic moment vector m is always oriented in the same way relative to the marker body, e.g., along the axis of the cylinder in the “x direction”. The magnetic moment vector \hat{m} may be replaced with \hat{x} in these equations, where the orientation is given by

$${A}_{m}^{T}$$

and the unit vector \hat{x} is no longer a constant.

The cost function may be written as:

$${‖ {b}_{s} ‖}^{2} - {( \frac{{μ}_{0} m}{4 π} )}^{2} \frac{1}{{r}^{6}} {\hat{m}}^{T} {P}^{T} {‖ C ‖}^{2} P \hat{m} = 0$$

where the moment unit vector \hat{m} is in the global frame (not the marker frame) and is no longer be a constant. The direction of this vector \hat{m} is the orientation of the marker.

The total field is independent of magnetometer orientation, so the magnetometer orientation need not be measured, which may save on the cost of the orientation measurement systems (e.g., for the drone and any payload encoders (119)), and also means that the measurement is independent of any uncertainty in the measurement of the sensor orientation (as no measurement will be perfect).

However, the effects of sensor rotation during a single measurement (during the accumulation time at a particular location) will remain, so b_{g} may be used instead of bₛ, where b_{g} is calculated by rotating the timeseries data as described hereinafter if estimating the total field from a vector magnetometer, but not when using a total field magnetometer.

The total field inversion process has been used in an experimental example, and the marker was successfully located through the earth (TTE).

### Non-Coherent Vector Magnetometer-Absolute Value Inversion Process

In the inversion process (340), the Absolute Value Inversion Process includes the process of Appendix D. This is used when the phase information is not available. Only the magnitude part of the phasor is used. The measurement and forward model prediction are still vectors, but now they are just vectors of magnitudes.

Rather than using only scalar value (the total field) as described hereinbefore, the processor may use the magnitude of each vector component individually. The quantity |b_{g}| is the vector containing the three x, y, z direction magnitudes individually as its elements. The absolute value of each component is thus measured, but the phase/quadrant is not measured (thus the sign of the amplitude or equivalently the phase is unknown). The sensor orientation is measured, and orientation uncertainty affects the result, but a measurement of the signal phase (or equivalently the ‘sign’ of the signal amplitude) is not required:

$$\vert {b}_{g} \vert - \vert \frac{{μ}_{0} m}{4 π {r}^{3}} {P}^{T} {CPA}_{m}^{T} \hat{m} \vert = 0.$$

The solution has 6DoF (or 5DoF if the moment m is calibrated). The absolute value inversion process uses more information than the total field inversion process (by using the length of each component rather than just the vector's total length), so can give better localization performance, but uncertainty in the sensor orientation can reduce performance (unlike the total field inversion process).

The absolute value inversion process may be suitable for systems with vector magnetometers and non-coherent detection, or systems with vector magnetometers and coherent detection, where some/all of the measurements have high uncertainty in the measured phase (‘sign’ of the amplitude), which can happen when SNR is low. When magnitude can be measured more precisely than phase, it may be preferable to reject the phase information.

### Coherent Vector Magnetometer-Coherent Vector Inversion Process

In the inversion process (340), the coherent vector inversion includes the process of Appendix A. The magnetometer measurement provides the coherent vector of measurements b: this is a three component vector (x/y/z) where each component is a phasor. The process may round the phase to the nearest 0 or pi. The process may subtract the predicted value of b from the forward model to provide a cost function to optimise.

The magnetic flux density b is measured by the magnetometer. It is a time-varying vector. Each component is sinusoidal. In general, b will have elliptical polarisation due the effect of the ground and other phase shifts in the system. Close to the marker, or in ideal free space, the polarisation is simpler and can have values of 0° or 180°. This is equivalent to the components having positive amplitude or negative amplitude. The phase can provide additional information which can be used in the inversion. The simplest cost function may be just the forward model, thus:

$${b}_{g} - \frac{{μ}_{0} m}{4 π {r}^{3}} {P}^{T} {CPA}_{m}^{T} \hat{m} = 0 .$$

In general the cost is complex-valued so the cost will have a contribution from a real part and an imaginary part: or a magnitude and a phase angle (both set equal to zero). Thus, there will be two cost functions for each measurement location (or “station”) that are optimised together. Generally, the phase angle will have higher uncertainty so it may be given a lower weighting than the magnitude as described hereinafter.

In a version of the coherent vector inversion process, the phase may be measured/determined to the nearest 0° or 180° (which is the same as measuring the sign of each (now real-valued) component of b_{g}), in which case the coupling matrix has the simple form for a dipole in free space. This may be of assistance when fitting the measurement to the cost function above because assuming that the phase is 0 or 180 simplifies this function: C is given by [2 0 0; 0 −1 0; 0 0 −1]. This is eliminates a variable from the cost function (the skin depth, which will usually be an unknown). If the cost function is solved for a general phase angle, the form of C is much more complicated.

### Phase Recovery for the Coherent Vector Inversion Process

As the marker apparatus (102) and the magnetometer (106) have different clocks that are generally not synchronised, they are “non-coherent”, so phase recovery is necessary for the inversion process (340), performed by the at least one microprocessor (110).

The phase recovery process may include decision directed carrier recovery, which includes matching the signal to a known digital code, which indicates the start of the packet (indicating ‘where to start measuring the phase’), e.g., as described in Johnson C R & Sethares W A (2004) “Telecommunication Breakdown: Concepts of Communication Transmitted via Software-Defined Radio”, Pearson-Prentice Hall.

The phase recovery process may include measuring a reference tone including a second sinusoid in a reference magnetic signal, including at a different frequency from the carrier frequency (fc), generated by the marker apparatus (102) and detected by the magnetometer (106). The two tones are selected to be factors of a common higher frequency so they will periodically align, and this can be taken as the phase reference. At longer distances between the marker apparatus (102) and the magnetometer (106), phase measurement becomes uncertain and non-coherent processes (including the total field or vector absolute value processes) may give better precision.

This coherent measurement enables the coherent vector inversion processes including the reduced DoF processes.

### Location-Only Inversion Process

In the inversion process (340), when using the coherent vector inversion process, the cost function may be configured to not relate to marker orientation or marker moment (which may be referred to as ‘nuisance’ parameters), but still to solve for marker location in 3 dimensions. Such a ‘location-only’ inversion may include using one of the following cost functions with only three degrees of freedom (3DoF) following algebraic manipulation of the forward model and eliminating constant variables:

$${r}_{i}^{3} {P}_{i}^{T} {C}_{i}^{- 1} {P}_{i} {b}_{g , i} - {r}_{j}^{3} {P}_{j}^{T} {C}_{j}^{- 1} {P}_{j} {b}_{g , j} = 0$$

$$and$$

$${r}_{i}^{6} {b}_{g , i}^{*} {P}_{i}^{T} {‖ {C}_{i}^{- 1} ‖}^{2} {P}_{i} {b}_{g , i} - {r}_{j}^{6} {b}_{g , j} {P}_{j}^{T} {‖ {C}_{j}^{- 1} ‖}^{2} {P}_{j} {b}_{g , j} = 0$$

where i and j refer to measurements made at different locations.

Variations on the cost functions are described in the Appendices.

### Direct Solution Processes

In the inversion process (340), in addition to, or as an alternative to, using the iterative solution process described hereinbefore, the system (100) may be configured to perform a direct solution process. As shown in FIG. 6, the direct solution process may generate an approximate measurement of the marker location (a “starting guess”) that can be used to seed one of the iterative processes.

The direct solution process may include estimating magnetic flux density gradients at a selected location based on the magnetic measurements of nearby locations (“stations”), including inverting the gradients and flux densities to generate marker position independent of orientation and marker moment. Such a simple process of estimating gradients need only use a few measurement locations and so the precision is not good: however, it may be sufficient to provide the starting guess. An example of such a direct solution process is described in Appendix F.

### Determination of Marker Orientation

In the inversion process (340), the at least one digital microprocessor (11) may also be configured to determine/calculate the marker orientation based on: the plurality of measurements of the magnetic field (b) from the marker apparatus (102); the plurality of measurement locations; and at least one predefined mathematical relationship between a model magnetic dipole source and modelled magnetic field strengths/directions from a plurality of modelled measurement locations. The orientation of each marker apparatus (102) may be determined by the inversion of the forward model when the forward model (and thus the predefined mathematical relationship) includes both a definition of the dipole orientation (in 3D) and well as the dipole location (in 3D).

When using the location-only inversion, once the position/location of the magnetic field source (MFS) has been determined, then the orientation and moment can be found by a direct process, e.g., using the “OrientationGuess” process described in Appendix A. For simple location markers, orientation may not be of interest. But for other applications or combinations of applications they could provide useful information. For the single-axis marker, there are only two orientation DoF (heading and elevation): because of its symmetry, the bank angle (the third orientation DoF) does not affect the field strength around the magnetic field source (MFS).

### APPLICATIONS/EXAMPLES

Monitoring operations/applications, such as in the examples listed below, may benefit from:
a) not needing to ‘survey-in’ the devices (P&O) during deployment, or at least not needing to do so relative to the expected marker locations;
b) wireless/tetherless deployment; and/or
c) wireless communications.

Examples of the system (100) and process (300) may be used for localizing markers in one or more of the following operations/application fields:
a) block caving: caved extent, movement of caved material;
b) geotechnical monitoring (measuring pore pressure, inclination changes etc.) for slope stability, tailings dams, water reservoirs, leach heaps stability (at mines), and/or stockpile stability;
c) checking wireless primer locations for commercial blasting applications, surface, underground (U/G), seismic, civil, including ensuring the wireless primers are in safe locations, not moved, including checking for slumping/floating/missing primers;
d) encoding wireless primers (with their delay times) in the rock according to detected position and a blast design;
e) coal stockpile and landfill temperature and temperature gradient monitoring (for spontaneous combustion);
f) in surface mining, measurement of borehole toe position and water level depending on the density of the marker apparatus (102),
g) in underground mining, wherein the as-drilled borehole location in underground mining to be used when designing a shot with continuous density control when loading emulsion explosives (e.g., Orica's “4D”);
h) marking underground utilities, especially long ones with many markers, e.g., pipelines, including with markers configured for leak detection;
i) monitoring explosives in hot and/or reactive ground;
j) tracking ore/waste to stockpiles, conveyors, dumps, crushers, e.g., similar to Orica's ORETrack;
k) locating snow (avalanche) monitoring sensors to measure snow thickness, stresses inclination changes etc.;
l) detecting or tracking drill bits, or portions of drill bits or drill strings, used to drill rock/boreholes, including during drilling and/or if portions break off, i.e., become detached in the ground/rock;
m) measuring draw within coarse ore stockpiles (internal movement trajectories) for the purposes of tracking grade/hardness/fragmentation information within the stockpile, e.g., when material is added on the top from the crusher and drawn out from beneath;
n) tracking locations of objects during demolition blasting by securing/attaching the marker apparatus (102) thereto, e.g., metals intended for recycling, or hazardous objects that cannot be removed from the structure prior to blasting; and
o) near-surface soil monitoring for agriculture, e.g., using devices configured to monitor moisture etc. in the soil, e.g., devices including the marker apparatus (102) that are tolerant to ploughing, and detecting their positions while wirelessly gathering the sensed soil monitoring data.

In ore tracking operations, as described hereinbefore, the system (100) may include the marker apparatuses (102) buried adjacent to or in an ore body (e.g., down a borehole), and the process (300) may include tracking the ore body during blasting, excavation and/or processing by the localization of the corresponding marker apparatuses (102). The process (300) may include measuring draw of a stockpile by repeated localization of the corresponding marker apparatuses (102) over a selected time period.

In commercial blasting operations, as described hereinbefore, the system (100) may include at least one marker apparatus (102) that includes or forms a blast initiation device or blast primer device for initiating blasts, and the process (300) may include localizing the blast initiation device or the blast primer device based on the localization of at least one marker apparatus (102) that includes or forms the blast initiation device or the blast primer device.

In drilling operations, the system (100) may include at least one marker apparatus (102) substantially adjacent to, coupled to or incorporated into a drill bit or a drill string. The process (300) may include localizing at least a portion of the drill bit or drill string by localizing the corresponding marker apparatus (102) during drilling with the drill bit or drill string (e.g., in the opaque medium (104)), or after detachment of the portion from the drill bit or drill string (e.g., in a muck pile). The detecting or tracking of the drill bits may including detecting tracking “drill steel”, including drill bits lost in the rock/earth during drilling of boreholes. The process may include loading a borehole with both the marker apparatus (102) and the drill steel, including loading the marker apparatus (102) into the borehole that contains a portion of drill steel lost in the borehole. The process can include marking/recording that marker apparatus (102)—the “drill marker apparatus”—as tracking or corresponding to the lost drill steel, e.g., using the marker's code or ID: alternatively, the drill bit marker may be the only marker used in the shot, so ID may not be required, to distinguish it from ore markers/primers etc. The process can then include the localization of the drill marker apparatus, and hence substantial localization of the drill steel, including before blasting, after blasting, during excavation of the muck pile, and during processing of the excavated material. Localization and monitoring/tracking of drill steel in the mine/quarry site and material processing can be critical to mitigate lost drill steel damaging processing equipment, especially in sites where the rock is hard, so the drill steel is very hard and thus harder than the material being processed. By provision and tracking of drill marker apparatus, the position of the lost drill steel is provided to survey/fleet management systems, e.g., software controlling excavation, and a selected volume of the material around the lost drill location is dug out and sent to waste, or the drill steel recovered and removed in a separate processing/excavation step. More than one marker may be deployed with the drill bit, for the sake of redundancy/reliability. The bit may be bonded to the marker, e.g., using resin/grout, to increase the likelihood of the bit being close to the marker after the shot. In addition to a survey/FMS system, an augmented reality system could be used by a spotter to help guide a person operating an excavator.

In seismic operations, including transition zone seismic blasting, as shown in FIG. 9, the system (100) may include the marker apparatuses (102) respectively incorporated into or attached to the seismic receivers (902) (hydrophones/geophones) and/or the seismic sources (904) (blasting devices). The process (300) may include localizing the seismic receivers (902) and/or the seismic sources (904) localizing the marker apparatuses (102) incorporated therein or attached thereto. The sources (904) may include quasi-planar shock wave generators, including as described in International Patent Application WO2020263194A1 (Petrovic et al., entitled “Deployment of quasi-planar shock wave generators in association with seismic exploration”), the as-published specification of which is hereby incorporated by reference herein in its entirety. As shown in FIG. 11, in a land seismic blasting application, the marker apparatuses (102) in the receivers and/or sources can be buried in the medium (104) and/or resting on the surface of the medium (104). As shown in FIG. 12, in a transition zone seismic blasting application, the marker apparatuses (102) in the receivers and/or sources can be buried in the medium (104) including sand/rock/earth, and/or resting on the surface of the medium (104), and/or suspended/submerged in the medium (104) or the navigable medium (112), e.g., water—and the mobile platform (108) may be mobile in the navigable medium (112), e.g., air. The magnetic field may be measured by a vehicle (908) that includes the mobile magnetometer (106), the mobile platform (108), the DAQ component (114), the MI Tx component (116), the navigation module (118) and the data Tx component (120). The mobile platform (108) may include a drone, submersible drone, surface boat, or submarine. The vehicle (908) is controlled to move between different measurement positions 910A, 910B (or “stations”) to measure the magnetic field. As shown in FIG. 10, the path may include a first path (124A) and a second path (124B) joined by a transit path (124C): the vehicle (908) is controlled to measure the magnetic fields along the first path (124A) and along the second path (124B) where the devices are approximately located, and the vehicle (908) is controlled (optionally) to not measure while transitioning along the transit path (124C) where no devices are known to be located (thus saving energy and data storage capacity). The transit path (124C) allows for typical seismic survey arrangements where arrays of the sources and the receivers are substantially separated in space. The receivers (902) may be formed in arrays and the sources (904) may be formed in arrays. The process may include measuring the actual 3D positions of the seismic sources (904) ahead of firing. The process may include measuring the 3D positions of the receivers (902) by incorporating the marker apparatus (102) into or with the receiver (902). The locations (measured by the system 100) of the receivers (902) and the sources (904) are used with the measured seismic vibrations in a seismic inversion process. The receivers (902) and the sources (904) can be synchronised to the same time base using the MI communications in the same way as wireless primer delays are synchronised, e.g., in Orica's WebGen system, and/or as described in International Patent Application Publication No. WO2020263193A1 (Nielsen et al., entitled “Commercial Blasting Systems”), the as-published specification of which is hereby incorporated by reference herein in its entirety. These position measurements reduce the need to survey in the receivers (902) and the sources (904): thus approximate locations can be used during deployment, and the actual as-buried depth measured using the marker apparatus (102). These position measurements may be useful for seismic surveys in transition zones that are prone to movement: the actual positions of the sources (904) and the receivers (902) can be detected after movement, before firing, and the actual positions may differ substantially from the original positions (906). The position measurement processes can be performed in the same flight path as other drone-based tasks using the mobile platform (108), such as drone-based deployment (dropping) and retrieval of the wireless receivers (902), drone-based deployment of the sources (904), drone-based geophysics methods, especially ‘electromagnetics’ methods, and drone measurement of a topological/digital elevation model of the ground surface. In some applications, the drone/mobile platform (108) can land and record MI signals with the magnetometer (106) attached to the airframe.

In avalanche blasting operations, the process for drone-based avalanche blasting may be similar to the seismic blasting process, including using receivers with the marker apparatus (102) for detecting whether the avalanche has been successfully triggered, and including locating primers with the marker apparatus (102) where an avalanche has occurred after deployment of the primers but before their firing.

In leach mining operations, the system (100) may include the marker apparatuses (102) placed on or buried in the opaque medium (104) in the form of broken rock (e.g., in a heap). The process (300) may include: placing/burying the marker apparatus (102) in the broken rock; and subsequently monitoring movement of the broken rock by repeatedly localizing the marker apparatus (102) buried in the broken rock. The system (100) can include sensor devices or blast initiator/primer devices, each incorporating one of the marker apparatuses (102), deployed in the leach heap, and the process (300) can include localizing the sensor devices or the blast initiator/primer devices by localizing the or each corresponding marker apparatus (102). These marker apparatuses (102) need not be deployed in holes: they could be added to the rock at a prior stage of the mining process before heaping (or stacking) the heap, e.g., to an un-blasted bench, in a conveyor, in a truck, and/or to ore before processing (Run Of Mine). The process may include re-localizing these marker apparatuses (102) when the heap is “re-stacked”, which includes digging and re-building a heap to reinvigorate flow of the lixiviant. The 3D locations of the marker apparatuses (102) (thus of the sensors/primers) may be useful for in-place recovery, “in-place leaching” (IPL), or “stope leaching”, because the stope can settle when material is drawn from the bottom or over time. The process (300) may include measuring the positions of marker apparatuses (102) buried under an impermeable liner beneath a leach heap, e.g., for the purpose of detecting leaks through the liner.

In dig limiting operations, the system (100) may include at least one marker apparatus (102) buried in a selected location in the opaque medium (104) relative to and/or adjacent to and/or above explosive material, generally in an explosive column with a blast initiation device or blast primer device for initiating the explosive material: the marker apparatus (102) thus marks the location of the explosive material for safety reasons. The process (300) may include placing the marker apparatus (102) at or near the top of the explosive column, or at least above the explosive material, e.g., in the stemming. The process (300) may include localizing the explosive material in the opaque medium (104) by localizing the marker apparatus (102) buried at the selected location in the opaque medium (104) relative to and/or adjacent to and/or above the explosive material, which may be while digging/excavating a portion of the opaque medium (104), or in a survey process (e.g., using a drone) after a portion has been excavated. The marker apparatus (102) may be incorporated into a blast initiator/primer device. In this application, the marker marks the actual top-of-charge position. The detected 3D location of the marker can be compared to the topography of the ground surface, e.g., from drone photogrammetry, and used to ensure that there is adequate cover over the explosives after digging/excavation and prior to blasting of the marked explosive column (to mitigate the risk of wild flyrock etc.), e.g., used by the shotfirer in their safety checks. The dig limiting application may be relevant where wireless blasting is used with buried shots because the shot remains buried while shots above are blasted and dug away, or a haul road operates above, and there may be uncertainty as to how much has been dug away.

In utility marking operations, the system (100) may include at least one marker apparatus (102) buried in a selected location in the opaque medium (104) relative to and/or adjacent to and/or above a linear utility (e.g., a pipeline/powerline) in the opaque medium (104). The process (300) may include placing the marker apparatus (102) in the selected location, e.g., in a trench with the linear utility. The process (300) may include localizing the linear utility in the opaque medium (104) by localizing the marker apparatus (102) buried in the selected location (i.e., in the opaque medium (104) relative to and/or adjacent to and/or above the linear utility), optionally while digging/excavating a portion of the opaque medium (104) above the linear utility.

In soil monitoring operations, the marker apparatus (102) can include one or more environmental sensors configured to detect, monitor, estimate, or measure physical parameters of the surrounding portion of the opaque medium (104), and the environmental sensors may include temperature sensors and/or moisture sensor (e.g., for soil monitoring). The shell (714) may be configured by its size/resilience to be tolerant to ploughing/erosion (in a way that wired soil sensors, connected by wires to a central hub or an above-ground unit, would not be), mitigating the need to remove the marker apparatuses (102) from the soil/paddock/pasture, and allowing for the new position of the sensor to be measured if it moves due to ploughing/erosion. The process (300) may include localizing measured physical parameters of the opaque medium (104), e.g., pressure, moisture, and/or temperature, by localizing at least one marker apparatus (102) buried in the opaque medium (104) with respective environmental sensors to measure the physical parameter values, optionally while ploughing the opaque medium (104) adjacent/around the buried marker apparatus (102).

In mine rescue operations, the marker apparatuses (102) can form or be incorporated into tracking/communications beacons for trapped miners. The system may include the fixed magnetometers forming fixed nodes that are embedded in tunnel walls/roofs, e.g., provided by the mine to generate a resilient peer-to-peer wireless network in case of emergencies. The markers apparatuses (102) may be incorporated marker beacons that are incorporated in existing cap lamps/batteries, respirator/self-rescue devices, or sewn into clothing.

In avalanche rescue operations, or in civil engineering operations, the marker apparatuses (102) may be incorporated into marker beacons for mountain workers or engineering workers, e.g., attached or incorporated in clothing, modified ski passes/access tags, and/or smartphone cases/power banks. The process (300) may include localizing a person or a piece of equipment buried in the opaque medium (104), e.g., an avalanche, a landslide, or a (collapsed) structure, by localizing at least one marker apparatus (102) attached to the person or the piece of equipment in the opaque medium (104).

In geological, seismological or construction monitoring operations, the process (300) may include placing/burying marker apparatus (102) on/in the opaque medium (104) (rock, earth, foundations or structures), and the process (300) may include localizing the marker apparatus (102) repeatedly over a selected time period to monitor movement of the opaque medium (104), e.g., up to months, years or decades, depending on the battery life of the marker apparatus (102).

In drone-based operations, the mobile platform (108) can include the mobile magnetometer and a wireless receiver to gather data from devices incorporating the marker apparatuses (102) allowing localization of the marker apparatuses (102) in the same flight path/travel pattern used to gather the relevant data. Furthermore, the process of measuring the magnetic fields may be combined with another task performed by a drone, e.g., optical/thermal camera monitoring.

### EXPERIMENTAL EXAMPLES

In an experimental trial at a quarry, positions of example markers were measured using an example of the system disclosed herein (referred to as a “magnetic localization system”) and compared with ground-truth values from a handheld GNSS rover and bore tracking, where localization precision (“error”) was a key performance metric. In the experimental example, the performance was found to be superior to a previous competitor system. In another experimental example, example marker apparatuses (102) were tested using a vector induction coil magnetometer model ‘SHFT-02e’ from ‘Metronix’ in a light-weight housing (with voids in non-structural areas to reduce mass to approximately 2-3 kg), a ‘DJI’ ‘Matrice 600 Pro’ drone providing the mobile platform (108), a GNSS-INS navigation system from Advanced Navigation (‘SPATIAL’, ‘CERTUS EVO’) providing the navigation module (118), ‘KINEMATICA’ kinematics software providing the P&O of the drone, and shells (714)—for blast and heave survivability—including nylon (5 mm, and 10 mm), polyethelene (PE), and/or polyoxymethylene (POM), including some examples with internal structures as described in co-pending Australian Provisional Patent Application No. 2022902919 (“Electronic device”), the as-filed specification of which is hereby incorporated by reference herein in its entirety, using MI frequencies between 5 kHz and 10 kHz, coil radii of substantially 0.02 to 0.04 m, and substantially 100 to 200 turns. The DAQ module (112) may include a commercially available preamplifier, and a commercially available analog to digital converter chip, e.g., from Analog Devices, e.g., e.g., LTC6373 and AD7134, configured to sample at substantially 74 kHz. In one experiment, Monte Carlo methods were used for comparing inversion methods, simulating hundreds of measurements to determine average performance, finding in that case that a vector absolute value method worked best at longer ranges while a coherent vector method worked best at shorter ranges. In a potential experiment, the navigation module (118) may include a LiDAR SLAM system based on Emesent's ‘Hovermap’.

### MI Signals and Interpretation

“Through the earth” (TTE) includes or refers to the communication of signals in, through and/or across a set of physical media residing between the signal source and the signal receiver or detector, e.g., wherein at least one of the signal source and the signal detector is at least partially obstructed, overlaid, covered, surrounded, buried, enclosed, or encased by the set of physical media. The set of physical media can include one or more of rock, broken rock, stone, rubble, debris, gravel, cement, concrete, stemming material, soil, dirt, sand, clay, mud, sediment, snow, ice, one or more hydrocarbon fuel reservoirs, site infrastructure, building/construction materials, and/or other media or materials. The physical media can be referred to as “the earth”, where “earth” includes the ground, soil, a rock formation, rock, construction material/concrete, stone, borehole stemming, ice, frozen ground, etc. The marker apparatuses (102) may be surrounded/buried in boreholes in hard material, or in piles of loose material: in the loose material, there may be fewer size constraints on the marker apparatus (102), so the shell (714) and the marker antenna could be long, perhaps one metre or more. If marker survivability is not required, e.g. for a seismic primer in a borehole, the shell (714) and the marker antenna could also potentially be one metre or more.

For the MI downlink signals, the marker apparatus (102) may be located within a near-field region or zone of the magnetic field generated by the MI Tx (116), wherein magnetic field strength as a function of distance away from the vehicle-based or broadcast MI signal source decays, including in accordance with an inverse distance cubed relationship, and the marker apparatus (102) detects changes in near-field magnetic flux generated by the MI Tx (116) rather than detecting far-field or radiatively propagated electromagnetic waves (e.g., radio waves) generated by the MI Tx (116). Alternatively/additionally, the marker apparatus (102) may be located within the transition region or zone (between the near-field and the far-field) of the magnetic field generated by the MI Tx (116).

For detecting the modulated magnetic field (b) and the MI uplink signals, the magnetometer (106) may be positioned, during operation, in or beyond the near-field region or zone of the magnetic field generated by the marker apparatus (102), e.g., within approximately one-half of a wavelength away from the marker apparatus (102), and more commonly or particularly resides within approximately 10 skin depths (e.g., less than 10 skin depths), approximately 6 to 8 skin depths (e.g., less than 8 skin depths), approximately 3 to 5 skin depths (e.g., less than 5 skin depths), or approximately 2 to 4 skin depths (e.g., less than 4 skin depths) away from the marker apparatus (102). Additionally/alternatively, the magnetometer (106) may be positioned, during operation, at any distance from the marker apparatus (102) while the signal-to-noise ratio (SNR) detected by the magnetometer (106)/recorded by the DAQ component (114) is above a selected threshold (minimum SNR threshold or minimum magnetic field threshold), e.g., a selected threshold for amplitude/phase/frequency recovery. Additionally/alternatively, the process (300) may include making the plurality of magnetic field measurements with varying SNRs or field strengths, and only selecting ones of the magnetic field measurements (also referred to as selecting the “stations”) having SNRs or field strengths over the selected threshold for the numerically estimating of the source location. The selected threshold (minimum magnetic field threshold) may be equivalent to for example 1 pico Tesla RMS.

The modulated magnetic field (b) and the uplink signals may travel an uplink distance TTE that is defined by the magnetic field detection range of the magnetometer (106) and external noise (including atmospheric and man-made noise) that defines the SNR. The uplink distance can be less than 200 meters (“m”): less than 100 m: less than 80 m; less than 60 m: between 0.10 m and 60 m; between 0.25 m and 50 m; between 0.50 m and 40 m; or between 1 and 30 m. The carrier frequency (fc) and the uplink MI signal frequencies can include at least one frequency in the low frequency (LF) ITU frequency band, and/or frequencies between 100 Hz to 1 MHz, or between 0.1 kHz and 200 kHz, between 1 kHz and 10 KHz, between 1 kHz and 1 MHz, or between 5 kHz and 10 kHz, or between 10 kHz and 50 kHz, between 10 KHz and 300 kHz, or between 20 kHz and 200 kHz, or between 35 kHz and 130 kHz, or between 50 kHz and 100 kHz, or between 100 kHz and 200 kHz, or between 120 KHz and 130 kHz.

In some embodiments, the marker apparatus (102) may receive downlink signals from a large antenna (e.g., a ‘WebGen’ antenna), including broadcast signals, as well as downlink signals from the MI Tx (116). These downlink signals can travel a downlink distance (including TTE) using one or more downlink MI signal frequencies, which can include broadcast MI signal frequencies. The broadcast MI signal frequencies, e.g., from a large ‘WebGen’ antenna, can include substantially 1.8 kHz, or between 1 kHz and 2 kHz, or between 100 Hz and 10 kHz, or between 0.1 kHz and 200 kHz, or between 1 kHz and 10 kHz, or between 10 kHz and 50 kHz, or between 50 kHz and 100 kHz, or between 100 Hz and 100 kHz, or between 100 kHz and 200 kHz, or between 120 kHz and 130 kHz, and the downlink distance can be greater than 100 meters: greater than multiple or many hundreds of meters: between 200 and 900 meters: greater than a kilometre: or greater than multiple kilometres. The broadcast downlink MI signal frequencies can include at least one frequency within the ultra low frequency (ULF) band, or within the very low frequency (VLF) band as defined by the International Telecommunications Union (ITU). The MI downlink signals from the MI Tx (116) would typically be of lower power than from a large ‘WebGen’ antenna, and would have less range, as described hereinbefore under the heading ‘Downlink Signals’.

With the downlink signals and the uplink signals, the marker apparatuses (102) can be configured for both sending and receiving MI signals and information therein to and from the mobile platform (108), thus providing bidirectional or 2-way MI-based communication with the mobile platform (108).

Herein, reference to one or more embodiments, e.g., as various embodiments, many embodiments, several embodiments, multiple embodiments, some embodiments, certain embodiments, particular embodiments, specific embodiments, or a number of embodiments, need not or does not mean or imply all embodiments.

As used herein, the term “set” corresponds to or is defined as a non-empty finite organization of elements that mathematically exhibits a cardinality of at least 1 (i.e., a set as defined herein can correspond to a unit, singlet, or single element set, or a multiple element set), in accordance with known mathematical definitions (for instance, in a manner corresponding to that described in An Introduction to Mathematical Reasoning: Numbers, Sets, and Functions, “Chapter 11: Properties of Finite Sets” (e.g., as indicated on p. 140), by Peter J. Eccles, Cambridge University Press (1998)). Thus, a set includes at least one element. In general, an element of a set can include or be one or more portions of a system, an apparatus, a device, a structure, an object, a process, a procedure, physical parameter, or a value depending upon the type of set under consideration.

The FIGs. included herewith show aspects of non-limiting representative embodiments in accordance with the present disclosure, and particular structural elements shown in the FIGs. may not be shown to scale or precisely to scale relative to each other. The depiction of a given element or consideration or use of a particular element number in a particular FIG. or a reference thereto in corresponding descriptive material can encompass the same, an equivalent, an analogous, categorically analogous, or similar element or element number identified in another FIG. or descriptive material associated therewith. The presence of “/” in a FIG. or text herein is understood to mean “and/or”, i.e., “X/Y” is to mean “X” or “Y” or “both X and Y”, unless otherwise indicated. The recitation of a particular numerical value or value range herein is understood to include or be a recitation of an approximate numerical value or value range, for instance, within +/−20%, +/−15%, +/−10%, +/−5%, +/−2.5%, +/−2%, +/−1%, +/−0.5%, or +/−0%. The term “essentially all” or “substantially” can indicate a percentage greater than or equal to 50%, 60%, 70%, 80%, or 90%, for instance, 92.5%, 95%, 97.5%, 99%, or 100%.

Many modifications will be apparent to those skilled in the art without departing from the scope of the present invention.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

### STATEMENTS

The present specification includes disclosures of the following statements.

Statement 1: a process including:
a) receiving/determining two or more measurements (“magnetic field measurements”) of a magnetic field using a magnetometer attached to a mobile platform when the magnetic field is generated by a magnetic field source (MFS) in a marker apparatus, when the marker apparatus is stationary in a medium, which may include being buried or submerged in the medium, when the marker apparatus is stationary relative to its surrounding medium so that the marker apparatus moves with the medium if the medium moves;
b) receiving/determining two or more locations (“measurement locations”) of the magnetic field measurements in three orthogonal dimensions (3D), thus determining the locations of the magnetometer when the magnetic field measurements are/were determined, wherein the locations may be in the medium or outside the medium—wherein the mobile platform is configured to move relative to the marker apparatus in the medium and/or outside the medium, which may include on the surface of the medium; and
c) numerically estimating (e.g., using an iterative process, and using at least one microprocessor) a location (“source location”) of the magnetic field source (MFS) in three orthogonal dimensions (3D) using:
   i) the two or more magnetic field measurements;
   ii) the two or more measurement locations; and
   iii) a mathematical model representing a magnetic dipole of the magnetic field source (MFS).

Statement 2: The process of Statement 1, including numerically estimating (e.g., using the iterative process) an orientation of the magnetic field source (MFS), including in three orthogonal dimensions (3D orientation), and estimating an orientation of the marker apparatus in the medium from the numerically estimated orientation of the magnetic field source (MFS).

Statement 3: The process of Statement 1 or 2, including generating the magnetic field with a selected strength or moment, which may include a selected value and/or a selected range of values (“calibrated range”), and using the selected strength or moment with the mathematical model when numerically estimating the location of the magnetic field source (MFS).

Statement 4: The process of any one of Statements 1 to 3, wherein the mathematical model associates the magnetic field measurements, the determined locations in 3D, and the 3D location of the magnetic dipole; and/or wherein the mathematical model assumes that the medium is homogeneous, and/or that the medium has a skin depth substantially approaching infinity for frequencies at which the magnetic field is modulated.

Statement 5: The process of any one of Statements 1 to 4, including measuring/controlling the orientation of the magnetic field source (MFS), and using the measured/controlled orientation of the magnetic field source (MFS) with the mathematical model when numerically estimating the location of the magnetic field source (MFS).

Statement 6: The process of any one of Statements 1 to 5, including:
a) receiving/determining (e.g., measuring) two or more orientations of the magnetometer at the two or more measurement locations in three orthogonal dimensions (3D orientation) (thus determining the orientations of the magnetometer when the magnetic field measurements are/were determined); and
b) numerically estimating (e.g., using an iterative process) the location of the magnetic field source (MFS) in the three orthogonal dimensions (3D) using a combination of:
   i) the two or more magnetic field measurements;
   ii) the two or more measurement locations;
   iii) the mathematical model representing the dipole of the magnetic field source; and
   iv) the two or more magnetometer orientations.

Statement 7: The process of Statement 6, wherein the determining of the two or more orientations of the magnetometer includes:
a) determining (e.g., measuring) orientation of the mobile platform;
b) determining (e.g., measuring) relative orientation of the magnetometer to the mobile platform; and
c) estimating the two or more orientations of the magnetometer based on a numerical addition/subtraction of the orientation of the mobile platform and the relative orientation.

Statement 8A: The process of any one of Statements 1 to 7, wherein the measurements of the magnetic field include scalar magnetic field strength values (total field).

Statement 8B: The process of any one of Statements 1 to 8A, wherein the measurements of the magnetic field include vector magnetic field strength values (1D, 2D or 3D absolute values).

Statement 8C: The process of any one of Statements 1 to 8B, wherein the measurements of the magnetic field include phasor magnetic field strength values (1D, 2D or 3D coherent values).

Statement 9: The process of any one of Statements 1 to 8C, wherein the determining of the two or more measurement locations includes:
a) determining (e.g., measuring) locations of the mobile platform;
b) determining (e.g., measuring) a relative location of the magnetometer to the mobile platform; and
c) estimating the two or more measurement locations on numerical addition/subtraction of the locations of the mobile platform and the relative location.

Statement 10: The process of any one of Statements 1 to 9, wherein the determining of the measurements of a magnetic field may include the magnetometer detecting magnetic-induction (MI) signals/through-the-earth (TTE) signals from the magnetic field source (MFS).

Statement 11: The process of any one of Statements 1 to 10, including:
a) the microprocessor receiving the one or more orientations of the magnetic field source (MFS) in the marker apparatus;
b) the microprocessor receiving the selected strength of the moment (m) of the magnetic field source (MFS) from the calibration process;
c) the microprocessor receiving the two or more magnetic field measurements from the magnetometer;
d) the microprocessor receiving the two or more measurement locations from a navigation module; and/or
e) the microprocessor receiving the two or more orientations of the magnetometer from a relative pose measurement system and/or a navigation module.

Statement 12: A system including:
a) a magnetometer attached to a mobile platform configured for determining (e.g., measuring) two or more measurements (“magnetic field measurements”) of a magnetic field when the magnetic field is generated by a magnetic field source (MFS) in a marker apparatus, when the marker apparatus is stationary in a medium;
b) a navigation module attached to the mobile platform configured for determining (e.g., measuring) two or more locations (“measurement locations”) of the magnetic field measurements in three orthogonal dimensions (3D), thus determining the locations of the magnetometer when the magnetic field measurements are/were determined, wherein the locations may be in the medium or outside the medium; and
c) at least one microprocessor configured for numerically estimating a location (“source location”) of the magnetic field source (MFS) in three orthogonal dimensions (3D) using:
   i) the two or more magnetic field measurements;
   ii) the two or more measurement locations; and
   iii) a mathematical model representing a magnetic dipole of the magnetic field source.

Statement 13: The system of Statement 12, wherein the microprocessor is configured for numerically estimating an orientation of the magnetic field source (MFS), including in three orthogonal dimensions (3D orientation), and optionally estimating an orientation of the marker apparatus in the medium from the numerically estimated orientation of the magnetic field source (MFS).

Statement 14: The system of Statement 12 or 13, wherein the magnetic field source (MFS) is configured to generate the magnetic field with a selected strength or moment, which may include a selected value and/or a selected range of values (which may be referred to as a “calibrated range”), and the microprocessor is configured for using the selected strength or moment with the mathematical model when numerically estimating the location of the magnetic field source (MFS).

Statement 15: The system of any one of Statements 12 to 14, wherein the marker apparatus is configured to measure/control the orientation of the magnetic field source (MFS), and the microprocessor is configured for using the measured/controlled orientation of the magnetic field source (MFS) with the mathematical model when numerically estimating the location of the magnetic field source (MFS).

Statement 16: The system of any one of Statements 12 to 15, wherein the system includes a relative pose measurement system and/or a navigation module configured for determining (e.g., measuring) two or more orientations of the magnetometer at the two or more measurement locations in three orthogonal dimensions (3D orientation); and the microprocessor is configured for numerically estimating the location of the magnetic field source in the three orthogonal dimensions (3D) using a combination of:
a) the two or more magnetic field measurements;
b) the two or more measurement locations;
c) the mathematical model representing the infinitesimal dipole of the magnetic field source; and
d) the two or more magnetometer orientations.

Statement 17A: The system of any one of Statements 12 to 16, wherein the magnetometer includes a total magnetometer configured to measure a total scalar value of the magnetic field (b) at the measurement location, regardless of its direction.

Statement 17B: The system of any one of Statements 12 to 17A, wherein the magnetometer includes a vector magnetometer configured to measure a scalar value of the magnetic field in one to three of the three orthogonal dimensions (3D).

Statement 17C: The system of any one of Statements 12 to 17B, wherein the magnetometer includes a coherent vector magnetometer configured to measure a phasor value of the magnetic field in three orthogonal dimensions (3D) including at least one relative phase between the orthogonal components.

Statement 18: The system of any one of Statements 12 to 17C, including an uplink channel between the marker apparatus and the magnetometer for transferring the one or more orientations of the magnetic field source (MFS) from the marker apparatus.

Statement 19: The system of any one of Statements 12 to 18, wherein the marker apparatus includes an accelerometer and/or a magnetometer configured to measure an orientation of the magnetic field source (MFS) when stationery relative to Earth's gravity and/or the Earth's magnetic field (or “geomagnetic field”).

Statement 20: A marker apparatus including:
a) an accelerometer and/or a magnetometer configured to measure an orientation of a magnetic field source (MFS) of the marker apparatus when stationery relative to Earth's gravity and/or the Earth's magnetic field (or “geomagnetic field”); and
b) the magnetic field source (MFS) (e.g., including a through-the-earth (TTE) or magnetic induction (MI) transmitter with a transmit antenna) in the marker apparatus configured to transmit a signal representing the measured orientation to a receiver (with a receive antenna) through a medium such that the measured orientation can be used to estimate a location of the marker apparatus in three orthogonal dimensions (3D).

Statement 21: The marker apparatus of Statement 20, configured to communicate the orientation of the magnetic field source (MFS) via modulation of the magnetic field and/or uplink signals from the magnetic field source (MFS).

Statement 22: A marker apparatus including:
a) an accelerometer and/or a magnetometer configured to measure an orientation of a magnetic field source (MFS) of the marker apparatus when stationery relative to Earth's gravity and/or the Earth's magnetic field; and
b) a microcontroller configured to control the magnetic field source (MFS) in the marker apparatus based on the measured orientation of the magnetic field source (MFS) such that the magnetic field source (MFS) generates a magnetic field with a selected orientation.

[Statements 23 to 100 are blank.]

Statement 101. A process for remote localization of an object, the process including:
receiving/determining two or more magnetic field measurements of a magnetic field using at least one magnetometer when the magnetic field is generated by a magnetic field source (MFS) in a marker apparatus, when the marker apparatus is remote from the or each magnetometer and in/on an opaque medium such that the magnetic field extends through the opaque medium and/or through a navigable medium between the MFS and the or each magnetometer;
receiving/determining two or more respective measurement locations of the magnetic field measurements in three orthogonal dimensions (3D) by determining locations of the or each magnetometer when the magnetic field measurements are/were determined; and
numerically estimating a source location of the magnetic field source (MFS) in 3D using:
   the two or more magnetic field measurements;
   the two or more measurement locations; and
   a mathematical model representing a magnetic dipole of the MFS.

Statement 102. The process of Statement 101, wherein the receiving/determining of the two or more magnetic field measurements includes receiving/determining magnetic field measurements from at least one of the or each magnetometer attached to at least one mobile platform (including using magnetic field measurements from one or more magnetometers attached to the or each mobile platform, and/or using magnetic field measurements from two or more magnetometers attached to two or more mobile platforms, including one magnetometer attached to each mobile platform), including using magnetic field measurements made while a speed of the or each magnetometer is substantially non-zero.

Statement 103. The process of Statement 101 or 102, wherein the receiving/determining of the two or more magnetic field measurements includes: using magnetic field measurements from at least one of the or each magnetometer attached to a fixed point, or stationary at a fixed point, in a reference frame of a site that includes the opaque medium and the marker apparatus.

Statement 104. The process of any one of Statements 101 to 103, including numerically estimating an orientation of the MFS, including in three orthogonal dimensions, and estimating an orientation of the marker apparatus from the numerically estimated orientation of the MFS.

Statement 105. The process of any one of Statements 101 to 104, wherein the magnetic field is generated with a selected strength or moment, including a selected value and/or a selected calibrated range of values, and the numerically estimating includes using the selected strength or moment with the mathematical model.

Statement 106. The process of any one of Statements 101 to 105, wherein the mathematical model associates the magnetic field measurements, the determined locations in 3D, and the 3D location of the magnetic dipole; and/or wherein the mathematical model assumes that the medium is homogeneous, and/or that the medium has a skin depth substantially approaching infinity for frequencies at which the magnetic field is modulated.

Statement 107. The process of any one of Statements 101 to 106, including the MFS having a measured/controlled orientation, and using the measured/controlled orientation of the MFS with the mathematical model when numerically estimating the location of the MFS.

Statement 108. The process of any one of Statements 101 to 107, including:
receiving/determining two or more orientations of the magnetometer at the two or more measurement locations in three orthogonal dimensions; and
numerically estimating the location of the MFS in the three orthogonal dimensions using a combination of:
   the two or more magnetic field measurements;
   the two or more measurement locations;
   the mathematical model representing the dipole of the MFS; and
   the two or more magnetometer orientations.

Statement 109. The process of any one of Statements 101 to 108, wherein the determining of the two or more measurement locations includes:
determining locations of the mobile platform;
determining a relative location of the magnetometer to the mobile platform; and
estimating the two or more measurement locations based on numerical addition/subtraction of the locations of the mobile platform and the relative location.

Statement 110. The process of any one of Statements 101 to 109, wherein the determining of the two or more measurement locations includes:
receiving/determining respective magnetic-field-measurement times when the magnetic field measurements are/were measured; and
determining the respective locations of the magnetometer at the magnetic-field-measurement times from location tracking data representing the location of the magnetometer over time.

Statement 111. The process of any one of Statements 101 to 110, wherein the plurality of magnetic field measurements have respective signal-to-noise ratios (SNRs), and the process includes selecting ones of the magnetic field measurements having SNRs over a selected threshold for the numerically estimating of the source location.

Statement 112. The process of any one of Statements 101 to 111, including localizing at least a portion of a drill bit or drill string by localizing a corresponding marker apparatus during drilling with the drill bit or drill string, or after detachment of the portion from the drill bit or drill string.

Statement 113. The process of any one of Statements 101 to 111, including localizing a blast initiation device or a blast primer device for initiating blasts in commercial blasting operations based on the localization of at least one marker apparatus (including a plurality of marker apparatuses) that is attached to or includes or forms the blast initiation device or the blast primer device.

Statement 114. The process of any one of Statements 101 to 111, including localizing an explosive material in the opaque medium by localizing at least one marker apparatus buried in a selected location in the opaque medium relative to and/or adjacent to and/or above the explosive material, optionally while digging/excavating a portion of the opaque medium or after the digging/excavating.

Statement 115. The process of any one of Statements 101 to 111, including localizing seismic receivers and/or seismic sources by localizing one or more of the or each marker apparatus respectively incorporated in or attached to the seismic receivers and/or the seismic sources.

Statement 116. The process of any one of Statements 101 to 111, including monitoring movement of broken rock by repeatedly localizing the or each marker apparatus placed on or buried in the broken rock.

Statement 117. The process of any one of Statements 101 to 111, including tracking an ore body during blasting, excavation and/or processing by localization of a corresponding one of the or each marker apparatuses, optionally including measuring draw of a stockpile by repeated localization of the corresponding marker apparatus over a selected time period.

Statement 118. A system for remote localization of an object, the system including:
at least one magnetometer configured for determining two or more magnetic field measurements of a magnetic field when the magnetic field is generated by a magnetic field source (MFS) in a marker apparatus, when the marker apparatus is remote from the or each magnetometer and in/on an opaque medium such that the magnetic field extends through the opaque medium and/or through a navigable medium between the MFS and the or each magnetometer;
a tracking module configured for determining two or more respective measurement locations of the magnetic field measurements in three orthogonal dimensions (3D) by determining locations of the magnetometer when the magnetic field measurements are/were determined; and
at least one microprocessor configured for numerically estimating a source location of the MFS in (3D) using:
   the two or more magnetic field measurements;
   the two or more measurement locations; and
   a mathematical model representing a magnetic dipole of the MFS.

Statement 119. The system of Statement 118, wherein the or each magnetometer includes at least one mobile magnetometer attached to at least one mobile platform (including a plurality of mobile magnetometers attached to the or each mobile platform, and/or two or more mobile magnetometers attached two or more mobile platforms, including one mobile magnetometer attached to each mobile platform), wherein the or each mobile magnetometer makes the magnetic field measurements while a speed of the or each mobile magnetometer is substantially non-zero.

Statement 120. The system of Statement 119, wherein the tracking module includes a navigation module attached to the mobile platform and configured for measuring the 3D measurement locations of the magnetic field measurements.

Statement 121. The system of Statement 119 or 120, wherein the tracking module includes a remote location tracking system configured for recording the 3D measurement locations in a path of the mobile platform during the measuring of the magnetic field measurements, and time stamping the 3D measurement locations.

Statement 122. The system of any one of Statements 118 to 121, wherein the or each magnetometer includes at least one magnetometer attached to a fixed point, or stationary at a fixed point, in a reference frame of a site that includes the opaque medium and the marker apparatus.

Statement 123. The system of any one of Statements 118 to 122, wherein the microprocessor is configured for numerically estimating an orientation of the MFS, including in three orthogonal dimensions, and optionally estimating an orientation of the marker apparatus from the numerically estimated orientation of the MFS.

Statement 124. The system of any one of Statements 118 to 123, wherein the MFS is configured to generate the magnetic field with a selected strength or moment, which may include a selected value and/or a selected calibrated range of values, and the microprocessor is configured for using the selected strength or moment with the mathematical model when numerically estimating the location of the MFS.

Statement 125. The system of any one of Statements 118 to 124, wherein the mathematical model associates the magnetic field measurements, the determined locations in 3D, and the 3D location of the magnetic dipole; and/or wherein the mathematical model assumes that the medium is homogeneous, and/or that the medium has a skin depth substantially approaching infinity for frequencies at which the magnetic field is modulated.

Statement 126. The system of any one of Statements 118 to 125, wherein the marker apparatus is configured to measure/control the orientation of the MFS, and the microprocessor is configured for using the measured/controlled orientation of the MFS with the mathematical model when numerically estimating the location of the MFS.

Statement 127. The system of any one of Statements 118 to 126, wherein the system includes a relative pose measurement system and/or the navigation module configured for determining two or more orientations of the magnetometer at the two or more measurement locations in three orthogonal dimensions; and the microprocessor is configured for numerically estimating the location of the MFS in the three orthogonal dimensions using a combination of:
the two or more magnetic field measurements;
the two or more measurement locations;
the mathematical model representing the dipole of the MFS; and
the two or more magnetometer orientations.

Statement 128. The system of any one of Statements 118 to 127, including an uplink channel between the marker apparatus and the magnetometer for transferring the one or more orientations of the MFS from the marker apparatus.

Statement 129. The system of any one of Statements 118 to 128, wherein the marker apparatus includes an accelerometer and/or a magnetometer configured to measure an orientation of the MFS when stationery relative to Earth's gravity and/or the Earth's magnetic field.

Statement 130. The system of any one of Statements 118 to 129, wherein at least one of the or each marker apparatus is substantially adjacent to, coupled to or incorporated into a drill bit or a drill string.

Statement 131. The system of any one of Statements 118 to 129, wherein at least one of the or each marker apparatus includes or forms a blast initiation device or blast primer device for initiating blasts in commercial blasting operations.

Statement 132. The system of any one of Statements 118 to 129, wherein at least one of the or each marker apparatus is buried in a selected location in the opaque medium relative to and/or adjacent to and/or above explosive material.

Statement 133. The system of any one of Statements 118 to 129, wherein at least one of the or each marker apparatus is incorporated respectively into a seismic receiver and/or a seismic sources in a seismic blasting system.

Statement 134. The system of any one of Statements 118 to 129, wherein at least one of the or each marker apparatus is buried in broken rock for monitoring heap leaching.

Statement 135. The system of any one of Statements 118 to 129, wherein at least one of the or each marker apparatus is buried adjacent to or in an ore body for ore tracking.

Statement 136. A marker apparatus including:
an accelerometer and/or a magnetometer configured to measure an orientation of a magnetic field source (MFS) of the marker apparatus when stationery relative to Earth's gravity and/or the Earth's magnetic field; and
the MFS in the marker apparatus configured to transmit a signal representing the measured orientation to a receiver through a medium such that the measured orientation can be used to estimate a location of the marker apparatus in three orthogonal dimensions.

Statement 137. The marker apparatus of Statement 136, configured to communicate the orientation of the MFS via modulation of the magnetic field and/or uplink signals from the MFS.

Statement 138. A marker apparatus including:
an accelerometer and/or a magnetometer configured to measure an orientation of a magnetic field source (MFS) of the marker apparatus when stationery relative to Earth's gravity and/or the Earth's magnetic field; and
a microcontroller configured to control the MFS in the marker apparatus based on the measured orientation of the MFS such that the MFS generates a magnetic field with a selected orientation.

Statement 139. The process of any one of Statements 101 to 111, including localizing a linear utility (e.g., a pipeline/powerline) in the opaque medium by localizing at least one marker apparatus buried in a selected location in the opaque medium relative to and/or adjacent to and/or above the linear utility, optionally while digging/excavating a portion of the opaque medium above the linear utility.

Statement 140. The process of any one of Statements 101 to 111, including localizing measured physical parameters of the opaque medium (e.g., pressure, moisture, and/or temperature) by localizing at least one marker apparatus buried in the opaque medium with respective environmental sensors to measure the physical parameter values, optionally while ploughing the opaque medium adjacent/around the buried marker apparatus.

Statement 141. The process of any one of Statements 101 to 111, including localizing a person or a piece of equipment buried in the opaque medium, e.g., an avalanche, a landslide, or a (collapsed) structure, by localizing at least one marker apparatus attached to the person or the piece of equipment in the opaque medium.

Statement 142. The process of any one of Statements 101 to 111, including placing/burying at least one of the at least one marker apparatus on/in the opaque medium (e.g., rock, earth, foundations or structures), and including localizing the marker apparatus repeatedly over a selected time period to monitor movement of the opaque medium.

Statement 143. The process of any one of Statements 101 to 117 and 139 to 142, including the mobile magnetometer and/or a wireless receiver on the mobile platform gathering wireless encoded/modulated data signals from devices in/on the opaque medium incorporating the marker apparatuses, and/or capturing optical/thermal images, while on the path measuring the magnetic fields.

Statement 144: The process of any one of Statements 102 and 103 to 117 and 139 to 143 when depending from Statement 102, wherein the determining of the two or more orientations of the magnetometer includes:
determining (e.g., measuring) orientation of the mobile platform;
determining (e.g., measuring) relative orientation of the magnetometer to the mobile platform; and
estimating the two or more orientations of the magnetometer based on a numerical addition/subtraction of the orientation of the mobile platform and the relative orientation.

Statement 145: The process of any one of Statements 101 to 117 and 139 to 144, wherein the measurements of the magnetic field include scalar magnetic field strength values (total field).

Statement 146: The process of any one of Statements 101 to 117 and 139 to 145, wherein the measurements of the magnetic field include vector magnetic field strength values (1D, 2D or 3D absolute values).

Statement 147: The process of any one of Statements 101 to 117 and 139 to 146, wherein the measurements of the magnetic field include phasor magnetic field strength values (1D, 2D or 3D coherent values).

Statement 148: The process of any one of Statements 101 to 117 and 139 to 147, wherein the determining of the measurements of a magnetic field may include the magnetometer detecting magnetic-induction (MI) signals/through-the-earth (TTE) signals from the magnetic field source (MFS).

Statement 149: The process of any one of 101 to 117 and 139 to 148, including:
the microprocessor receiving the one or more orientations of the magnetic field source (MFS) in the marker apparatus;
the microprocessor receiving the selected strength of the moment (m) of the magnetic field source (MFS) from the calibration process;
the microprocessor receiving the two or more magnetic field measurements from the magnetometer;
the microprocessor receiving the two or more measurement locations from a navigation module; and/or
the microprocessor receiving the two or more orientations of the magnetometer from a relative pose measurement system and/or a navigation module.

Statement 150. The system of any one of Statements 118 to 135, including the at least one marker apparatus buried in a selected location in the opaque medium relative to and/or adjacent to and/or above a linear utility, optionally a pipeline/powerline, in the opaque medium.

Statement 151. The system of any one of Statements 118 to 135, including one or more environmental sensors configured to detect, monitor, estimate, or measure physical parameters of the surrounding portion of the opaque medium, and the environmental sensors may include temperature sensors and/or moisture sensor, optionally for soil monitoring.

Statement 152. The system of any one of Statements 118 to 135, including at least one marker apparatus incorporated into a marker beacon for mountain workers or engineering workers, optionally attached or incorporated in clothing, modified ski passes/access tags, and/or smartphone cases/power banks.

Statement 153. The system of any one of Statements 119 and 120 to 135 and 150 to 152 when depending from Statement 119, wherein the mobile platform includes the mobile magnetometer and/or a wireless receiver configured for receiving wireless encoded/modulated data signals from devices in/on the opaque medium.

Statement 154. The system of any one of Statements 119 and 120 to 135 and 150 to 153 when depending from Statement 119, wherein the mobile platform includes at least one optical/thermal camera configured to capture images from the mobile platform while the mobile platform travels along the path and makes the magnetic field measurements.

Statement 155. The system of any one of Statements 118 to 135 and 150 to 154, wherein the magnetometer includes a total magnetometer configured to measure a total scalar value of the magnetic field (b) at the measurement location, regardless of its direction.

Statement 156. The system of any one of Statements 118 to 135 and 150 to 155, wherein the magnetometer includes a vector magnetometer configured to measure a scalar value of the magnetic field in one to three of the three orthogonal dimensions (3D).

Statement 157. The system of any one of Statements 118 to 135 and 150 to 156, wherein the magnetometer includes a coherent vector magnetometer configured to measure a phasor value of the magnetic field in three orthogonal dimensions (3D) including at least one relative phase between the orthogonal components.

APPENDIX A
Coherent Vector Process - determining P&O of a marker (iterative)

```
  In these Appendices, bold face indicates a vector or matrix quantity, while plain face
is a scalar. E.g. r = ||r||. The marker P&O variables are usually written in the form of a
‘tracking matrix’ P, and an ‘orientation matrix’ Aₘ, as described in Kuipers J B, others
(1999) “Quaternions and rotation sequences”. Princeton University Press, Princeton. This
allows the forward model to be factorised into a rotation sequence, simplifying algebraic
manipulation.
  d stores n measurements of the sensor position vector, over the course of the mission
(where the measurement locations may be referred to herein as n “stations” or “measurement
stations”)
  b stores n corresponding measurements of the magnetic flux density vector
  x stores a list of values for the unknown marker variables (position vector R,
orientation Euler angles ψ and θ, and magnetic moment magnitude m)
$x = ( \begin{matrix}{R}_{x} \\ {R}_{y} \\ {R}_{z} \\ ψ \\ θ \\ m\end{matrix} )$
  The function OrientationGuess(R₀, d, b) is used with coherent data.
  1: d ← populated with data from vehicle GNSS-INS and any sensor-vehicle
    displacement
  2: b ← populated with data from magnetometer, corrected for sensor rotation
  3: R₀ ← populated from prior information on marker location (e.g., approximate
    estimates), or a direct inversion process
  4: ψ₀, θ₀ ← OrientationGuess(R₀, b)
  5: m₀ ← nominal design moment
  $6 : {x}_{0} ← ( \begin{matrix}{R}_{0} \\ {ψ}_{0} \\ {θ}_{0} \\ {m}_{0}\end{matrix} )$
  7: x ← x₀ iteration variable (marker unknowns)
  8: while cost > tol do standard non-linear (global) optimisation routines
  9: cost ← CostFunction(x, d, b)
  10: x ← NewGuess(x, d, b)
  11: function OrientationGuess(R₀, d,b)
  12: r ← R₀ − d vectors from stations to marker location
  13: for i = 1 to n do for each station, i
  14: Pᵢ ← tracking(rᵢ) “Tracking Matrix” (a rotation matrix)
  15: Cᵢ ← coupling(rᵢ) “Coupling Matrix” (depending on the medium model)
  $16 : {f}_{i} ← {r}_{i}^{3} {P}_{i}^{T} {C}_{i}^{- 1} {P}_{i} {b}_{i}$
  $17 : F ← mean ( f ) should be approx . \frac{{μ}_{0} m}{4 π} {A}_{m}^{T} \hat{m} ,$
    where \hat{m} is a unit vector of known direction.
    e.g. \hat{x}, ŷ, or \hat{z} determined by the design
    of the marker (by definition)
  18: ψ ← atan2(F₂,F₁)
  19: θ ← − asin(F₃/||F||)
  $20 : m ← \frac{4 π}{{μ}_{0}} ‖ F ‖ optional ( nominal factory m may be used instead$
  21: Function CostFunction(x,d,b) coherent vector process
  22:   r ← R − d
  23:  Aₘ ← aero(ψ, θ) a rotation matrix (ZYX aerospace sequence)
  24:  for i = 1 to n do
  25: Pᵢ ← tracking(rᵢ)
  26: Cᵢ ← coupling(rᵢ)
  $27 : {f}_{i} = {b}_{i} - \frac{{μ}_{0} m}{4 π {r}_{i}^{3}} {P}_{i}^{T} {C}_{i} {P}_{i} {A}_{m}^{T} \hat{m} simplest cost function , using the forward model directly$
  $28 : cost = {\sum }_{i} {f}_{i}^{2} sum of squares of cost at each station$
  29: Function NewGuess(x, d, b)
  e.g., processes such as MATLAB's Isqnonlin( ) function
```

APPENDIX B
cost function: Self-righting dipole

```
$x ← ( \begin{matrix}{R}_{x} \\ {R}_{y} \\ {R}_{z}\end{matrix} ) list of unknown marker variables is now only 3 DoF ( position only ) . Don ' t$
iterate on orientation or moment.
  1: Function CostFunction(x, d, b) a coherent vector process
  2: r ← R − d
  3: for i = 1 to n do
  4: Pᵢ ← tracking(rᵢ)
  5: Cᵢ ← coupling(rᵢ)
  $6 : {f}_{i} = {b}_{i} - \frac{{μ}_{0} m}{4 π {r}_{i}^{3}} {P}^{T} {C}_{i} {P}_{i} \hat{z} for a vertical magnetic dipole , {A}_{m} \hat{m} becomes \hat{z}$
  $7 : cost = {\sum }_{i} {f}_{i}^{2}$
```

APPENDIX C
cost functions: Total field process

```
  b ← magnetometer data, which may be in the sensor frame in this case (as opposed to
the global frame). Phase/sign of b not required. Vector components of b not necessarily
required (only total field).
  1: Function CostFunction(x, d, b)
  2: r ← R − d
  3: Aₘ ← aero(ψ, θ)
  4: for i = 1 to n do
  5: Pᵢ ← tracking(rᵢ)
  6: Cᵢ ← coupling(rᵢ)
  $7 : {f}_{i} = {‖ {b}_{i} ‖}^{2} - {( \frac{{μ}_{0} m}{4 π} )}^{2} \frac{1}{{r}_{i}^{6}} {\hat{m}}^{T} {A}_{m} {P}_{i}^{T} {‖ {C}_{i} ‖}^{2} {P}_{i} {A}_{m}^{T} \hat{m}$
    randomly oriented dipole m, RMD
  $8 : cost = {\sum }_{i} {f}_{i}^{2}$
For a self-righting dipole, this becomes:
$x ← ( \begin{matrix}{R}_{x} \\ {R}_{y} \\ {R}_{z}\end{matrix} )$
  1: Function CostFunction(x, d,b)
  2: r ← R − d
  3: for i = 1 to n do
  4: Pᵢ ← tracking(rᵢ)
  5: Cᵢ ← coupling(rᵢ)
  $6 : {f}_{i} = {‖ {b}_{i} ‖}^{2} - {( \frac{{μ}_{0} m}{4 π} )}^{2} \frac{1}{{r}_{i}^{6}} {\hat{z}}^{T} {P}_{i}^{T} {‖ {C}_{i} ‖}^{2} {P}_{i} \hat{z} for a vertical magnetic dipole ,$
    Aₘ\hat{m} becomes \hat{z}
  $7 : cost = {\sum }_{i} {f}_{i}^{2}$
```

APPENDIX D
Absolute value process (of vector components)

```
  b ← magnetometer data, only magnitude of each component of b required.
  1: Function CostFunction(x, d, b)
  2: r ← R − d
  3: Aₘ ← aero(ψ, θ)
  4: for i = 1 to n do
  5: Pᵢ ← tracking(rᵢ)
  6: Cᵢ ← coupling(rᵢ)
  $7 : {f}_{i} = \vert {b}_{i} \vert - \vert \frac{{μ}_{0} m}{4 π {r}_{i}^{3}} {P}_{i}^{T} {C}_{i} {P}_{i} {A}_{m}^{T} \hat{m} \vert$
  $8 : cost = {\sum }_{i} {f}_{i}^{2}$
  For a self-righting dipole, this becomes:
  $x ← ( \begin{matrix}{R}_{x} \\ {R}_{y} \\ {R}_{z}\end{matrix} )$
  1: Function CostFunction(x, d, b)
  2: r ← R − d
  3: for i = 1 to n do
  4: Pᵢ ← tracking(rᵢ)
  5: Cᵢ ← coupling(rᵢ)
  $6 : {f}_{i} = \vert {b}_{i} \vert - \vert \frac{{μ}_{0} m}{4 π {r}_{i}^{3}} {P}_{i}^{T} {C}_{i} {P}_{i} \hat{z} \vert$
  $7 : cost = {\sum }_{i} {f}_{i}^{2}$
  For a self-righting dipole, and a single (z-)axis sensor, this becomes:
  b ← magnetometer data in the sensor frame only. Conversion to global frame not
possible.
  1: Function CostFunction(x, d, b)
  2: r ← R − d
  3: for i = 1 to n do
  4: Pᵢ ← tracking(rᵢ)
  5: Cᵢ ← coupling(rᵢ)
  $6 : {f}_{i} = {b}_{z , i} - {\vert \frac{{μ}_{0} m}{4 π {r}_{i}^{3}} {P}_{i}^{T} {C}_{i} {P}_{i} \hat{z} \vert}_{z} z - subscript indicates z - direction component of vector$
  $7 : cost = {\sum }_{i} {f}_{i}^{2}$
```

APPENDIX E
Reduced DoF

```
  b ← coherent vector magnetometer data
  $x ← ( \begin{matrix}{R}_{x} \\ {R}_{y} \\ {R}_{z}\end{matrix} ) list of unknown marker variables is now only 3 DoF ( position only ) . Don ' t$
iterate on orientation or moment.
  1: Function CostFunction(x, d, b)
  2: r ←R − d
  3: for i = 1 to n, and j = 1 to n, do
  4: Pᵢ ← tracking(rᵢ)
  5: Pⱼ ← tracking(rⱼ)
  6: Cᵢ ← coupling(rᵢ)
  7: Cⱼ ← coupling(rⱼ)
  $8 : {f}_{i , j} = {r}_{i}^{3} {P}_{i}^{T} {C}_{i}^{- 1} {P}_{i} {b}_{i} - {r}_{j}^{3} {P}_{j}^{T} {C}_{j}^{- 1} {P}_{j} {b}_{j} 3 - element vector , 3 DoF$
  $9 : cost = {\sum }_{i \neq j} {f}_{i , j}^{2}$
  Once cost has been minimised, the orientation may be determined from the solution
R = x, by calling Orientation Guess(R, d, b).
  Alternative reduced DoF cost element in the above (line 8):
  $8 : {f}_{i , j} = {r}_{i}^{6} {b}_{i}^{*} {P}_{i}^{T} {‖ {C}_{i}^{- 1} ‖}^{2} {P}_{i} {b}_{i} - {r}_{j}^{6} {b}_{j}^{*} {P}_{j}^{T} {‖ {C}_{j}^{- 1} ‖}^{2} {P}_{j} {b}_{j} scalar , 3 DoF$
  Here, the asterisk * indicates complex conjugate transpose. After cost has been
minimised, OrientationGuess may be used to get the remaining marker variables (orientation
& moment).
  $Each term of f above should be approx . {( \frac{{μ}_{0} m}{4 π} )}^{2} . This could be used to create a$
version of OrientationGuess just for the moment, without orientation.
  Alternative reduced DoF cost elements in the above (line 8):
  $8 : {f}_{i} = {( \frac{4 π {r}_{i}^{3}}{{μ}_{0} m} )}^{2} {b}_{i}^{*} {P}_{i}^{T} {‖ {C}_{i}^{- 1} ‖}^{2} {P}_{i} {b}_{i} - 1 scalar , 4 DoF$
```

APPENDIX F
determining P&O of a marker using a direct process (no iteration, no guess).

```
  d stores n measurements of the sensor position vector, over the course of the mission
(stations)
  b stores n corresponding measurements of the magnetic flux density vector
  1: d ← populated with data from vehicle GNSS-INS and any sensor-vehicle
    displacement
  2: b ← populated with data from magnetometer, corrected for sensor rotation. Coherent
    detector.
  3: imax ← argmax(||b||) find max signal strength
  4: i1, i2, i3, i4 ← NearbyStations(d(imax)) nearby stations in roughly a square
  5: d1, d2, d3, d4 ← d(i1), d(i2), d(i3), d(i4)
  6: b1, b2, b3, b4 ← b(i1), b(i2), b(i3), b(i4) corresponding signal measurements
  7: b_{avg} ← mean(b1, b2, b3, b4)
  8: d_{avg} ← mean(d1,d2, d3, d4)
  9: for i, j = x, y do
  10: ∂ᵢbⱼ ← Δbⱼ/Δdᵢ approximate gradients
  $11 : G ← ( \begin{matrix}{\partial }_{x} {b}_{x} & {\partial }_{x} {b}_{y} & {\partial }_{x} {b}_{z} \\ {\partial }_{y} {b}_{x} & {\partial }_{y} {b}_{y} & {\partial }_{y} {b}_{z} \\ {\partial }_{x} {b}_{z} & {\partial }_{y} {b}_{z} & - ( {\partial }_{x} {b}_{x} + {\partial }_{y} {b}_{y} )\end{matrix} ) compose Gradient tensor G ≡ {▽ ( b )}^{T}$
  12: r ← 3G⁺b (·)⁺ means the Moore-Penrose pseudoinverse
  13: R←r_{avg} + d_{avg} return the marker position R
  Euler Deconvolution may be implemented as described in Appendix F, including as a
process of obtaining an initial guess R₀. It is then followed by a more precise iterative
process set out in Appendix A.
```

1-38. (canceled)

39. A process for remote localization of an object, comprising:
receiving two or more magnetic field measurements of a magnetic field using at least one magnetometer when the magnetic field is generated by a magnetic field source (MFS) in a marker apparatus associated with the object, the marker apparatus being remote from the at least one magnetometer and on an opaque medium such that the magnetic field extends through the opaque medium and/or through a navigable medium between the MFS and the at least one magnetometer;
determining two or more respective measurement locations of the magnetic field measurements in three orthogonal dimensions (3D) by determining locations of the at least one magnetometer in response to the receipt of the magnetic field measurements; and
numerically estimating a source location of the magnetic field source (MFS) in 3D using (i) the two or more magnetic field measurements, (ii) the two or more measurement locations, and (iii) a mathematical model representing a magnetic dipole of the MFS.

40. The process of claim 39, wherein the at least one magnetometer includes a moving magnetometer attached to a mobile platform that is moving at a speed that is substantially non-zero, and wherein the receiving of the two or more magnetic field measurements includes receiving magnetic field measurements from the moving magnetometer.

41. The process of claim 39, wherein the at least one magnetometer includes a stationary magnetometer that is located at a fixed point in a reference frame of a site that includes the opaque medium and the marker apparatus, and wherein the receiving of the two or more magnetic field measurements includes receiving magnetic field measurements from the stationary magnetometer.

42. The process of claim 39, further including numerically estimating an orientation of the MFS in three orthogonal dimensions, and estimating an orientation of the marker apparatus from the numerically estimated orientation of the MFS.

43. The process of claim 39, wherein the magnetic field is generated with a selected strength or moment, the selected strength or moment including a selected value and/or a selected calibrated range of values, and wherein the numerically estimating includes using the selected strength or moment with the mathematical model.

44. The process of claim 39, wherein the mathematical model associates the magnetic field measurements, the determined locations in 3D, and the 3D location of the magnetic dipole, and wherein the mathematical model assumes that the opaque medium is homogeneous, and that the opaque medium has a skin depth substantially approaching infinity for frequencies at which the magnetic field is modulated.

45. The process of claim 39, wherein the MFS has a measured orientation, and wherein the numerically estimating includes using the measured orientation of the MFS with the mathematical model.

46. The process of claim 39, further including receiving two or more orientations of the magnetometer at the two or more measurement locations in three orthogonal dimensions, and wherein the numerically estimating the source location of the MFS also uses the two or more magnetometer orientations.

47. The process of claim 39, wherein the at least one magnetometer includes a moving magnetometer that is attached to a mobile platform that is moving at a speed that is substantially non-zero, and wherein the determining of the two or more measurement locations includes (i) determining locations of the mobile platform; (ii) determining a relative location of the moving magnetometer to the mobile platform, and (iii) estimating the two or more measurement locations based on numerical addition/subtraction of the locations of the mobile platform and the relative location.

48. The process of claim 39, wherein the determining of the two or more measurement locations includes (i) receiving respective magnetic-field-measurement times when the magnetic field measurements were measured and (ii) determining the respective locations of the magnetometer at the magnetic-field-measurement times from location tracking data representing the location of the magnetometer over time.

49. The process of claim 39, wherein the two or more magnetic field measurements have respective signal-to-noise ratios (SNRs), and the process further comprises selecting ones of the magnetic field measurements having SNRs over a selected threshold for use in the numerically estimating of the source location.

50. The process of claim 39, wherein the object is at least a portion of a drill bit or drill string, and the numerical estimating of the source location occurs (i) during drilling with the drill bit or drill string, or (ii) after detachment of the portion from the drill bit or drill string.

51. The process of claim 39, wherein the object is a blast initiation device or a blast primer device for initiating blasts in commercial blasting operations, the marker apparatus is attached to, includes, or forms the blast initiation device or the blast primer device.

52. The process of claim 39, further including localizing an explosive material in the opaque medium by localizing the marker apparatus buried in a selected location in the opaque medium relative to, adjacent to, or above the explosive material.

53. The process of claim 52, wherein the localizing the marker apparatus buried in the selected location in the opaque medium occurs (i) during digging or excavating a portion of the opaque medium or (ii) after the digging or excavating a portion of the opaque medium.

54. The process of claim 39, wherein the object is a seismic receiver or seismic source, the marker apparatus is incorporated in or attached to the seismic receives or the seismic source.

55. The process of claim 39, further including monitoring movement of broken rock by repeatedly localizing the marker apparatus placed on or buried in the broken rock.

56. The process of claim 39, further including tracking an ore body during blasting, excavation and/or processing by localization of a corresponding one of the or each marker apparatuses.

57. The process of claim 56, wherein the tracking includes measuring draw of a stockpile by repeated localization of the corresponding marker apparatus over a selected time period.

58. The process of claim 39, wherein the marker apparatus is located within the opaque medium.
